(19) United States
(12) Patent Application Publication
(10) Pub. No.: US 2026/0096415 A1
(43) Pub. Date: Apr. 2, 2026

(54) Power Package Configured for Increased Power Density, Electrical Efficiency, and Thermal Performance

(71) Applicant: WOLFSPEED, INC.

(72) Inventors: Shashwat Singh, Fayetteville, AR (US); Brice McPherson, Springdale, AR (US); Brandon Passmore, Fayetteville, AR (US); Ben Samples, Fayetteville, AR (US); Sayan Seal, Fayetteville, AR (US); Roberto Marcelo Schupbach, Fayetteville, AR (US)

(21) Appl. No.: 18/899,287

(22) Filed: Sep. 27, 2024

(51) Int. Cl. H01L 23/528; H01L 23/00; H01L 25/16; H05K 1/18

(52) U.S. Cl. CPC H10W 20/427; H05K 1/181; H05K 2201/10757; H05K 2201/10818; H10W 72/07552; H10W 72/07653; H10W 72/527; H10W 72/5445; H10W 72/631; H10W 72/871; H10W 72/884; H10W 72/886; H10W 90/00; H10W 90/734; H10W 90/753; H10W 90/754; H10W 90/763

(57) ABSTRACT

A power package includes at least one power substrate having at least one power trace, at least one power device on the at least one power trace, signal terminals, and at least one signal connection assembly. The at least one signal connection assembly includes at least one of the following: at least one signal trace that is thinner than the at least one power trace; at least one embedded routing layer within the at least one power substrate; and/or at least one routing layer on the at least one power substrate.

### FIELD OF THE DISCLOSURE

The disclosure relates to a power package configured for increased power density. The disclosure further relates to a power package configured for increased electrical efficiency. The disclosure additionally relates to a power package configured for increased thermal performance.

### BACKGROUND OF THE DISCLOSURE

Silicon Carbide (SiC) power devices offer a high level of performance benefits, including high voltage blocking, low on-resistance, high current, fast switching, low switching losses, high junction temperatures, and high thermal conductivity.

Ultimately, these characteristics result in a notable increase in potential power density, which is power processed per area or volume.

However, implementation of Silicon Carbide (SIC) power devices at a package level and/or system level presents significant challenges including higher voltages, currents, switching speeds and/or the like that manifest into significantly higher physical stresses applied onto smaller and more constrained areas.

Accordingly, what is needed is a package and/or system configured to implement higher voltages, currents, switching speeds, and/or the like.

### SUMMARY OF THE DISCLOSURE

In one aspect, a power package includes at least one power substrate having at least one power trace. The power package in addition includes at least one power device on the at least one power trace. The power package moreover includes signal terminals. The power package also includes at least one signal connection assembly. The power package further includes where the at least one signal connection assembly comprises at least one of the following: at least one signal trace that is thinner than the at least one power trace; at least one embedded routing layer within the at least one power substrate; and/or at least one routing layer on the at least one power substrate.

In one aspect, a power package includes at least one power substrate having at least one power trace. The power package in addition includes at least one power device on the at least one power trace. The power package moreover includes signal terminals. The power package also includes at least one signal connection assembly configured to reduce a signal loop trace area and increase a power loop area. The power package further includes where the at least one signal connection assembly comprises at least one of the following: at least one signal trace that is thinner than the at least one power trace; at least one embedded routing layer within the at least one power substrate; and/or at least one routing layer on the at least one power substrate.

In one aspect, a power package includes at least one power substrate having at least one power trace. The power package in addition includes at least one power device on the at least one power trace. The power package moreover includes signal terminals. The power package also includes at least one signal connection assembly. The power package further includes where the at least one signal connection assembly is connected to at least one signal interconnect. The power package in addition includes where the at least one signal interconnect is further connected to at least one of the signal terminals. The power package moreover includes where the at least one signal connection assembly comprises at least one of the following: at least one signal trace that is thinner than the at least one power trace; at least one embedded routing layer within the at least one power substrate; and/or. The power package in addition includes at least one routing layer on the at least one power substrate.

In one aspect, a power package includes at least one power substrate having at least one power trace. The power package in addition includes at least one power device on the at least one power trace. The power package moreover includes signal terminals. The power package also includes at least one signal connection assembly. The power package further includes where the at least one signal connection assembly comprises at least one of the following: at least one signal trace that is thinner than the at least one power trace; at least one embedded routing layer within the at least one power substrate; and/or at least one routing layer on the at least one power trace.

There has thus been outlined, rather broadly, certain aspects of the disclosure in order that the detailed description thereof herein may be better understood, and in order that the present contribution to the art may be better appreciated. There are, of course, additional aspects of the disclosure that will be described below and which will form the subject matter of the claims appended hereto.

In this respect, before explaining at least one aspect of the disclosure in detail, it is to be understood that the disclosure is not limited in its application to the details of construction and to the arrangements of the components set forth in the following description or illustrated in the drawings. The disclosure is capable of aspects in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods, and systems for carrying out the several purposes of the disclosure. It is important, therefore, that the claims be regarded as including such equivalent constructions insofar as they do not depart from the spirit and scope of the disclosure.

### BRIEF DESCRIPTION OF THE DRAWINGS

FIG. 1 illustrates a partial perspective view of a power package according to aspects of the disclosure.

FIG. 2 illustrates a partial perspective view of another power package according to aspects of the disclosure.

FIG. 3 illustrates a partial perspective view of another power package according to aspects of the disclosure.

FIG. 4 illustrates a partial perspective view of another power package according to aspects of the disclosure.

FIG. 5 illustrates a partial perspective view of another power package according to aspects of the disclosure.

FIG. 6 illustrates a partial perspective view of another power package according to aspects of the disclosure.

FIG. 7 illustrates a partial perspective view of another power package according to aspects of the disclosure.

FIG. 8 illustrates a partial perspective view of another power package according to aspects of the disclosure.

FIG. 9 illustrates a partial top view of another power package according to aspects of the disclosure.

FIG. 10 illustrates a partial top view of another power package according to aspects of the disclosure.

FIG. 11 illustrates a partial top view of a power package according to aspects of the disclosure.

FIG. 12 illustrates a partial top view of a power package according to aspects of the disclosure.

FIG. 13 illustrates a partial top view of a power package according to aspects of the disclosure.

FIG. 14 illustrates a partial top view of a power package according to aspects of the disclosure.

FIG. 15 illustrates a partial top view of a power package according to aspects of the disclosure.

FIG. 16 illustrates a partial perspective view of the power package according to FIG. 15.

FIG. 17 illustrates an exploded partial perspective view of the power package according to FIG. 15.

FIG. 18 illustrates a partial top view of a power package according to aspects of the disclosure.

FIG. 19 illustrates a partial perspective view of a power package according to FIG. 18.

FIG. 20 illustrates a partial exploded perspective view of a power package according to FIG. 18.

FIG. 21 illustrates a partial top view of a power package according to aspects of the disclosure.

FIG. 22 illustrates a partial perspective view of a power package according to FIG. 21.

FIG. 23 illustrates a partial exploded perspective view of a power package according to FIG. 21.

FIG. 24 illustrates a partial top view of a power package according to aspects of the disclosure.

FIG. 25 illustrates a partial top view of a power package according to aspects of the disclosure.

FIG. 26 illustrates a partial top view of a power package according to aspects of the disclosure.

FIG. 27 illustrates a partial top view of a power package according to aspects of the disclosure.

FIG. 28 illustrates a partial top view of a power package according to FIG. 27.

FIG. 29 illustrates a partial top view of a power package according to aspects of the disclosure.

FIG. 30 illustrates a partial top view of a power package according to aspects of the disclosure.

FIG. 31 illustrates a partial top view of a power package according to aspects of the disclosure.

FIG. 32 illustrates a partial top view of a power package according to aspects FIG. 31.

FIG. 33 illustrates a partial top view of a power package according to aspects of the disclosure.

FIG. 34 illustrates a partial top view of a power package according to FIG. 33.

FIG. 35 illustrates a partial perspective view of a power package according to aspects of the disclosure.

FIG. 36 illustrates a partial top view of a power package according to aspects of the disclosure.

FIG. 37 illustrates a partial side view of a power package according to aspects of the disclosure.

FIG. 38 illustrates a partial perspective view of a power package according to aspects of the disclosure.

FIG. 39 illustrates a partial top view of a power package according to aspects of the disclosure.

FIG. 40 illustrates a partial side view of a power package according to aspects of the disclosure.

FIG. 41 illustrates a partial perspective view of a power package according to aspects of the disclosure.

FIG. 42 illustrates a partial top view of a power package according to FIG. 41.

FIG. 43 illustrates a partial side view of a power package according to FIG. 41.

FIG. 44 illustrates a partial perspective view of a power package according to FIG. 41.

FIG. 45 illustrates a partial top view of a power package according to FIG. 41.

FIG. 46 illustrates a partial side view of a power package according to FIG. 41.

FIG. 47 illustrates a partial exploded perspective view of a power package according to FIG. 41.

FIG. 48 illustrates a partial top view of a power package according to aspects of the disclosure.

FIG. 49 illustrates a partial exploded perspective view of a power package according to FIG. 48.

FIG. 50 illustrates a partial top view of a power package according to aspects of the disclosure.

FIG. 51 illustrates a partial exploded perspective view of a power package according to FIG. 50.

FIG. 52 illustrates a partial top view of a power package according to aspects of the disclosure.

FIG. 53 illustrates a partial top view of a power package according to aspects of the disclosure.

FIG. 54 illustrates a partial exploded perspective view of a power package according to aspects of the disclosure.

FIG. 55 illustrates a partial view of a power package according to aspects of the disclosure.

FIG. 56 illustrates a partial view of a power package according to aspects of the disclosure.

FIG. 57 illustrates a partial view of a power package according to aspects of the disclosure.

FIG. 58 illustrates a partial top view of a power package according to aspects of the disclosure.

FIG. 59 illustrates a partial top view of a power package according to aspects of the disclosure.

FIG. 60 illustrates a partial exploded perspective view of a power package according to aspects of the disclosure.

FIG. 61 illustrates a partial top view of a power package according to aspects of the disclosure.

FIG. 62 illustrates a partial top view of a power package according to aspects of the disclosure.

FIG. 63 illustrates a partial exploded perspective view of a power package according to aspects of the disclosure.

FIG. 64 illustrates partial cross-sectional views of power packages according to aspects of the disclosure.

FIG. 65 illustrates a partial cross-sectional views of a power packages according to aspects of the disclosure.

FIG. 66 illustrates a partial perspective view alongside a partial top view of a power package according to aspects of the disclosure.

FIG. 67 illustrates a partial exploded view of an exemplary implementation of a power package according to aspects of the disclosure.

FIG. 68 illustrates partial views of exemplary power packages according to aspects of the disclosure.

### DETAILED DESCRIPTION

The disclosure will now be described with reference to the drawing figures, in which like reference numerals refer to like parts throughout.

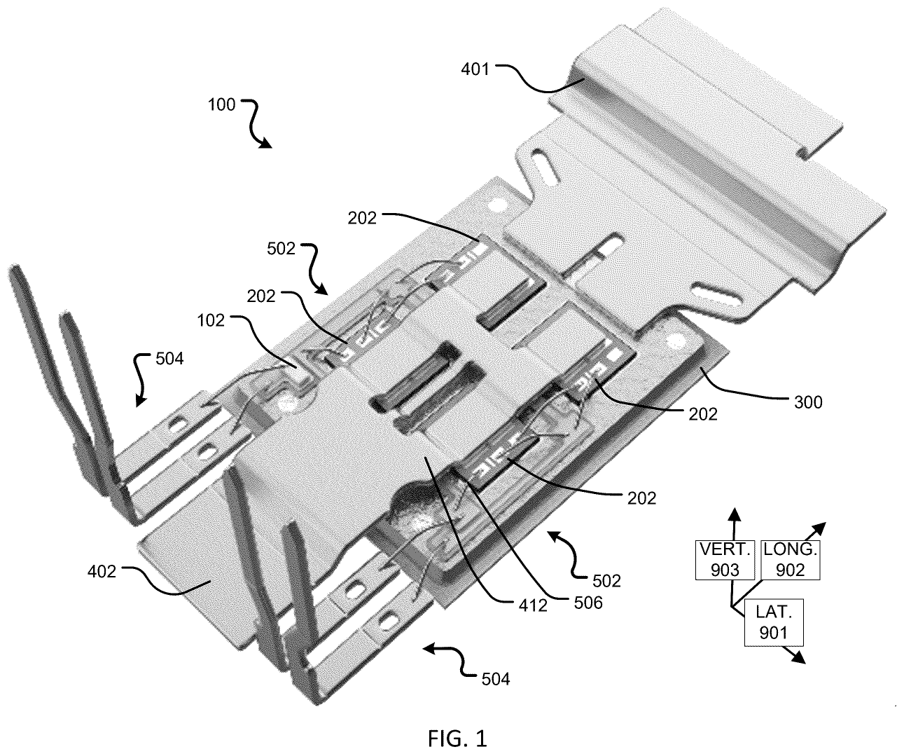

FIG. 1 illustrates a partial perspective view of a power package according to aspects of the disclosure.

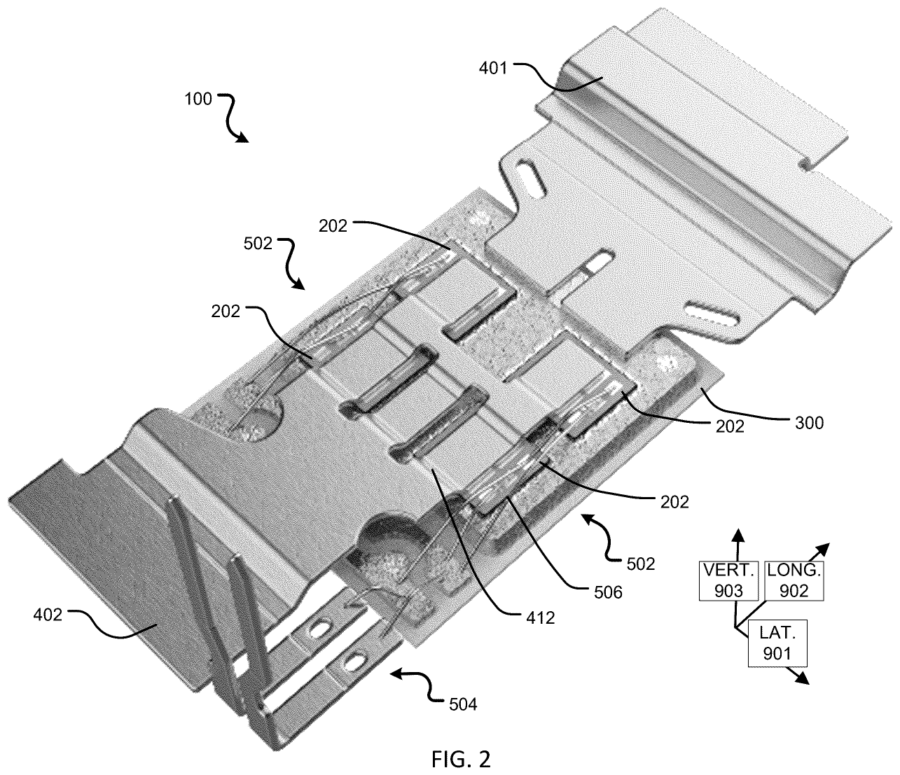

FIG. 2 illustrates a partial perspective view of another power package according to aspects of the disclosure.

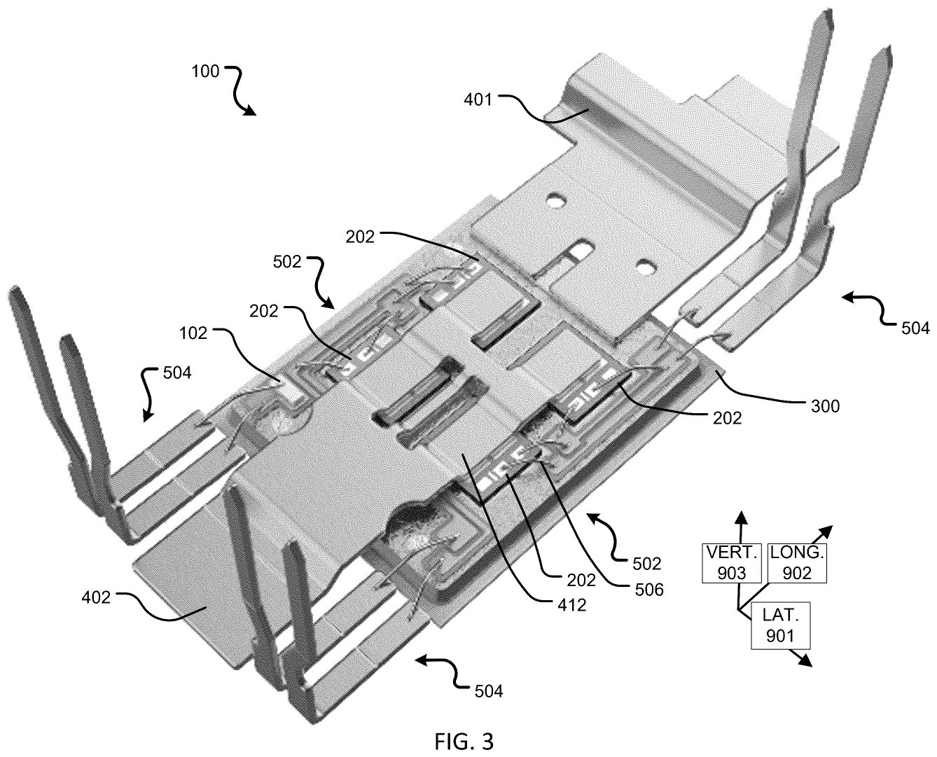

FIG. 3 illustrates a partial perspective view of another power package according to aspects of the disclosure.

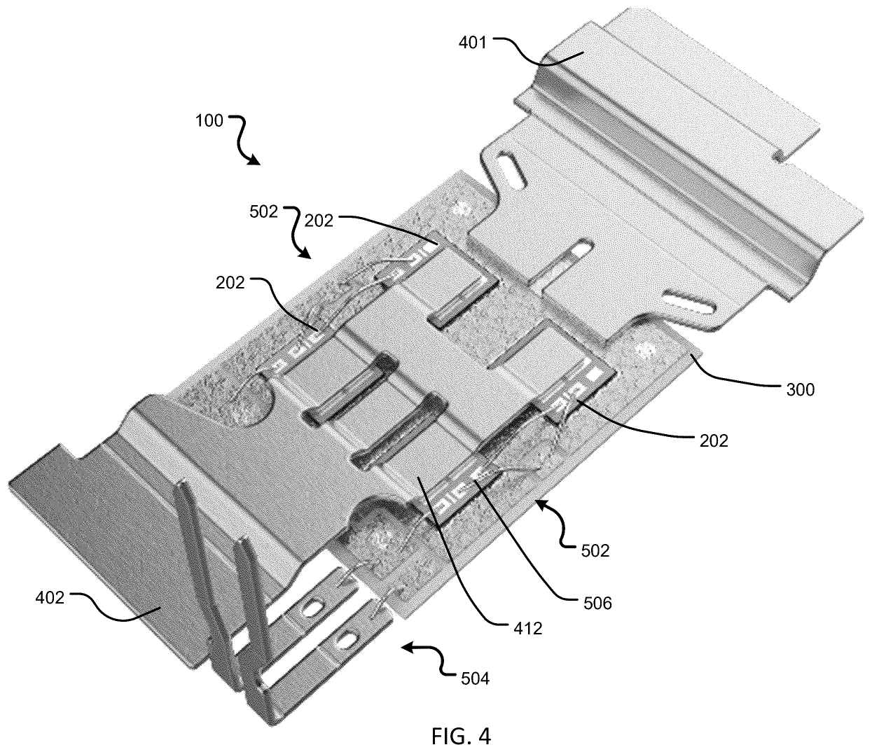

FIG. 4 illustrates a partial perspective view of another power package according to aspects of the disclosure.

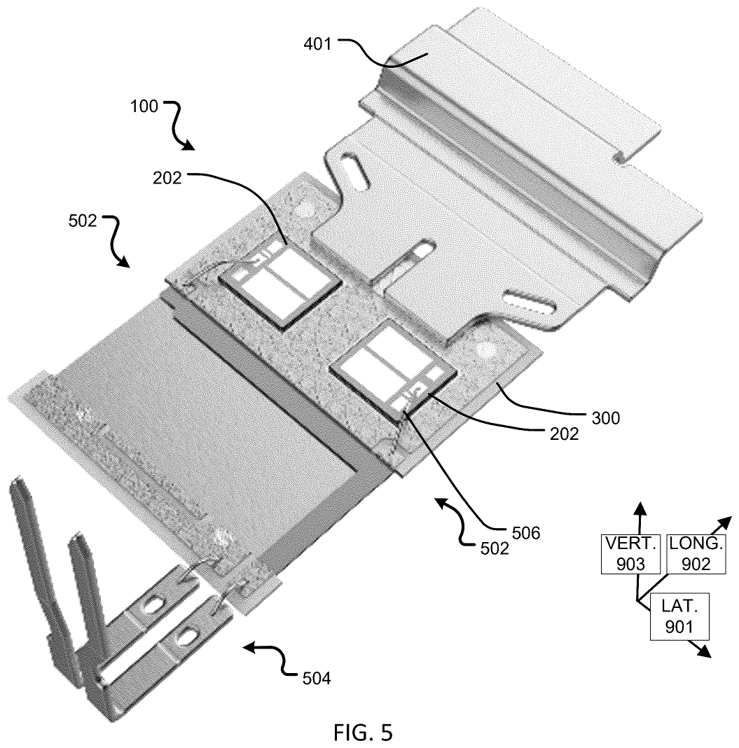

FIG. 5 illustrates a partial perspective view of another power package according to aspects of the disclosure.

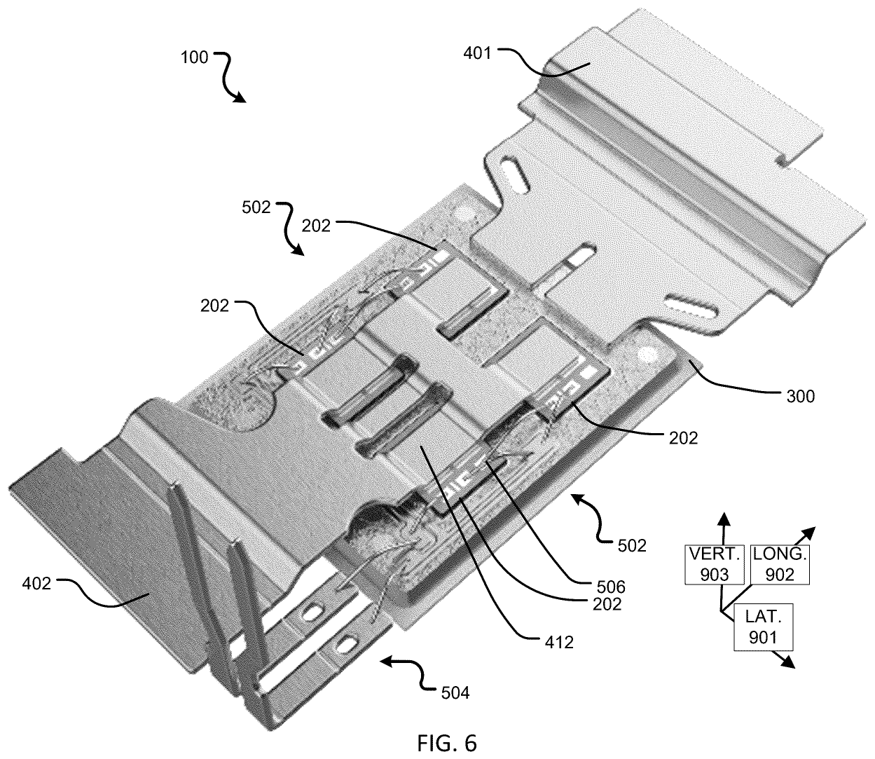

FIG. 6 illustrates a partial perspective view of another power package according to aspects of the disclosure.

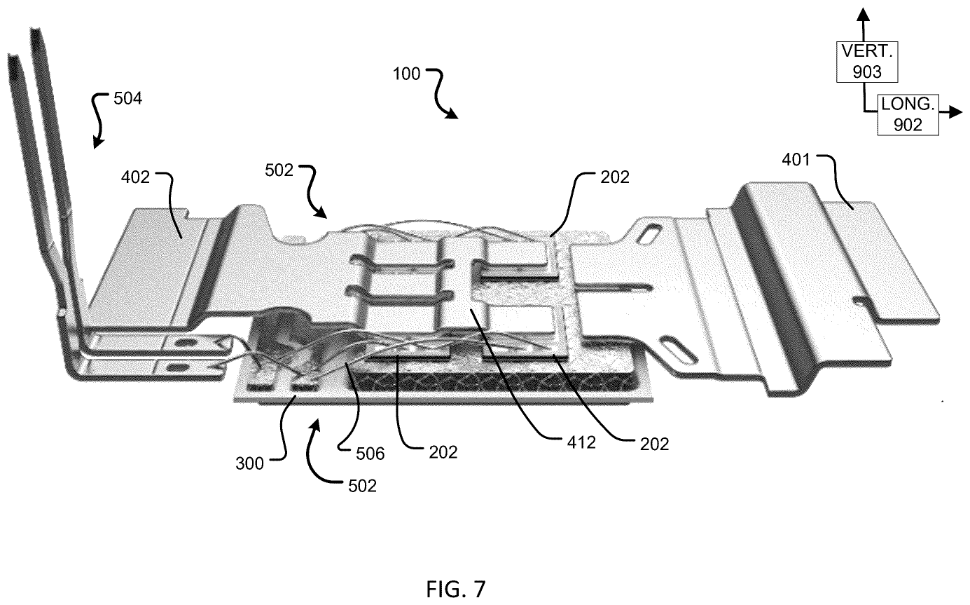

FIG. 7 illustrates a partial perspective view of another power package according to aspects of the disclosure.

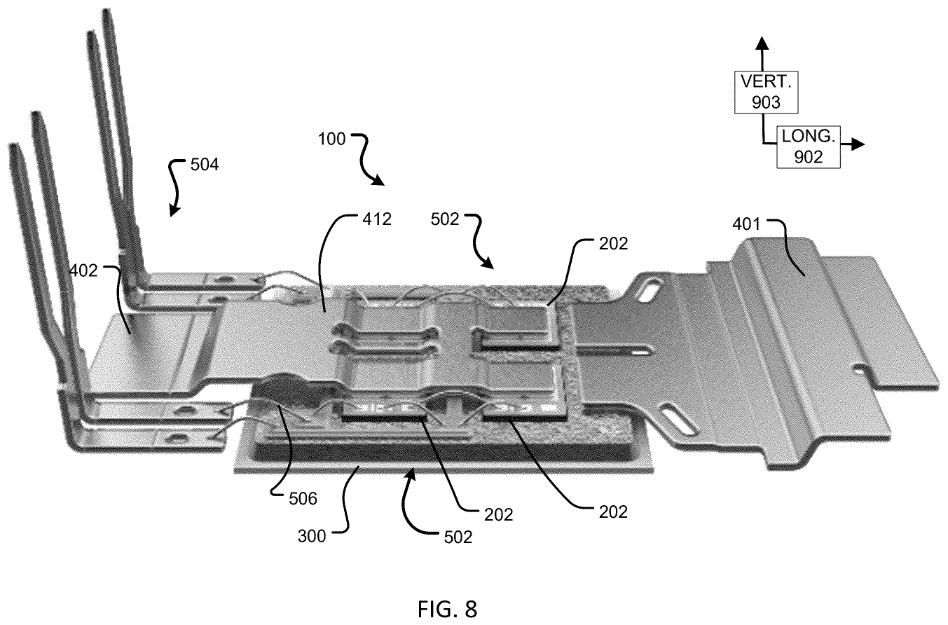

FIG. 8 illustrates a partial perspective view of another power package according to aspects of the disclosure.

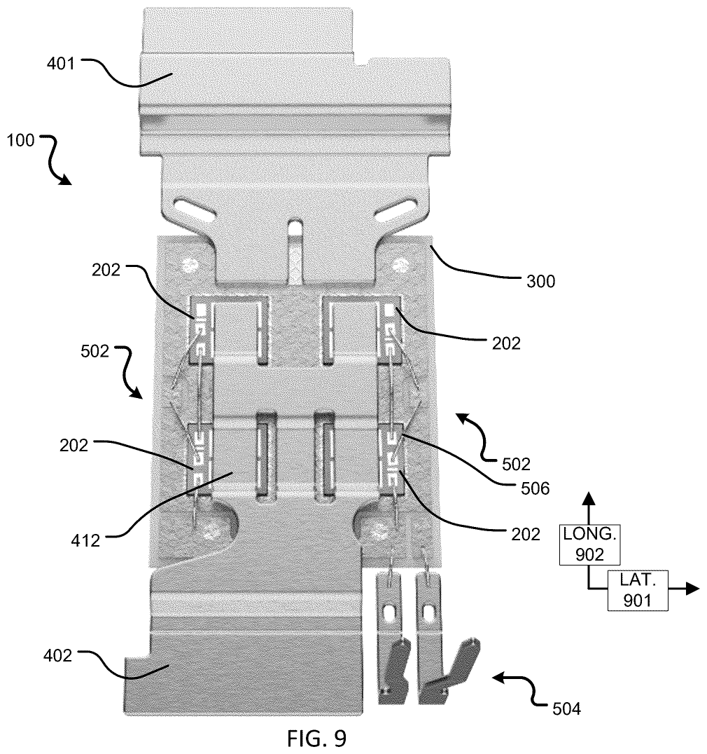

FIG. 9 illustrates a partial top view of another power package according to aspects of the disclosure.

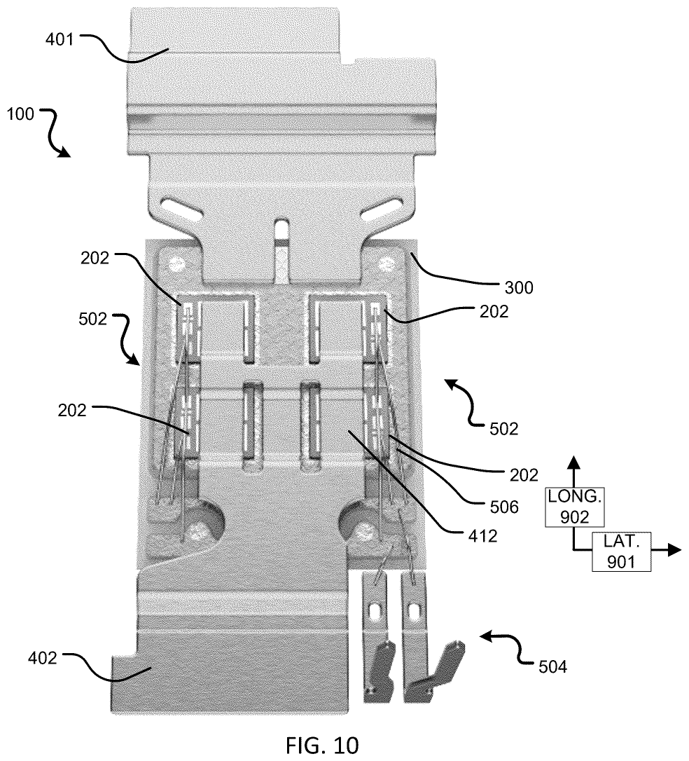

FIG. 10 illustrates a partial top view of another power package according to aspects of the disclosure.

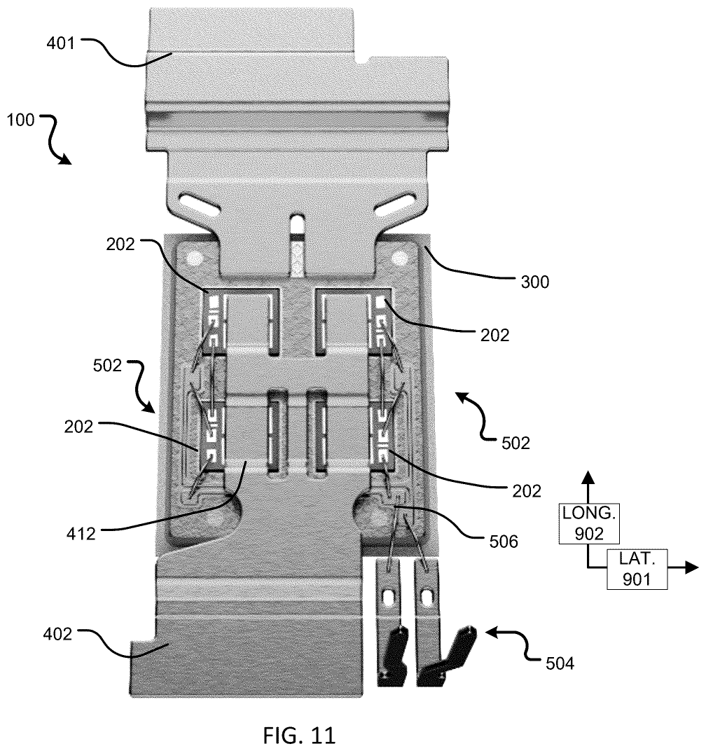

FIG. 11 illustrates a partial top view of a power package according to aspects of the disclosure.

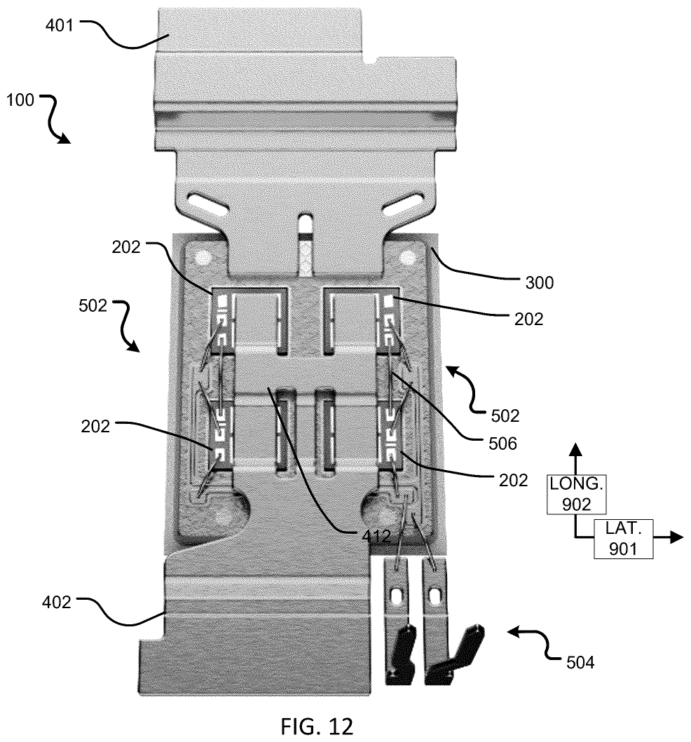

FIG. 12 illustrates a partial top view of a power package according to aspects of the disclosure.

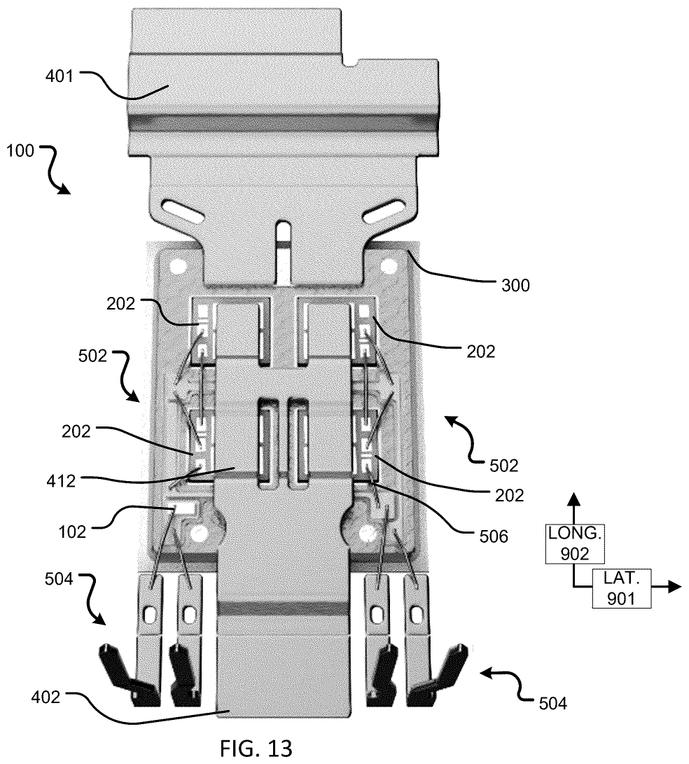

FIG. 13 illustrates a partial top view of a power package according to aspects of the disclosure.

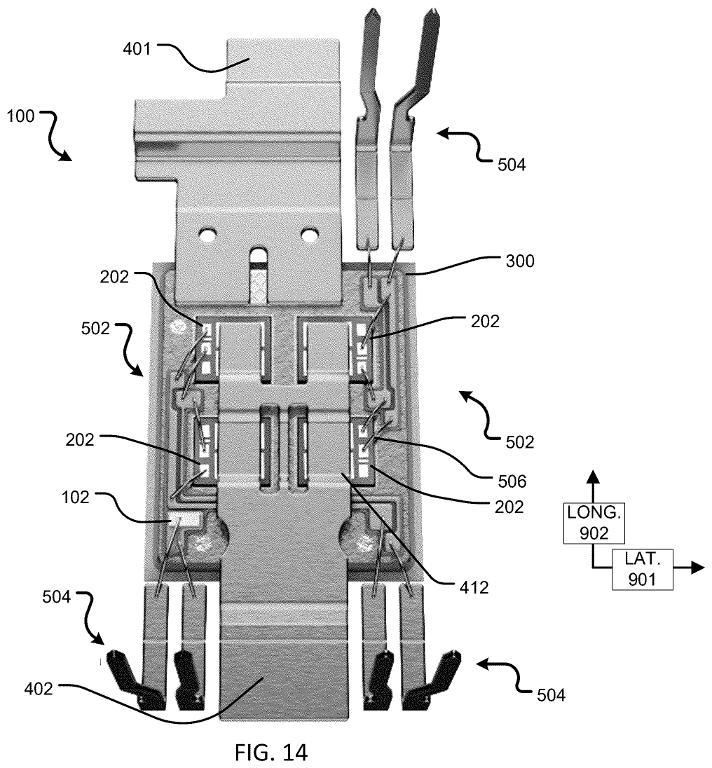

FIG. 14 illustrates a partial top view of a power package according to aspects of the disclosure.

In particular, FIGS. 1-14 illustrate partial views of a power package 100 that may include at least one power device 202, at least one power substrate 300, a first power terminal 401, a second power terminal 402, signal terminals 504, at least one signal connection assembly 502, and/or the like. In aspects, the power package 100 may be implemented as a module, a power module, a power module package, a package, and/or the like.

In aspects, the at least one signal connection assembly 502 and/or the at least one power substrate 300 may be configured to provide improved and/or optimized circuit resolution, power density, signal density, and/or the like. In aspects, the at least one signal connection assembly 502 may include and/or may connect to at least one signal interconnect 506. In this regard, the power package 100 illustrated in the figures shows numerous implementations of the at least one signal interconnect 506. However, for clarity of illustration, not all implementations of the at least one signal interconnect 506 are provided with a reference numeral.

In this disclosure, the power package 100 may be configured to include incorporation of novel technologies, components, features, layouts, and/or the like to obtain higher and/or high-density signal and power routing while further increasing and/or optimizing a performance and power density of the power package 100. Multiple layout/topology arrangements are described for devices arranged in series, arrays, and/or the like to minimize a footprint of the power package 100 while maximizing power of the power package 100.

In aspects of the power package 100, the at least one power substrate 300 and/or the at least one signal connection assembly 502 may be configured as one or more multilayer power substrates, multi-thickness substrates, and/or the like. Further, aspects of the at least one power substrate 300 and/or the at least one signal connection assembly 502 may implement various types of metal clad laminates.

In aspects, the at least one signal connection assembly 502 may be integrated on and/or within the at least one power substrate 300 to transfer signals through the at least one power substrate 300. In aspects, the at least one signal connection assembly 502 may be integrated on and/or within the at least one power substrate 300 to transfer signals between the signal terminals 504 and the at least one power device 202.

In aspects, the at least one signal connection assembly 502 may be integrated on and/or within a multilayer power substrate implementation of the at least one power substrate 300. In aspects, the at least one signal connection assembly 502 may be integrated on and/or within a multilayer power substrate implementation of the at least one power substrate 300 to transfer signals between the signal terminals 504 and the at least one power device 202.

In aspects, the at least one signal connection assembly 502 may be integrated on and/or within an internal multilayer power substrate implementation of the at least one power substrate 300. In aspects, the at least one signal connection assembly 502 may be integrated on and/or within an external multilayer power substrate implementation of the at least one power substrate 300.

In aspects, the at least one signal connection assembly 502 may be integrated on and/or within a multi-thickness substrate implementation of the at least one power substrate 300. In aspects, the at least one signal connection assembly 502 may be integrated on and/or within a multi-thickness substrate implementation of the at least one power substrate 300 to transfer signals through the at least one power substrate 300. In aspects, the at least one signal connection assembly 502 may be integrated on and/or within a multi-thickness substrate implementation of the at least one power substrate 300 to transfer signals between the signal terminals 504 and the at least one power device 202.

In aspects, the at least one signal connection assembly 502 may be integrated on and/or within a metal clad laminate implementation of the at least one power substrate 300. In aspects, the at least one signal connection assembly 502 may be integrated on and/or within a multilayer power substrate implementation of the at least one power substrate 300, a multi-thickness substrate implementation of the at least one power substrate 300, and/or a metal clad laminate implementation of the at least one power substrate 300.

In aspects, the at least one signal connection assembly 502 may be integrated on and/or within the at least one power substrate 300 such that a portion of the at least one power substrate 300 that carries power may be larger. In aspects, the at least one signal connection assembly 502 may be integrated on and/or within the at least one power substrate 300 such that a portion of the at least one power substrate 300 that carries power may be larger to maximize package footprint utilization, thermal management, switching performance, manufacturability, power density, and/or the like.

FIGS. 1-14 illustrate implementations of the power package 100 for a single switch position layout with the at least one power device 202 that may be arranged in a 2×2 array, as an example. Further, FIGS. 1-14 illustrate the various multi-layer substrate technologies discussed in this disclosure, which are conceptualized in exemplary configurations of the power package 100.

Aspects of the power package 100 may include a series of internal and external layout arrangements for a single switch position high voltage power package containing one power device or multiple power devices in parallel. In aspects, implementations of the power package 100 may include layouts that may make use of technologies such as multi-thickness substrates, multi-layer substrates, metal clad laminates, intra-module temperature sensing, intra-module current sensing, intra-module strain sensing, intra-module humidity sensing, one or multiple true source kelvins, integrated substrate geometries and enhancements to maximize package footprint utilization, thermal management, switching performance, manufacturability, power density, and/or the like. Aspects of the power package 100 may be configured and/or offer benefits to the power density, dynamic electrical performance, thermal performance, and/or the like of the power package 100, which may parallel power semiconductor devices and/or package them into a topology.

In aspects, configurations of the power package 100 may be implemented close to an industry standard product outline specification. Accordingly, configurations of the power package 100 may be commonly used in many systems which have or will adopt the standard, while also taking advantages of the specific benefits and optimizations of the given approaches.

In general, output current scales with device area, with more device area able to process more current and dissipate more waste heat from conduction, switching, and package resistance losses. Scalability is achieved with each layout able to accommodate devices of different sizes. Device positions are also modular, such that they also be fully or partially populated with devices for even more adaptability. Using both of these techniques, total active device area can be modulated to allow for a range of performance and cost targets depending on the needs of a system.

Aspects of the power package 100 may implement multiple internal configurations and layouts for power electronic devices in an industry standard external product outline. Aspects of the power package 100 may implement layout implementations for true source kelvin with one or multiple pin terminals. Aspects of the power package 100 may implement layout implementations for grouping of pin terminals by voltage classes.

Aspects of the power package 100 may implement multi-thickness substrate implementations for maximizing power loop area while minimizing signal loop trace area. Aspects of the power package 100 may implement the at least one signal connection assembly 502 with substrate routing implementations to minimize electromagnetic coupling between different current carrying loops and thus minimize the power and signal loop inductances. Aspects of the power package 100 may implement multi-layer substrate implementations to significantly increase power density using the same package footprint.

Aspects of the power package 100 may implement the at least one signal connection assembly 502 with strategic placement of buried conductors within layers of the substrate, to provide maximum electromagnetic shielding, improved and/or optimal thermal conduction, minimal loop parasitics, minimal mechanical stress, and ease of manufacturing. Aspects of the power package 100 may implement layout implementations to minimize interconnect length and loop height. Aspects of the power package 100 may implement surface and geometric enhancements to one or more components to maximize adhesion of attach materials, interconnects, lead frame, devise, sensors, laminates, and epoxy mold compound. These include, but are not limited to-plating, pattern etching, partial etching, mechanical abrasion, chemical abrasion, and textured surfaces.

Aspects of the power package 100 may implement an optional sensor to measure temperature, current, humidity/moisture, mechanical strain inside the power package 100, and/or the like. Aspects of the power package 100 may implement power interconnect implementations for direct source attach, aluminum power wire bonding, copper power wire bonding, gold power wire bonding, aluminum power ribbon bonding, copper power ribbon bonding, copper core aluminum power wire bonding, and other alloys wire materials of copper, aluminum, gold, and/or the like.

Aspects of the power package 100 may implement signal interconnect implementations may use aluminum signal wire bonding, copper signal wire bonding, gold signal wire bonding, copper trace signal routing, aluminum trace signal routing, tungsten trace signal routing, and other alloys materials of copper, aluminum, gold, silver, tungsten, and/or the like.

Aspects of the power package 100 may implement interconnect implementations to reduce package resistances and increase maximum package current. Aspects of the power package 100 may implement a physical arrangement of power devices to improve and/or optimize heat spreading for minimal thermal overlap. Aspects of the power package 100 may implement layout implementations of mechanical linkages from the lead frame to the power substrate for handling support during product manufacturing.

Aspects of the power package 100 may implement molded-in voltage creepage extenders on the bottom side of the package to improve voltage safety requirements. Aspects of the power package 100 may implement scalable device positions allowing for devices to scale up or down in length and/or width to increase output current (more device area) or reduce cost (less device area). Aspects of the power package 100 may implement modular device positions allowing for full or partial population of the up to four possible device locations.

Aspects of the power package 100 may implement modular device positions allowing for the inclusion of antiparallel diodes. Aspects of the power package 100 may implement a semi-modular lead frame with clip insert for modular switch position optimization. Aspects of the power package 100 may implement lead frame implementations for solder, sinter, direct welding, and/or the like attaches. Aspects of the power package 100 may implement surface enhancements of the backside thermal pad for improved and/or optimal heat transfer. Aspects of the power package 100 may implement geometrical enhancements such as pins, fins, grooves, trenches, blades, and/or the like, on the backside thermal pad to increase effective surface area and obtain integrated cooling with better thermal management.

In aspects, one or more of the signal terminals 504 may be configured as one or more intra-module temperature sensing terminals, intra-module current sensing terminals, intra-module strain sensing terminals, intra-module humidity sensing terminals, true Kelvin source terminals, pseudo-kelvin source terminals, gate drive terminals, drain Kelvin terminals, and/or the like.

In aspects, the signal terminals 504 may be connected to the at least one signal connection assembly 502. In aspects, the signal terminals 504 may be connected to the at least one signal connection assembly 502 that may include one or more implementations of the at least one signal interconnect 506. In aspects, separate implementations of the signal terminals 504 may be connected to separate implementations of the at least one signal connection assembly 502 that may include one or more implementations of the at least one signal interconnect 506.

In aspects, the at least one signal connection assembly 502 and/or the at least one signal interconnect 506 may be configured with and/or configured to provide signal interconnect implementations that may include aluminum signal wire bonding, copper signal wire bonding, gold signal wire bonding, copper trace signal routing, aluminum trace signal routing, tungsten trace signal routing, and other alloys materials of copper, aluminum, gold, silver, tungsten, and/or the like.

In aspects, the at least one power substrate 300 may be configured as a multi-thickness substrate, a multi-layer substrate, a metal clad laminate substrate, and/or the like. In aspects, the at least one signal connection assembly 502 may be arranged in the at least one power substrate 300, on the at least one power substrate 300, within the at least one power substrate 300, and/or the like.

In aspects, the at least one signal connection assembly 502 and/or the at least one signal interconnect 506 may be connected to the at least one power device 202. In aspects, separate implementations of the at least one signal connection assembly 502 and/or the at least one signal interconnect 506 may be connected to separate implementations of the at least one power device 202. In aspects, separate implementations of the at least one signal connection assembly 502 and/or the at least one signal interconnect 506 may be connected to different signal pads of the at least one power device 202.

In aspects, separate implementations of the at least one signal connection assembly 502 and/or the at least one signal interconnect 506 may be connected to different signal pads of at least one sensor 102. In aspects, the at least one sensor 102 may be configured to measure temperature, current, humidity/moisture, mechanical strain, and/or the like inside the power package 100. In aspects, the at least one sensor 102 may be temperature sensor, a current sensor, a humidity/moisture sensor, a mechanical strain sensor, and/or the like. In aspects, the at least one signal connection assembly 502 may be integrated on and/or within the at least one power substrate 300 to transfer signals between the signal terminals 504 and the at least one sensor 102.

In aspects, separate implementations of the at least one signal connection assembly 502 and/or the at least one signal interconnect 506 may be connected to different signal pads of other components of the power package 100.

In aspects, the at least one power device 202 may be arranged on the at least one power substrate 300. In aspects, the at least one power device 202 may be attached to the at least one power substrate 300. In aspects, the at least one power device 202 may be attached directly to the at least one power substrate 300.

In aspects, there may be any number of the at least one power device 202 arranged on the at least one power substrate 300. In aspects, there may be any number of the at least one power device 202 arranged on and along a longitudinal axis 902 of the at least one power substrate 300. In aspects, there may be any number of the at least one power device 202 arranged on and along a lateral axis 901 of the at least one power substrate 300. In aspects, there may be any number of the at least one power device 202 arranged on and along the longitudinal axis 902 of the at least one power substrate 300; and there may be any number of the at least one power device 202 arranged on and along the lateral axis 901 of the at least one power substrate 300.

Further, the at least one power device 202 may each include a source connection. In aspects, the source connection may be connected to the second power terminal 402. In aspects, the source connection may be connected to the second power terminal 402 through a power interconnect 412.

In aspects, the power interconnect 412 may implement a direct source attach, aluminum power wire bonding, copper power wire bonding, gold power wire bonding, aluminum power ribbon bonding, copper power ribbon bonding, copper core aluminum power wire bonding, and other alloys wire materials of copper, aluminum, gold, and/or the like.

Additionally, the at least one power device 202 may include a drain connection. In aspects, the drain connection may be connected to the at least one power substrate 300. In aspects, the drain connection may be directly arranged on the at least one power substrate 300. In aspects, the at least one power substrate 300 may be connected to the first power terminal 401.

FIGS. 1-14 show various arrangements, implementations, constructions, and/or the like of the at least one signal connection assembly 502. Additionally, FIGS. 1-14 show various arrangements and constructions of the first power terminal 401, the second power terminal 402, the signal terminals 504, and/or the like. Notably, FIG. 5 illustrates the power package 100 with the at least one power substrate 300 partially removed to illustrate an implementation of the at least one signal connection assembly 502 arranged below a surface of the at least one power substrate 300.

The aspects of the power package 100 illustrated in FIGS. 1-14 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 1-14.

As further detailed below, the disclosure explores a number of ways of increasing power and signal density in the power package 100 and improving the switching performance of the power package 100. These technologies/designs can be used independently or in combination with each other to achieve maximum performance. In particular, the power package 100 may implement the at least one power substrate 300 as a multi-thickness substrate, an internal multi-layer substrate, an external multi-layer substrate, and/or a combination of the previously noted substrate configurations.

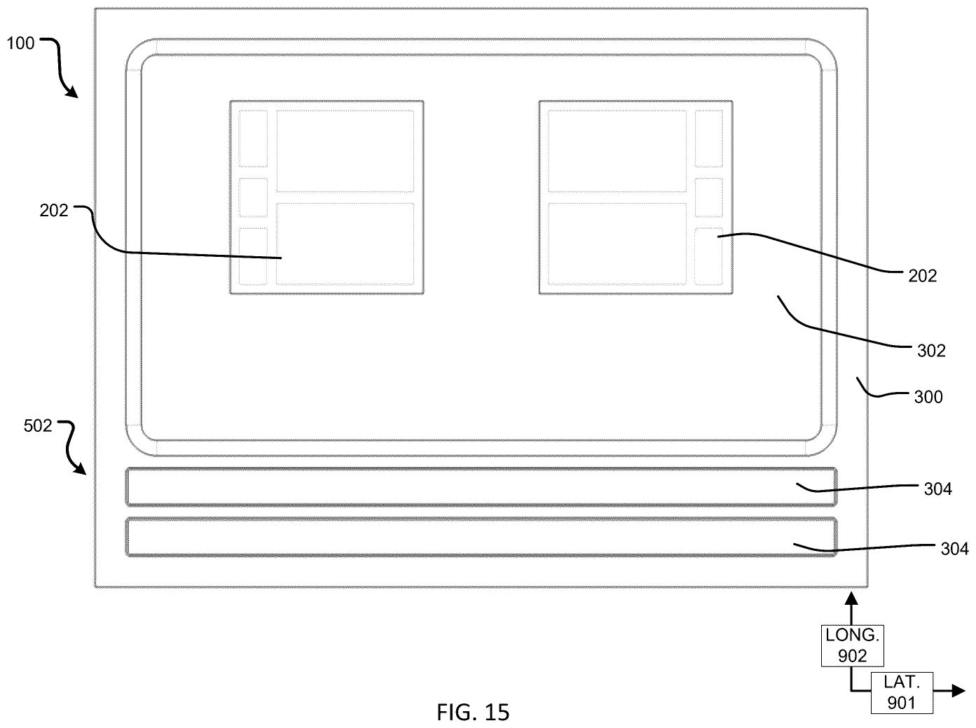

FIG. 15 illustrates a partial top view of a power package according to aspects of the disclosure.

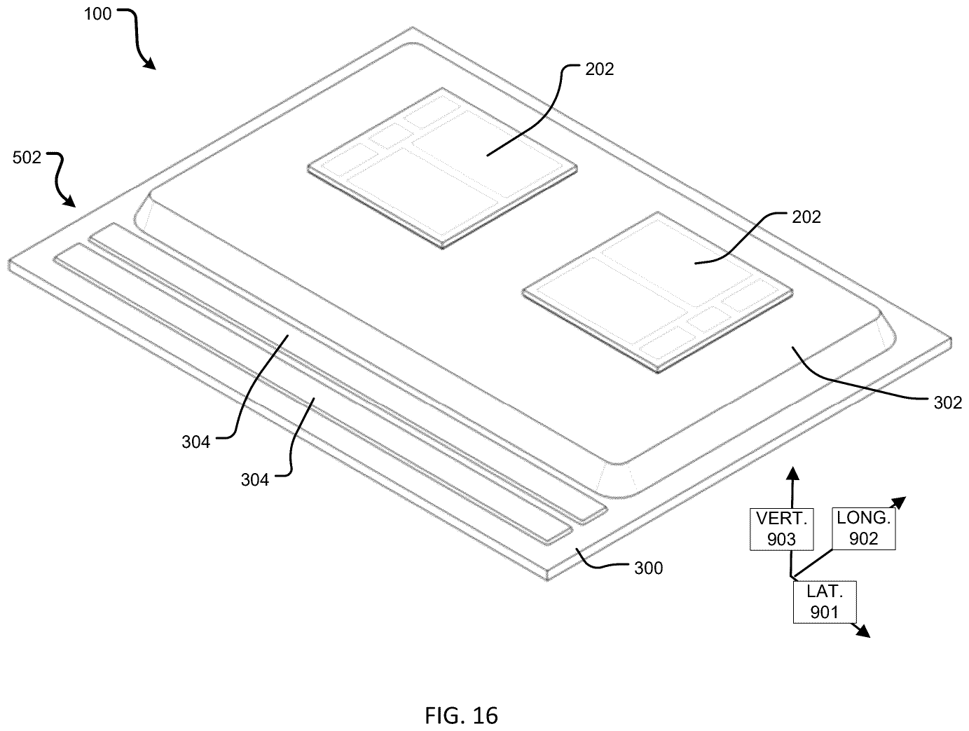

FIG. 16 illustrates a partial perspective view of the power package according to FIG. 15.

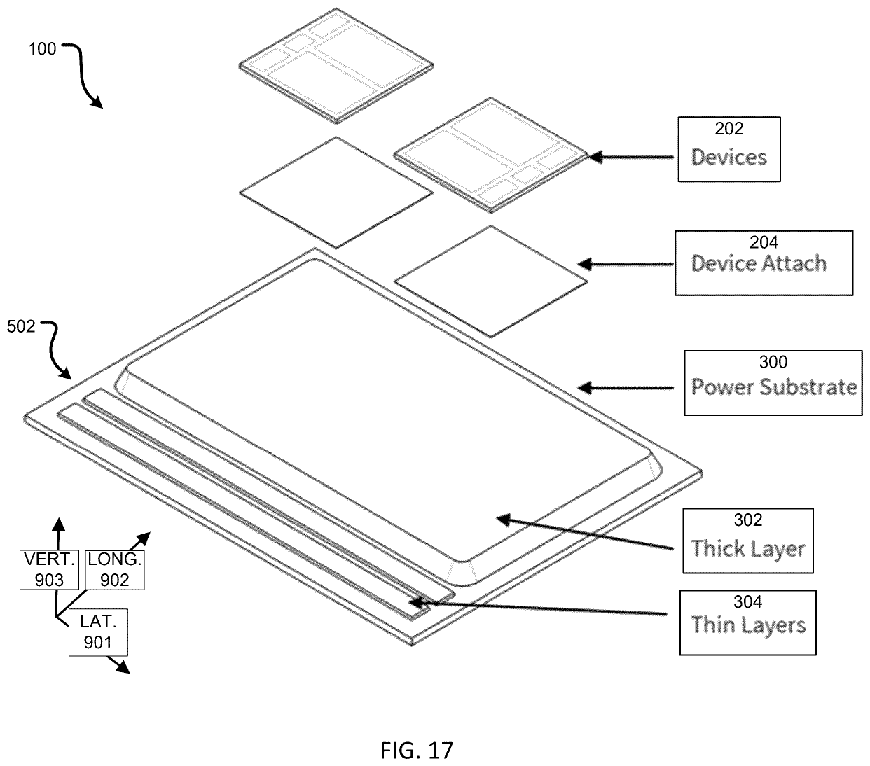

FIG. 17 illustrates an exploded partial perspective view of the power package according to FIG. 15.

In particular, FIGS. 15-17 illustrate that the power package 100 may implement the at least one power substrate 300 as a multi-thickness substrate. In particular aspects, the at least one power substrate 300 may be a layered structure of metal and ceramic, layered thick printed circuit board (PCB), thick film printed on organic/inorganic laminate, and/or the like.

This configuration of the at least one power substrate 300 may be configured to provide high current electrical interconnection, high voltage isolation, high thermal conductivity, co-efficient of thermal expansion (CTE) matching, an external thermal interface with surface and geometrical enhancements, and/or the like. In aspects, the multi-thickness power substrate configuration of the at least one power substrate 300 may be configured with multiple metal traces of varying thicknesses to provide improved and/or optimized circuit resolution, power density, signal density, and/or the like.

With reference to FIG. 15, the at least one power substrate 300 may include a power trace 302 and at least one signal trace 304. In aspects, the at least one signal trace 304 may be or may be part of the at least one signal connection assembly 502. In aspects, the power trace 302 and/or the at least one signal trace 304 may be arranged on a dielectric, a dielectric portion, a dielectric layer, and/or the like of the at least one power substrate 300. In aspects, the at least one signal connection assembly 502 may be configured with the at least one signal trace 304 that is thinner than the power trace 302. In aspects, the at least one signal connection assembly 502 may be configured such that the at least one signal trace 304 is thinner than the power trace 302 along a vertical axis, which allows the power trace 302 to be larger.

The power trace 302 may be arranged adjacent the at least one signal trace 304. In aspects, there may be single implementation of the at least one signal trace 304, two implementations of the at least one signal trace 304, or more than two implementations of the at least one signal trace 304. In aspects, a surface of the at least one signal trace 304 may be arranged in a plane parallel to the lateral axis 901 and the longitudinal axis 902. Further, the surface of the at least one signal trace 304 may extend along the lateral axis 901 and the longitudinal axis 902.

In aspects, the at least one power device 202 may be arranged on a surface of the power trace 302. The surface of the power trace 302 may be arranged in a plane parallel to the lateral axis 901 and the longitudinal axis 902. Further, the surface of the power trace 302 may extend along the lateral axis 901 and the longitudinal axis 902. In aspects, the at least one power device 202 may be arranged on the power trace 302. In aspects, the at least one power device 202 may be attached to the power trace 302. In aspects, the at least one power device 202 may be attached directly to the power trace 302.

As illustrated in FIG. 16, the at least one signal trace 304 may have a thickness along a vertical axis 903; and the power trace 302 may have a thickness along a vertical axis 903. In this regard, the thickness of the power trace 302 along the vertical axis 903 may be greater than the thickness of the at least one signal trace 304 along the vertical axis 903.

In other words, a thickness of the at least one signal trace 304 along the vertical axis 903 is thinner than a thickness of the power trace 302 along the vertical axis 903. Accordingly, the at least one signal trace 304 may likewise be smaller along the lateral axis 901 and the longitudinal axis 902 because the at least one signal trace 304 is thinner along the vertical axis 903. Accordingly, the power trace 302 may be configured to be larger along the lateral axis 901 and the longitudinal axis 902.

In aspects, the power package 100 and/or the at least one power substrate 300 may be configured such that the at least one signal trace 304 is thinner than the power trace 302 along the vertical axis 903, which allows the power trace 302 to be larger. In aspects, the power package 100 and/or the at least one power substrate 300 may be configured such that the at least one signal trace 304 is thinner than the power trace 302 along the vertical axis 903, which allows the at least one signal trace 304 to be smaller along the lateral axis 901 and the longitudinal axis 902 in which allows the power trace 302 to be larger. Thus, a larger implementation of the power trace 302 may have greater current carrying capability, greater thermal conduction, greater power density using the same package footprint, reduced mechanical stress, and/or the like. Further, a smaller implementation of the at least one signal trace 304 may minimize electromagnetic coupling between different current carrying loops, reduce power and signal loop inductances, increase manufacturability, and/or the like.

Accordingly, the configuration of the at least one power substrate 300 including the power trace 302 and the at least one signal trace 304 may be configured to provide improved and/or optimized circuit resolution, power density, signal density, and/or the like.

In aspects, the thickness of the power trace 302 along the vertical axis 903 may be greater than two times, three times, four times, five times, six times, seven times, eight times, nine times, ten times, or more, greater than the thickness of the at least one signal trace 304 along the vertical axis 903.

In aspects, the thickness of the power trace 302 along the vertical axis 903 may be two times to four times, four times to six times, six times to eight times, or eight times to ten times greater than the thickness of the at least one signal trace 304 along the vertical axis 903.

FIG. 17 illustrates that the at least one power device 202 may be attached to the power trace 302 of the at least one power substrate 300 with a die attach 204. In aspects, the die attach 204 may include and/or may implement solder, sinter, conductive adhesive, direct welding, and/or the like.

In aspects, implementations of the power package 100 may further include implementations of the at least one signal interconnect 506 (not shown) extending between the at least one signal trace 304 and the signal terminals 504. In aspects, implementations of the power package 100 may further include implementations of the at least one signal interconnect 506 (not shown) extending between the at least one signal trace 304 and the at least one power device 202.

The aspects of the power package 100 illustrated in FIGS. 15-17 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 15-17.

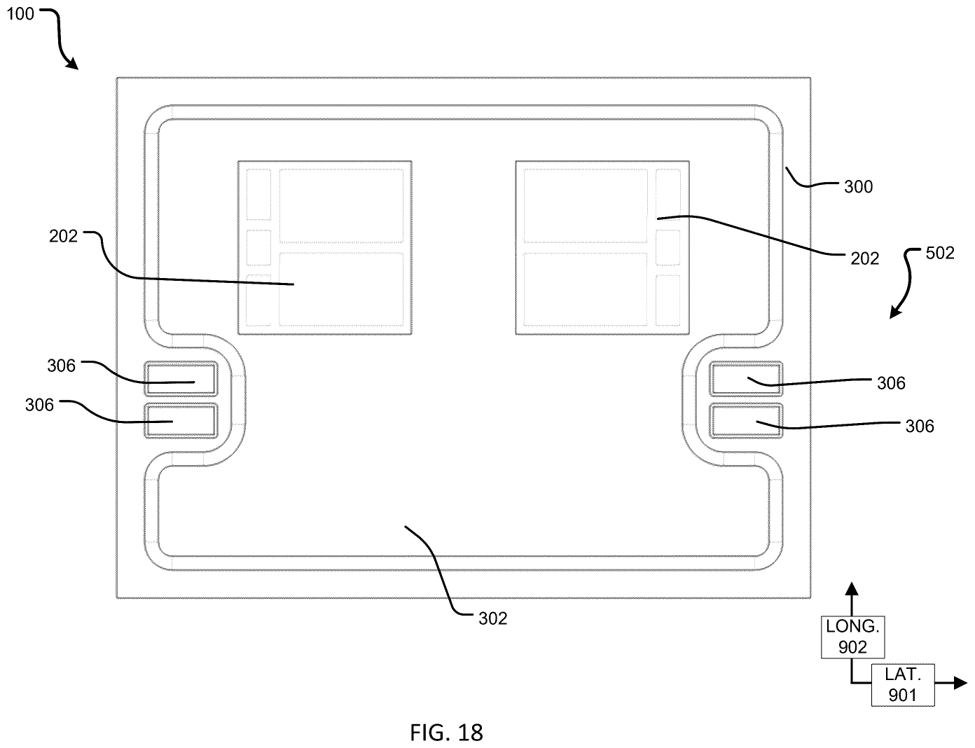

FIG. 18 illustrates a partial top view of a power package according to aspects of the disclosure.

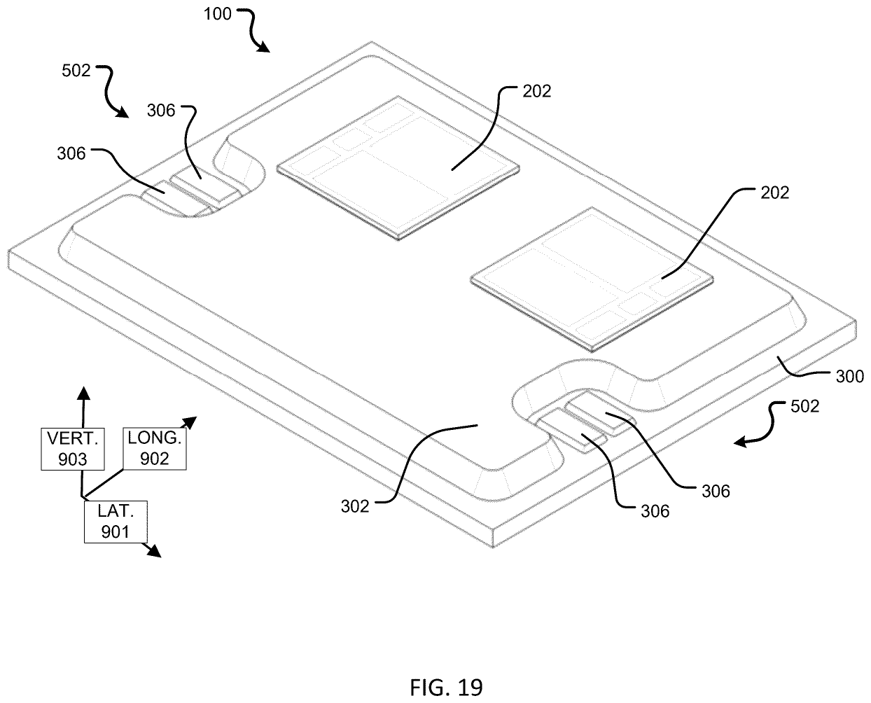

FIG. 19 illustrates a partial perspective view of a power package according to FIG. 18.

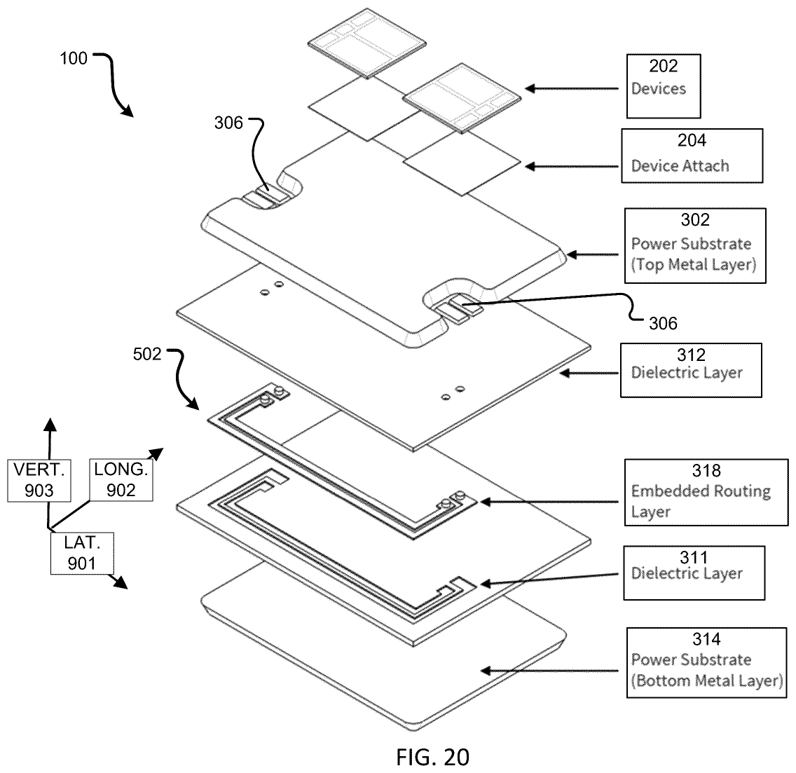

FIG. 20 illustrates a partial exploded perspective view of a power package according to FIG. 18.

In particular, FIGS. 18-20 illustrate that the power package 100 may implement the at least one power substrate 300 as an internal multi-layer substrate. Similar to a multi-layered printed circuit board, the internal multi-layer power substrate implementation of the at least one power substrate 300 may contain metallic/conductive layers interspersed by electrically insulating layers. In aspects, the internal multi-layer power substrate implementation of the at least one power substrate 300 may contain three or more metallic/conductive layers interspersed by electrically insulating layers. In aspects, the multi-layer composite power and signal substrates may be configured to have thicker metallic layers for high-current, high-power applications with higher voltage insulating capability while having thin metallic layers for conducting switching and sensing signals.

With reference to FIG. 18, the at least one power substrate 300 may include the power trace 302 and at least one signal pad trace 306. In aspects, the at least one signal pad trace 306 may be or may be part of the at least one signal connection assembly 502.

The power trace 302 may be arranged adjacent the at least one signal pad trace 306. In aspects, the power trace 302 may be arranged on at least one side, two sides, or three sides of the at least one signal pad trace 306.

In aspects, there may be single implementation of the at least one signal pad trace 306, two implementations of the at least one signal pad trace 306, three implementations of the at least one signal pad trace 306, four implementations of the at least one signal pad trace 306, or more than four implementations of the at least one signal pad trace 306. In aspects, a surface of the at least one signal pad trace 306 may be arranged in a plane parallel to the lateral axis 901 and the longitudinal axis 902. Further, the surface of the at least one signal pad trace 306 may extend along the lateral axis 901 and the longitudinal axis 902.

As noted in FIG. 19, the at least one signal pad trace 306 may have a thickness along a vertical axis 903; and the power trace 302 may have a thickness along the vertical axis 903. In this regard, the thickness of the power trace 302 along the vertical axis 903 may be greater than the thickness of the at least one signal pad trace 306 along the vertical axis 903. Accordingly, the configuration of the at least one power substrate 300 including the power trace 302 and the at least one signal pad trace 306 may be configured to provide improved and/or optimized circuit resolution, power density, signal density, and/or the like.

In aspects, the thickness of the power trace 302 along the vertical axis 903 may be greater than two times, three times, four times, five times, six times, seven times, eight times, nine times, ten times, or more, greater than the thickness of the at least one signal pad trace 306 along the vertical axis 903.

In aspects, the thickness of the power trace 302 along the vertical axis 903 may be two times to four times, four times to six times, six times to eight times, or eight times to ten times greater than the thickness of the at least one signal pad trace 306 along the vertical axis 903.

In other words, a thickness of the at least one signal pad trace 306 along the vertical axis 903 is thinner than a thickness of the power trace 302 along the vertical axis 903. Accordingly, the at least one signal pad trace 306 may likewise be smaller along the lateral axis 901 and the longitudinal axis 902 because the at least one signal pad trace 306 is thinner along the vertical axis 903. Accordingly, the power trace 302 may be larger along the lateral axis 901 and the longitudinal axis 902.

In aspects, the power package 100 and/or the at least one power substrate 300 may be configured such that the at least one signal pad trace 306 is thinner than the power trace 302 along the vertical axis 903, which allows the power trace 302 to be larger. In aspects, the power package 100 and/or the at least one power substrate 300 may be configured such that the at least one signal pad trace 306 is thinner than the power trace 302 along the vertical axis 903, which allows the at least one signal pad trace 306 to be smaller along the lateral axis 901 and the longitudinal axis 902 in which allows the power trace 302 to be larger. Thus, a larger implementation of the power trace 302 may have greater current carrying capability, greater thermal conduction, greater power density using the same package footprint, reduced mechanical stress, and/or the like. Further, a smaller implementation of the at least one signal pad trace 306 may minimize electromagnetic coupling between different current carrying loops, reduce power and signal loop inductances, increase manufacturability, and/or the like.

FIG. 20 illustrates that the at least one power device 202 may be attached to the power trace 302 of the at least one power substrate 300 with the die attach 204. In aspects, the die attach 204 may include and/or may implement solder, sinter, conductive adhesive, direct welding, and/or the like.

Additionally, FIG. 20 illustrates that the power package 100 and/or the at least one power substrate 300 may further include a bottom metal layer 314. A first dielectric layer 311 may be arranged on the bottom metal layer 314. In aspects, the first dielectric layer 311 may be directly arranged on the bottom metal layer 314.

Further, the power package 100 and/or the at least one power substrate 300 may include an embedded routing layer 318. In aspects, the embedded routing layer 318 may connect opposing implementations of the at least one signal pad trace 306. In aspects, the first dielectric layer 311 may include recessed areas that are configured to receive the embedded routing layer 318. In aspects, the at least one signal connection assembly 502 may be configured with the embedded routing layer 318 within the at least one power substrate 300. In aspects, the at least one signal connection assembly 502 may be configured with the embedded routing layer 318 below the power trace 302. In aspects, the at least one signal connection assembly 502 may be configured with the at least one signal pad trace 306 connected to the embedded routing layer 318.

Additionally, the power package 100 and/or the at least one power substrate 300 may include a second dielectric layer 312 arranged on the embedded routing layer 318 and/or the first dielectric layer 311. In aspects, the second dielectric layer 312 may include apertures allowing for vias of the embedded routing layer 318 to extend through and connect to the at least one signal pad trace 306. Further, the power trace 302 and the at least one signal pad trace 306 may be arranged on the second dielectric layer 312.

In aspects, implementations of the power package 100 may further include implementations of the at least one signal interconnect 506 (not shown) extending between the at least one signal pad trace 306 and the signal terminals 504. In aspects, implementations of the power package 100 may further include implementations of the at least one signal interconnect 506 (not shown) extending between the at least one signal pad trace 306 and the at least one power device 202.

The aspects of the power package 100 illustrated in FIGS. 18-20 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 18-20.

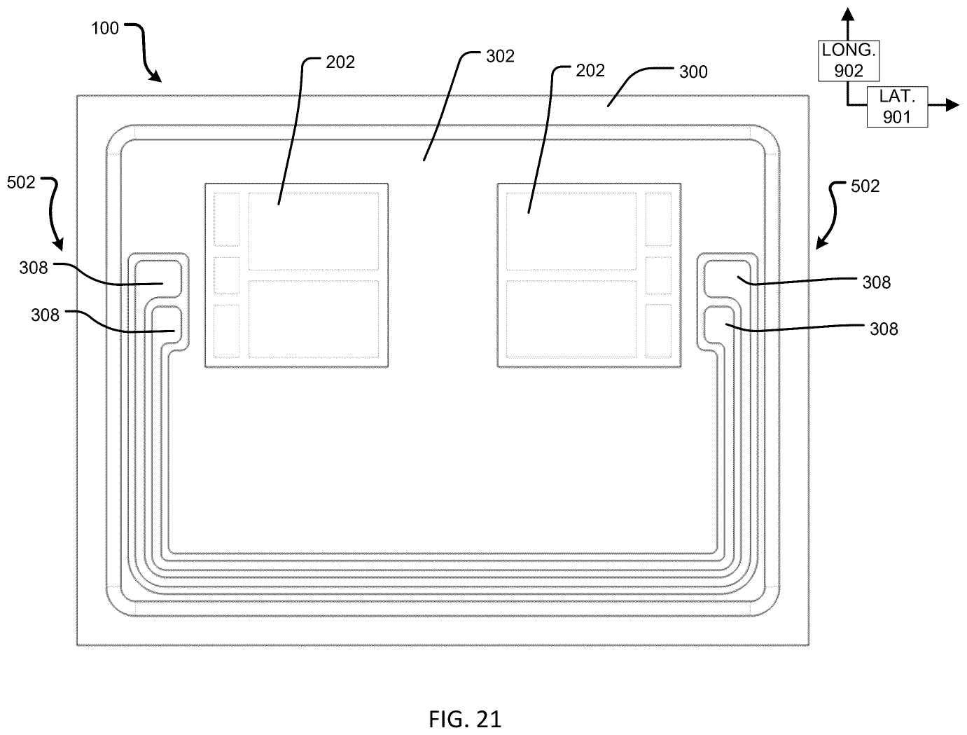

FIG. 21 illustrates a partial top view of a power package according to aspects of the disclosure.

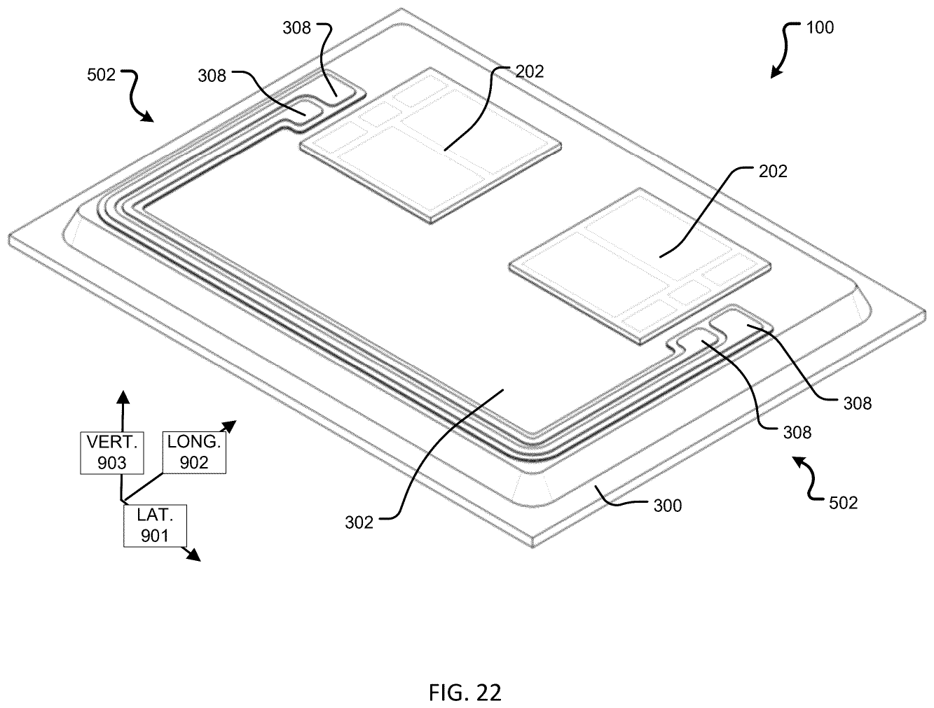

FIG. 22 illustrates a partial perspective view of a power package according to FIG. 21.

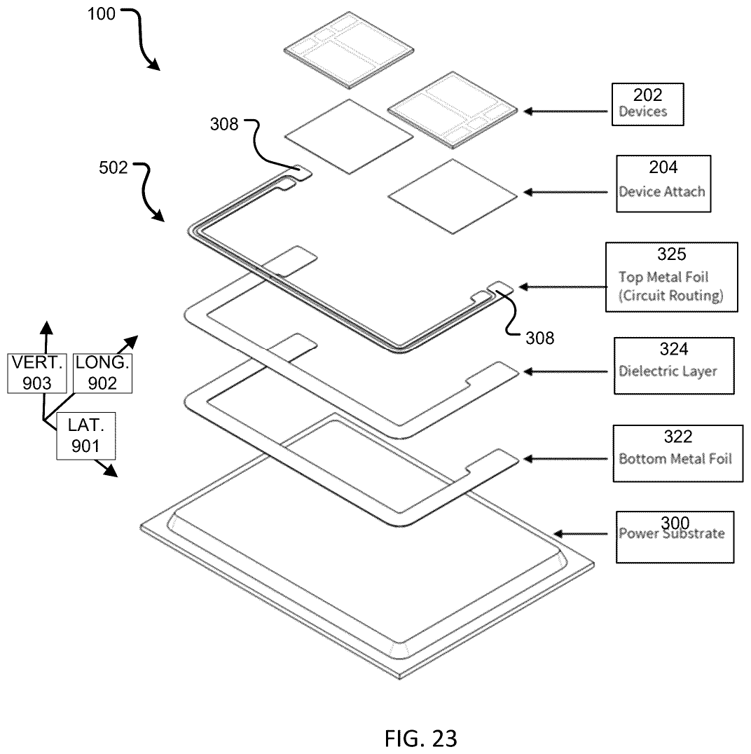

FIG. 23 illustrates a partial exploded perspective view of a power package according to FIG. 21.

In particular, FIGS. 21-23 illustrate that the power package 100 may implement the at least one power substrate 300 as an external multi-layer substrate. In aspects, the external multi-layer implementation of the at least one power substrate 300 may include the at least one signal connection assembly 502 implementing one or more than one routing layer added externally to the at least one power substrate 300 that may be configured to conduct signals and increase a power density of the power package 100.

In aspects, an effective way of adding external layers on the at least one power substrate 300 and/or the power trace 302 may be through metal clad laminates (MCLs). In aspects, the MCLs may be soldered, sintered, tacked, and/or the like onto the surface of the at least one power substrate 300, the power trace 302, and/or the like. In aspects, the MCL layouts may also be achieved through direct printing of insulating and conductive pastes onto the at least one power substrate 300 and/or the power trace 302.

With reference to FIG. 21, the at least one power substrate 300 may include the power trace 302 and at least one routing layer 308. In aspects, the at least one routing layer 308 may be or may be part of the at least one signal connection assembly 502. In aspects, the at least one routing layer 308 may be arranged on the power trace 302. In aspects, the at least one signal connection assembly 502 may be configured with the at least one routing layer 308 on the at least one power substrate 300. In aspects, the at least one signal connection assembly 502 may be configured with the at least one routing layer 308 on the at least one power substrate 300. In aspects, the at least one signal connection assembly 502 may be configured with the at least one routing layer 308 is on the power trace 302.

In aspects, the at least one routing layer 308 may be configured as one or more added external layers on the at least one power substrate 300 and/or the power trace 302 that may be configured through metal clad laminates (MCLs). In aspects, the MCL configuration of the at least one routing layer 308 may be soldered, sintered, tacked, and/or the like onto the surface of the at least one power substrate 300, the power trace 302, and/or the like. In aspects, the MCL configuration of the at least one routing layer 308 may be configured through direct printing of insulating and conductive pastes onto the at least one power substrate 300.

As the at least one routing layer 308 may be arranged on the power trace 302, the power trace 302 may be larger along the lateral axis 901 and the longitudinal axis 902. Thus, a larger implementation of the power trace 302 may have greater current carrying capability, greater thermal conduction, greater power density using the same package footprint, reduced mechanical stress, and/or the like.

In aspects, implementations of the power package 100 may further include implementations of the at least one signal interconnect 506 (not shown) extending between the at least one routing layer 308 and the signal terminals 504. In aspects, implementations of the power package 100 may further include implementations of the at least one signal interconnect 506 (not shown) extending between the at least one routing layer 308 and the at least one power device 202.

FIG. 23 illustrates that the at least one power device 202 may be attached to the power trace 302 of the at least one power substrate 300 with the die attach 204. In aspects, the die attach 204 may include and/or may implement solder, sinter, conductive adhesive, direct welding, and/or the like.

Additionally, FIG. 23 illustrates that the at least one signal connection assembly 502 may further include a bottom metal foil 322 arranged on the at least one power substrate 300. In aspects, the bottom metal foil 322 may be arranged directly on the at least one power substrate 300.

Further, FIG. 23 illustrates that the at least one signal connection assembly 502 may further include a dielectric layer 324 arranged on the bottom metal foil 322. In aspects, the dielectric layer 324 may be arranged directly on the bottom metal foil 322.

Additionally, FIG. 23 illustrates that the at least one signal connection assembly 502 may further include a top metal foil 325 arranged on the dielectric layer 324. In aspects, the top metal foil 325 may be arranged directly on the dielectric layer 324. In aspects, the construction of the bottom metal foil 322, the dielectric layer 324, the top metal foil 325, and/or the like may form the at least one signal connection assembly 502 and/or the at least one routing layer 308.

In aspects, one or more terminal ends of the at least one routing layer 308 and/or the top metal foil 325 may include wider portions. In aspects, the wider portions of the at least one routing layer 308 and/or the top metal foil 325 may form bond pads for the at least one signal interconnect 506 to connect and further connect to the at least one power device 202. In aspects, the wider portions of the at least one routing layer 308 and/or the top metal foil 325 may be arranged adjacent the at least one power device 202.

In further aspects of the power package 100, the at least one signal connection assembly 502 may be configured with the at least one signal trace 304, the at least one signal pad trace 306, the embedded routing layer 318, and/or the at least one routing layer 308 to provide improved and/or optimized circuit resolution, power density, signal density, and/or the like.

The aspects of the power package 100 illustrated in FIGS. 21-23 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 21-23.

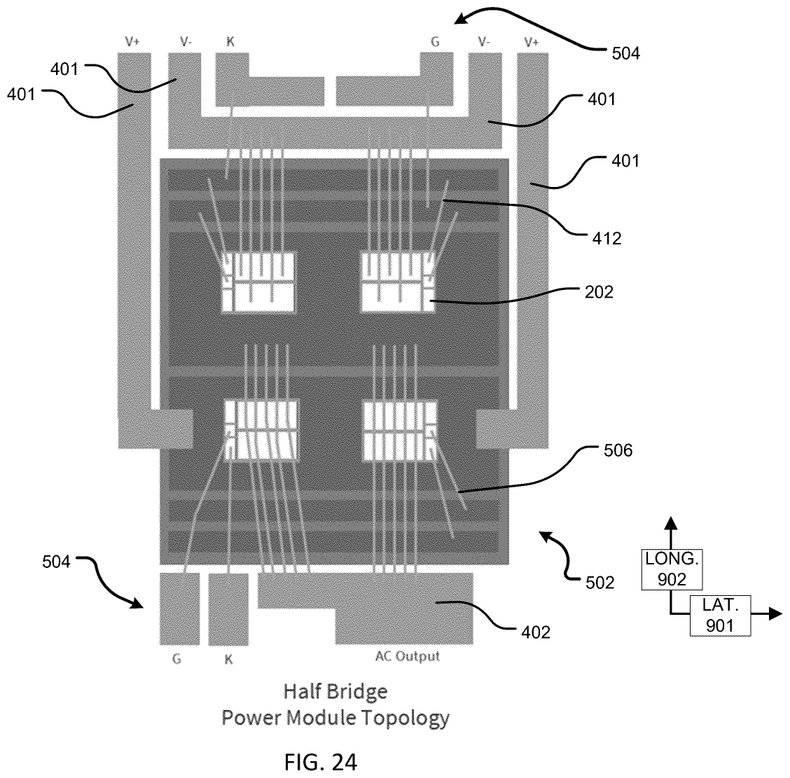

FIG. 24 illustrates a partial top view of a power package according to aspects of the disclosure.

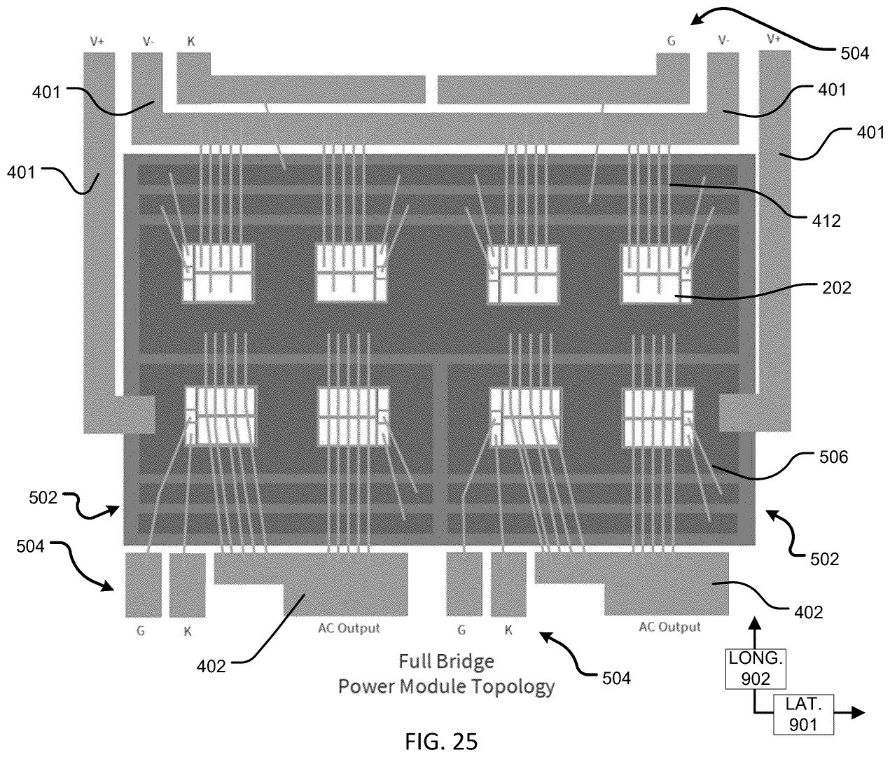

FIG. 25 illustrates a partial top view of a power package according to aspects of the disclosure.

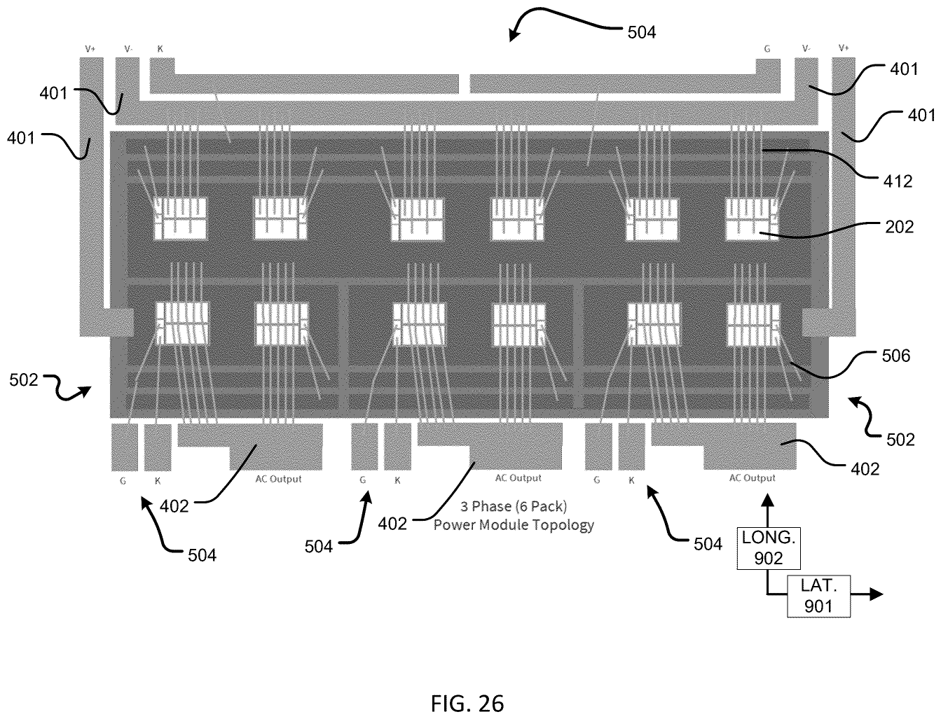

FIG. 26 illustrates a partial top view of a power package according to aspects of the disclosure.

In particular, FIGS. 24-26 illustrate implementations of the power package 100 implementing the various technologies of the at least one signal connection assembly 502. These technologies are not just limited to single switch position implementations of the power package 100, but also may extend to implementations of the power package 100 with topologies such as a half bridge implementation of the power package 100 illustrated in FIG. 24, a full bridge implementation of the power package 100 illustrated in FIG. 25, a 3-phase (6 pack) implementation of the power package 100 illustrated in FIG. 26.

Additionally, it should be noted that the power package 100 illustrated in FIGS. 24-26 may include multiple implementations of the first power terminal 401, the second power terminal 402, the signal terminals 504, the at least one signal interconnect 506, the at least one signal connection assembly 502, and/or the like.

Further, the power package 100 illustrated in FIGS. 24-26 show numerous implementations of the at least one power device 202, the at least one signal interconnect 506, and/or the like. However, for clarity of illustration, not all implementations are provided with a reference numeral. Further, these technologies may be used in implementations of the power package 100, such as case style modules, overmolded style modules, and/or the like.

The aspects of the power package 100 illustrated in FIGS. 24-26 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 24-26.

As further described below, implementations of the power package 100 may implement multiple additional routing layers (internal and external) and the multi-thickness substrate routing layer can be configured and designed in several different ways based on the power module design and optimization goals. These routing traces can be orthogonal to the primary power loop, parallel to it, parallel and orthogonal to it, winged on two sides, or any custom contoured design aimed at improving and/or optimizing manufacturing, cost, efficiency, features, ease of system integration, and/or the like of the power package 100.

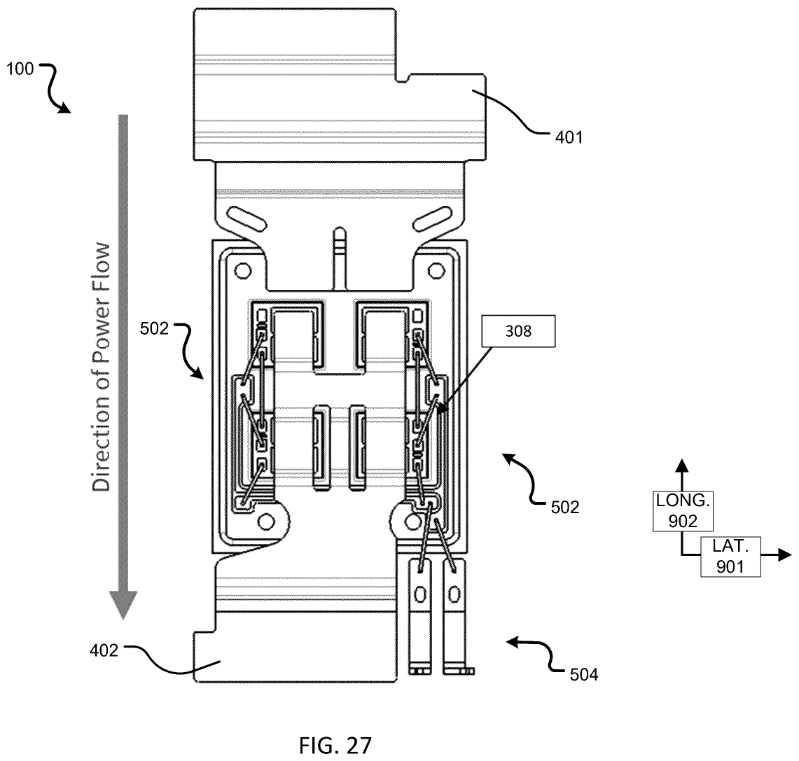

FIG. 27 illustrates a partial top view of a power package according to aspects of the disclosure.

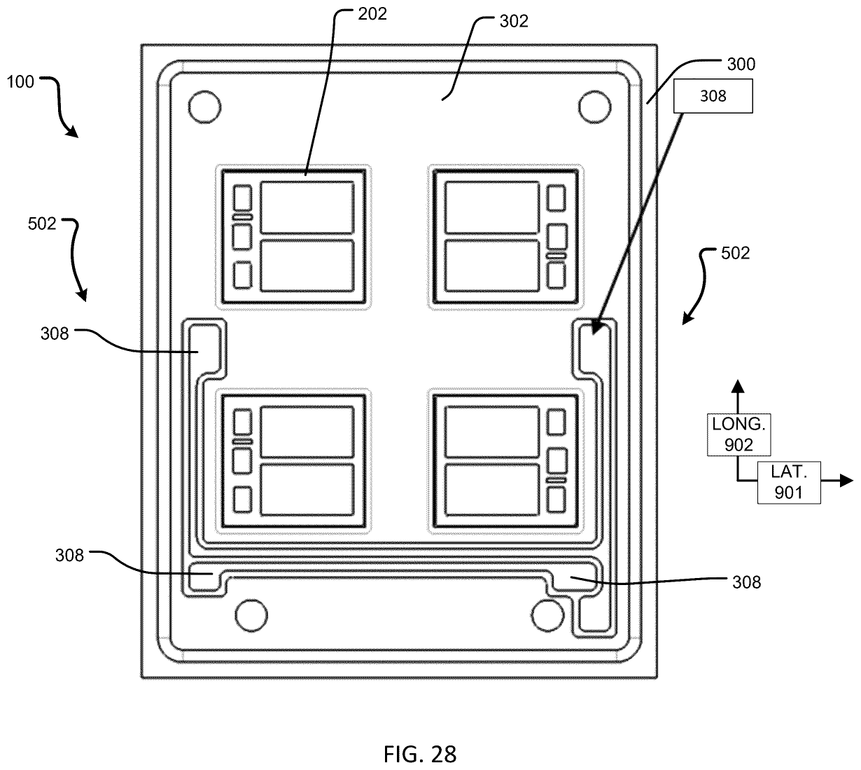

FIG. 28 illustrates a partial top view of a power package according to FIG. 27.

In aspects, the power package 100 may implement orthogonal routing of the at least one signal connection assembly 502 as illustrated in FIG. 27 and FIG. 28 with an external multi-layer implementation of the at least one power substrate 300. In aspects, the orthogonal routing of the at least one signal connection assembly 502 may be implemented such that a majority of the routing traces may be configured and designed to be perpendicular to the high current power loop in order to minimize a magnetic coupling disturbance of the power loop onto a signal loop that carries the high frequency switching signals and/or the sensing signals within the power package 100.

The aspects of the power package 100 illustrated in FIGS. 27-28 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 27-28.

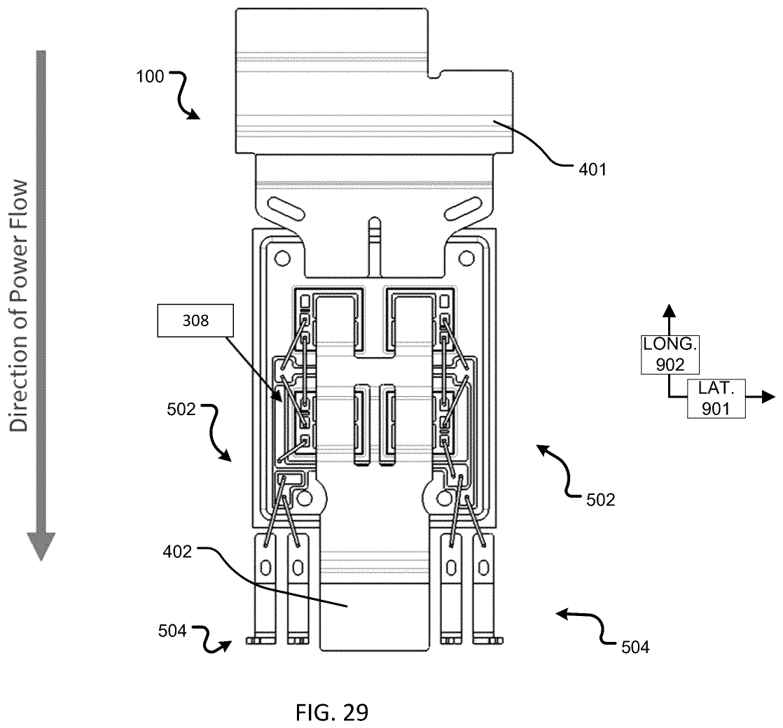

FIG. 29 illustrates a partial top view of a power package according to aspects of the disclosure.

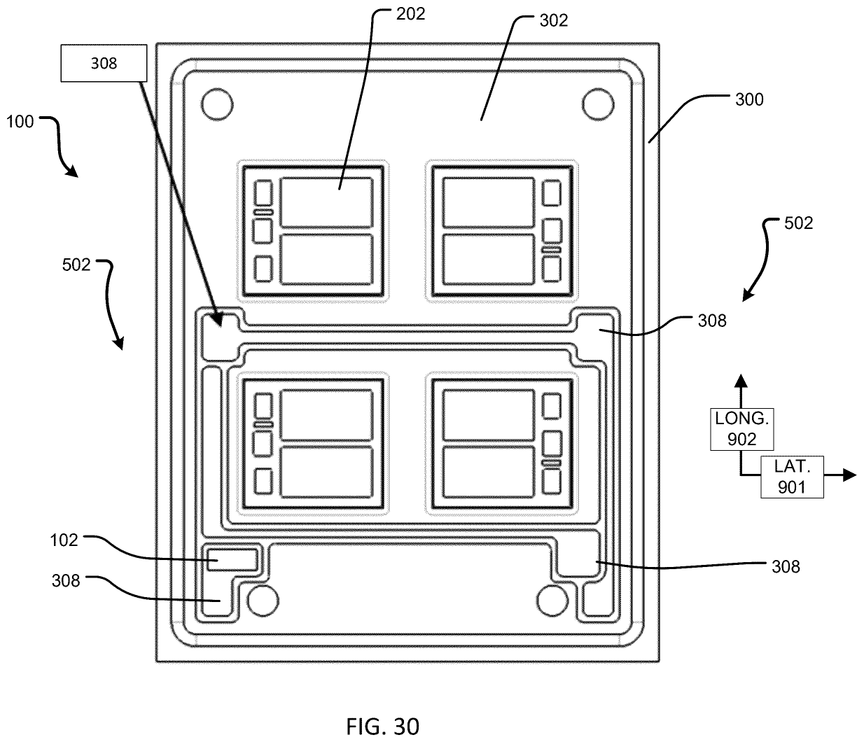

FIG. 30 illustrates a partial top view of a power package according to aspects of the disclosure.

In aspects, the power package 100 may implement contoured routing of the at least one signal connection assembly 502 and/or the at least one routing layer 308 with an external multi-layer implementation of the at least one power substrate 300. In aspects, the contoured routing of the at least one signal connection assembly 502 and/or the at least one routing layer 308 may be implemented such that the signal routing trace layout may be configured and designed to contour most efficiently around the power trace pattern, the power device position, and the terminal/pin out position. This routing configuration aims to minimize the signal loop inductance, cost, and material while maximizing manufacturability, component integration, and processability.

The aspects of the power package 100 illustrated in FIGS. 29-30 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 29-30.

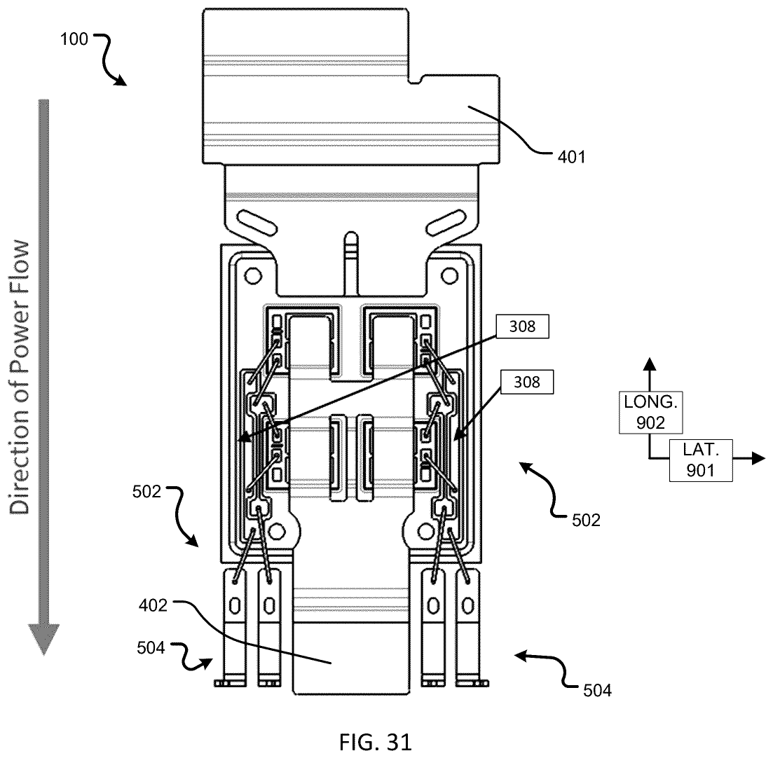

FIG. 31 illustrates a partial top view of a power package according to aspects of the disclosure.

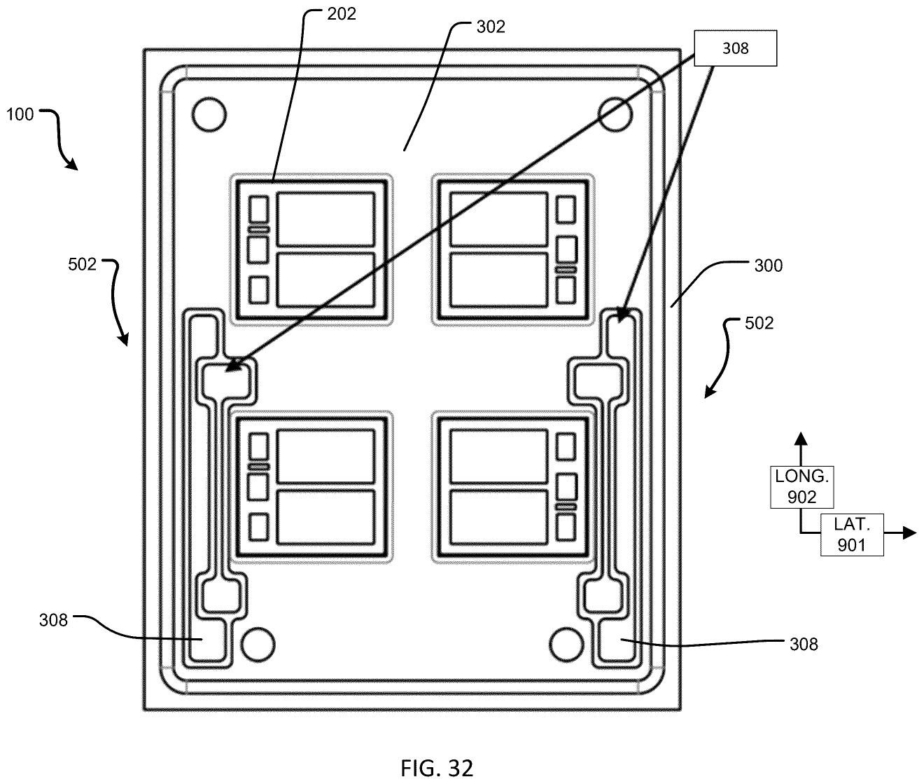

FIG. 32 illustrates a partial top view of a power package according to aspects FIG. 31.

In aspects, the power package 100 may implement winged routing of the at least one signal connection assembly 502 and/or the at least one routing layer 308 with an external multi-layer implementation of the at least one power substrate 300. In aspects, the winged routing of the at least one signal connection assembly 502 and/or the at least one routing layer 308 the signal routing may be split into dual trace patterns, typically on opposite sides of the power package 100, that enables the implementation of independent signal loops. This routing configuration is ideal for dual true source kelvin implementations within the power package 100 as well as adding sensing capabilities. This configuration allows for traces to be smaller than other configurations by not having a connecting trace (connecting the two ‘wing’ traces) that runs along the length of the at least one power substrate 300.

The aspects of the power package 100 illustrated in FIGS. 31-32 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 31-32.

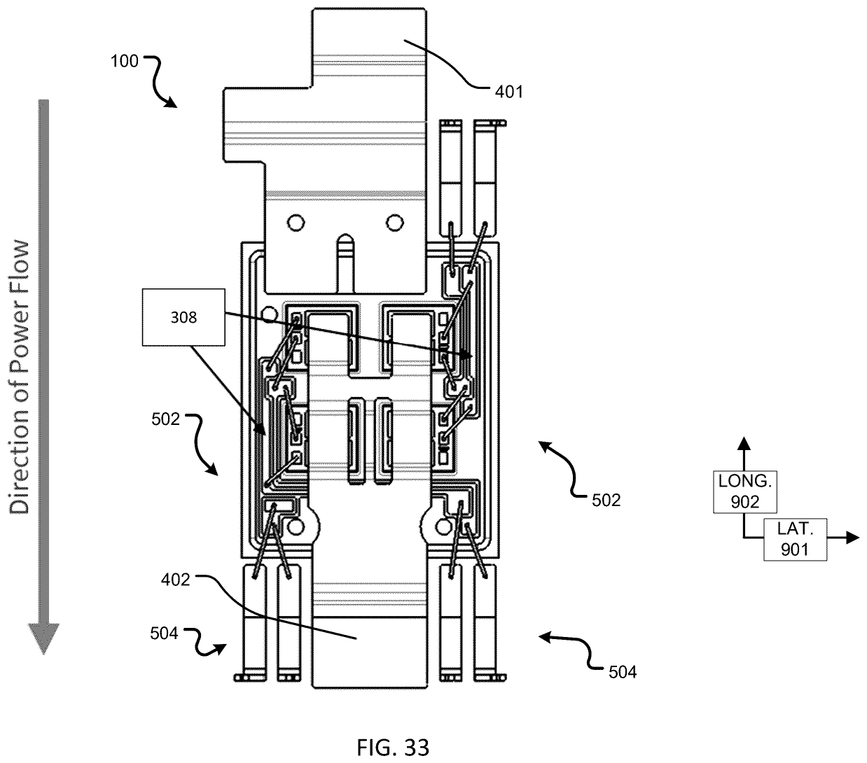

FIG. 33 illustrates a partial top view of a power package according to aspects of the disclosure.

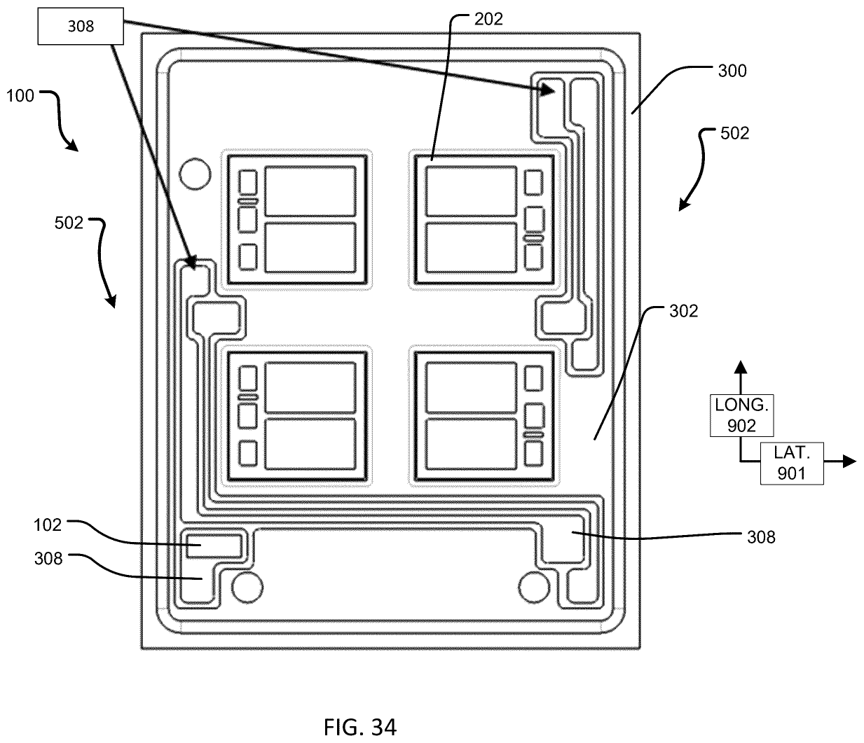

FIG. 34 illustrates a partial top view of a power package according to FIG. 33.

In aspects, the power package 100 may implement custom routing of the at least one signal connection assembly 502 and/or the at least one routing layer 308 with an external multi-layer implementation of the at least one power substrate 300. In aspects, the custom routing of the at least one signal connection assembly 502 and/or the at least one routing layer 308 may be a configuration of routing that is a mixture of orthogonal, parallel, contoured, and winged layouts. This configuration is based around the optimization of the package layout and efficient implementation of defined intra-module functions. This configuration may make use of multiple routing layers and structures.

The aspects of the power package 100 illustrated in FIGS. 33-34 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 33-34.

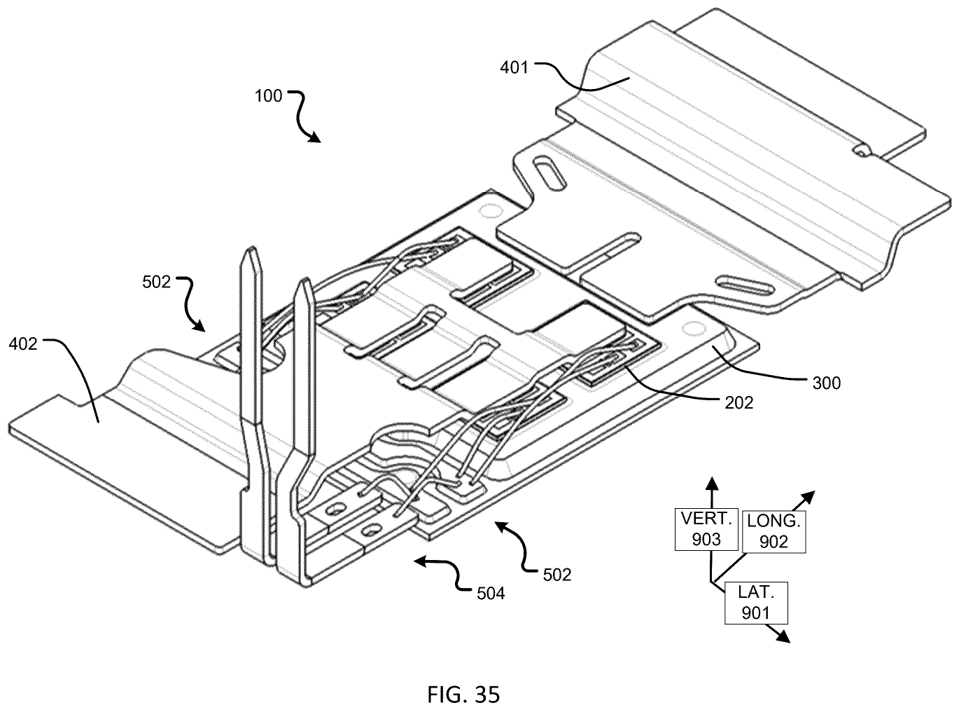

FIG. 35 illustrates a partial perspective view of a power package according to aspects of the disclosure.

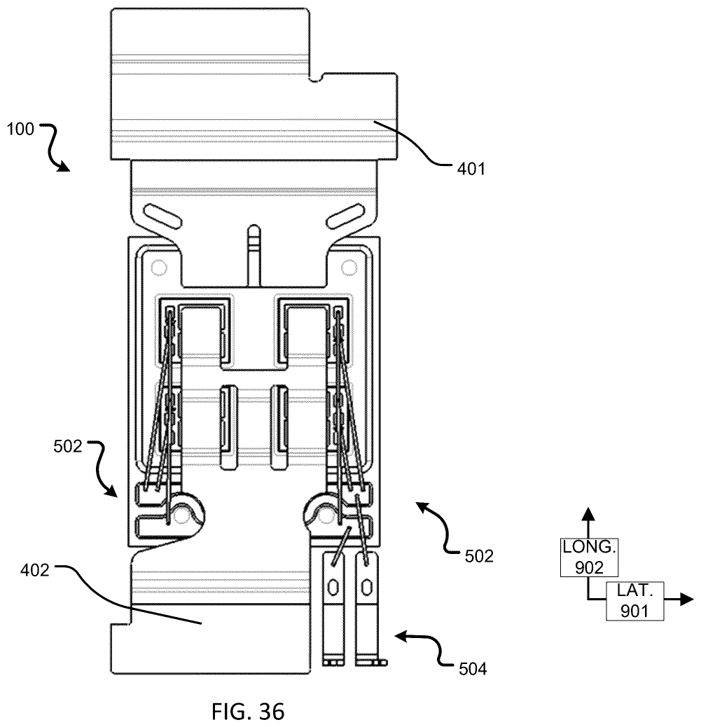

FIG. 36 illustrates a partial top view of a power package according to aspects of the disclosure.

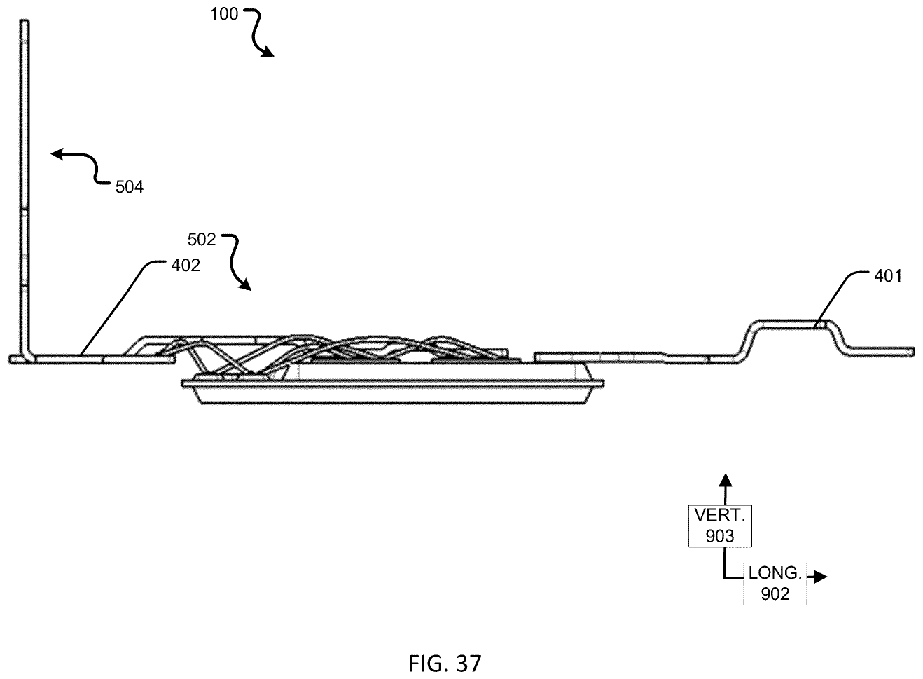

FIG. 37 illustrates a partial side view of a power package according to aspects of the disclosure.

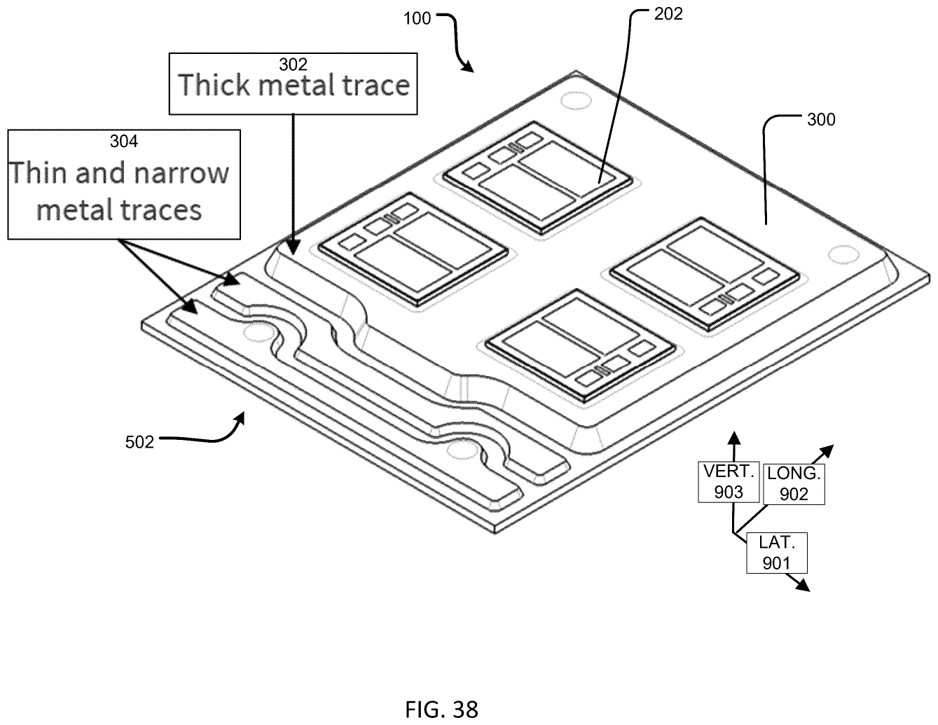

FIG. 38 illustrates a partial perspective view of a power package according to aspects of the disclosure.

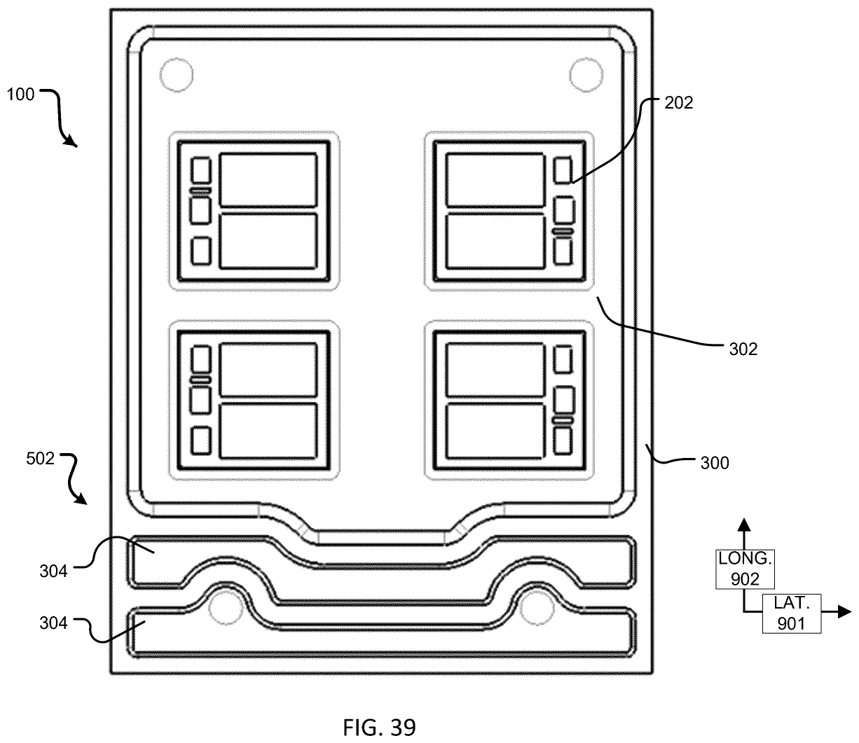

FIG. 39 illustrates a partial top view of a power package according to aspects of the disclosure.

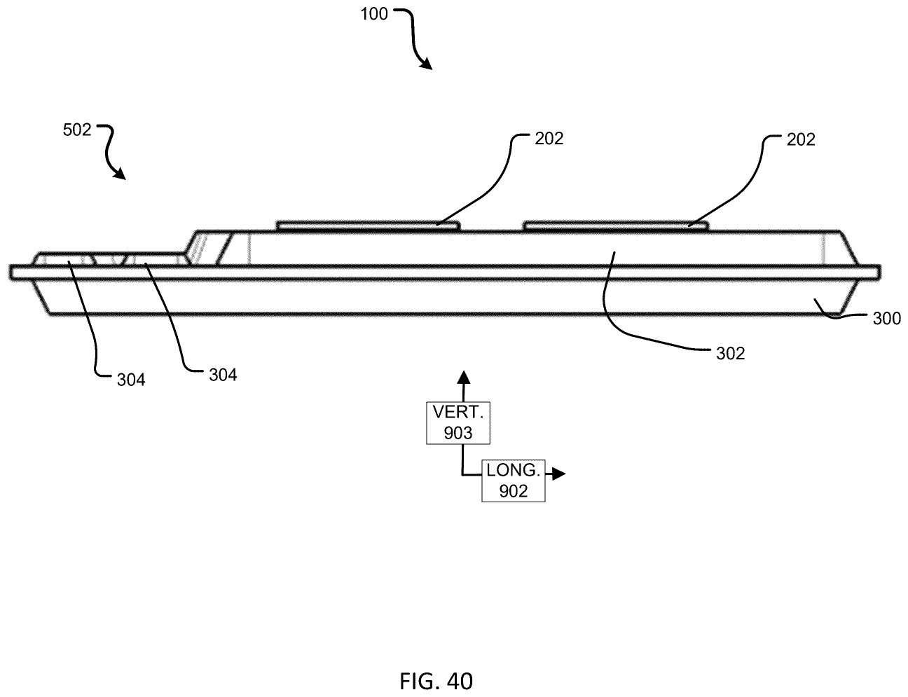

FIG. 40 illustrates a partial side view of a power package according to aspects of the disclosure.

In particular, FIGS. 35-40 illustrates an exemplary implementation of the power package 100 implementing the at least one power substrate 300 and/or the at least one signal connection assembly 502 in a multi-thickness power substrate implementation of the at least one power substrate 300 as disclosed herein. In particular, the power package 100 may include implementation of one or more of the components of the power package 100 as previously described including the power trace 302 and the at least one signal trace 304.

In aspects of the power package 100, the at least one power substrate 300 may be a layered structure of metal and ceramic, layered thick printed circuit board (PCB), thick film printed on organic/inorganic laminate, and/or the like, providing high current electrical interconnection, high voltage isolation, high thermal conductivity, co-efficient of thermal expansion (CTE) matching, and an external thermal interface with surface and geometrical enhancements. Multi-thickness power substrates differ from traditional power substrates by offering multiple metal traces of varying thicknesses so improved and/or optimized circuit resolution and power/signal density.

In aspects, the at least one power substrate 300 may be configured to act as the primary heat dissipation path from the power semiconductor devices to the cooling mechanism of the system. A power substrate's heat dissipation ability depends on its thermal conductivity, thickness, and lateral area. The top metallic layer of a power substrate is patterned into traces for electrical interconnection, based on the power module topology, semiconductor devices position, and pin/terminal layout. Some of these traces are used for the module's power loop and are designed to carry high currents, while some traces are designed to carry low currents such as high frequency switching signals or intra-module sensors signals. The idea is to maximize the width and thickness (to some extent) of the power trace while keeping the signal/sensor trace narrow and thin.

However, conventional power substrate manufacturing methods only offer metallic layers of a single thickness; with a relatively coarse pitch between metallic circuit traces; thicker the metallic layer, larger the pitch. Designers often juxtapose the thermal benefit of the thicker substrate with the thermal drawbacks of a smaller power trace (owing to the area lost to signal/sensor traces and pitch). Aspects of the at least one power substrate 300 implemented as a multi-thickness power substrate aims to solve this very dilemma. It allows the combination of thick, coarse metallic traces for power routing and thin, densely routed metallic traces for signal routing. As shown in FIGS. 35-40, the at least one power substrate 300 may be configured to maximize the power trace thickness and area by offering narrower and thinner signal/sensor traces with a tighter pitch.

In aspects, the at least one power substrate 300 implemented as a multi-thickness power substrate may offer higher resolution patterning of metal circuits, thereby increasing the power and signal density of the power package 100, within the same module footprint. In this aspect, the at least one power substrate 300 may also offer thinner metal around the perimeter of a thick metal trace, acting as a stress buffer.

In this regard, FIGS. 35-40 show an example configuration implementing the at least one power substrate 300 with multi-thickness substrate technology alone. However, this technology can be used in combination with other technologies (taught in this disclosure) including integrated cooling structures, to obtain an improved and/or optimized product.

Various embodiments of the at least one power substrate 300 may use materials such as copper, aluminum, molybdenum, tungsten, graphite, alloys of these metals, and/or a combination of multiple metals layered or printed together. The metallic layers of the at least one power substrate 300 may also include surface enhancements such as plating, mechanical abrasion, chemical abrasion, perimeter etching, step etching, spot etching, and/or the like.

In this regard, aspects of the power package 100 may realize a number of advantages offered by multi-layer substrate implementations of the at least one power substrate 300 over traditional single layer substrates, including:

Higher power density: By offering a layered structure of conducting and insulating layers, multi-layer substrates break free from the limitations of the footprint surface area.

Smaller system size: By enabling power modules with higher power and current capabilities, multi-layer substrate technology can help meet system requirements with fewer higher rated modules than multiple lower rated modules paralleled together. Thereby saving overall system footprint.

Lighter system assembly: Although multi-layer substate modules will be heavier than their single layer counterparts, there is a system level reduction in weight by replacing multiple lower rated power modules with fewer higher rated power modules.

Lower signal loop parasitics: With the help of proper substrate design techniques, electrical traces can be positioned and layered in ways that lead to magnetic flux cancellation in conductors and provide lower resistance and inductance in electrical loops. System integration with fewer high rated modules is more compact and efficient as compared to long and multiple signal loops required to connect several low rated modules.

Electromagnetic interference (EMI) shielding: The ability to bury/embed high frequency signal conductors between insulating dielectric layers, helps protect these sensitive conductors from the strong external magnetic field of the power loop conductors of the module. EMI shielding becomes an important design consideration during rapid switching events. Better EMI shielding results in faster switching times and lower switching losses in the power module, thereby improving and/or optimizing the overall system performance.

Improved thermal conductivity: Since power substrate is the primary heat dissipation path in a power module, the at least one power substrate 300 may be configured with materials with a high thermal conductivity in the lateral as well as vertical direction. However, for manufacturing of traditional power substrates, a materials mechanical strength and reliability dominates the mechanical properties list. Materials and alloys which have significantly superior thermal conductivity as compared to metals like copper and aluminum, cannot be used to manufacture traditional power substrates due to their brittle and fatigue prone qualities. However, these materials do find use in multi-layer power substrates where they can be embedded between mechanically stronger metallic layers; thereby improving overall thermal conductivity while having minimal reliability implications.

The aspects of the power package 100 illustrated in FIGS. 35-40 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 35-40.

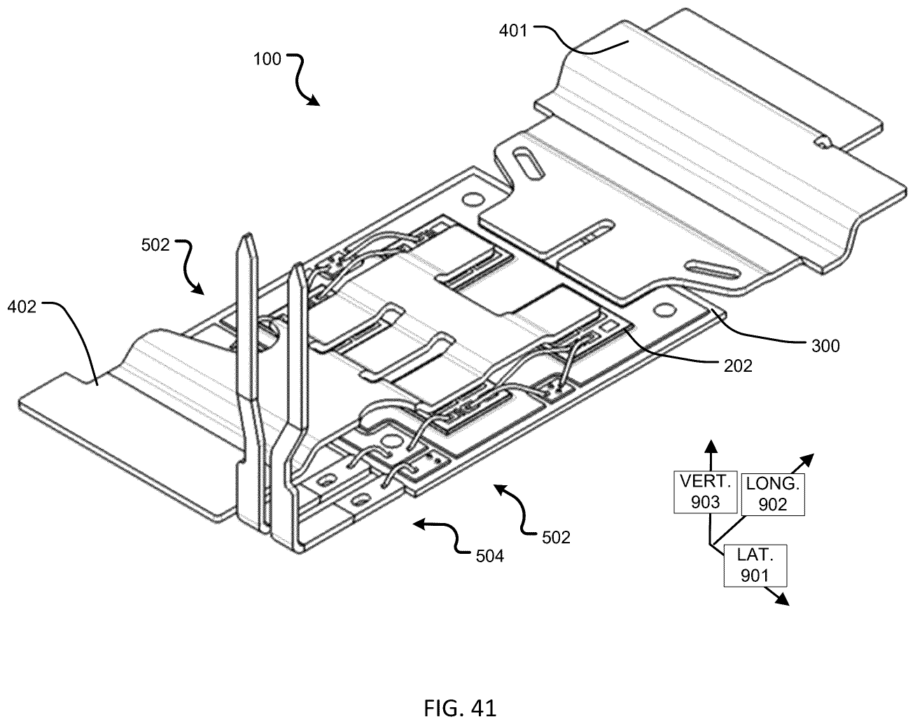

FIG. 41 illustrates a partial perspective view of a power package according to aspects of the disclosure.

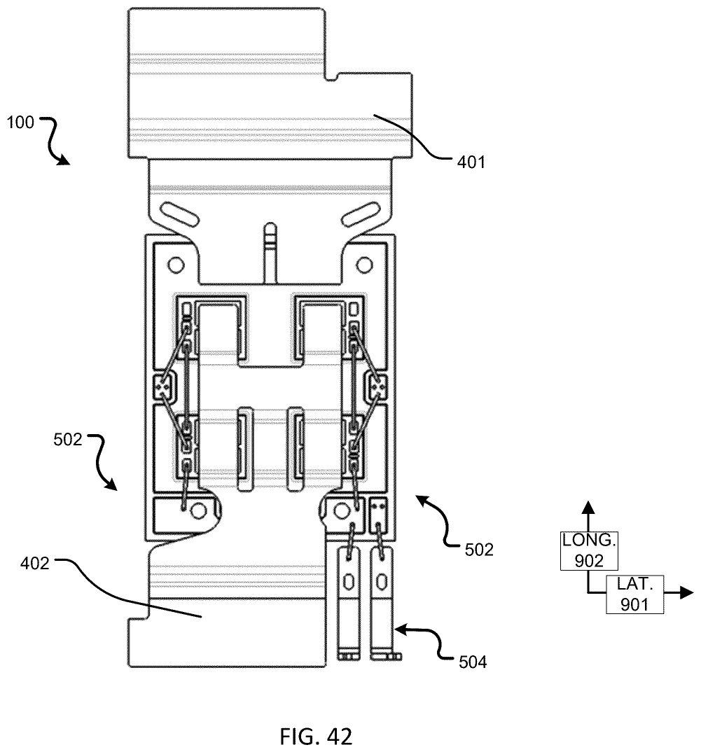

FIG. 42 illustrates a partial top view of a power package according to FIG. 41.

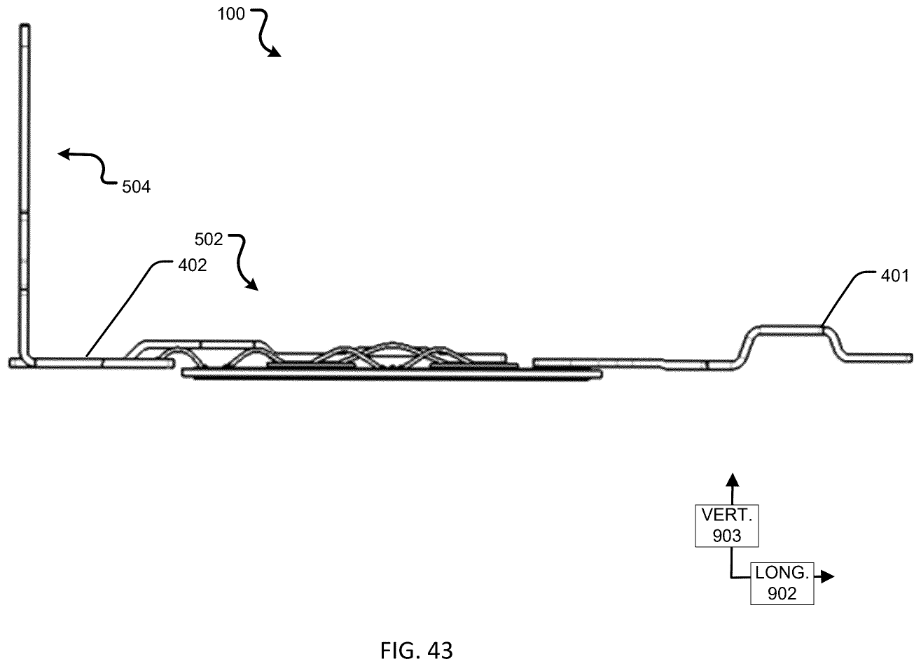

FIG. 43 illustrates a partial side view of a power package according to FIG. 41.

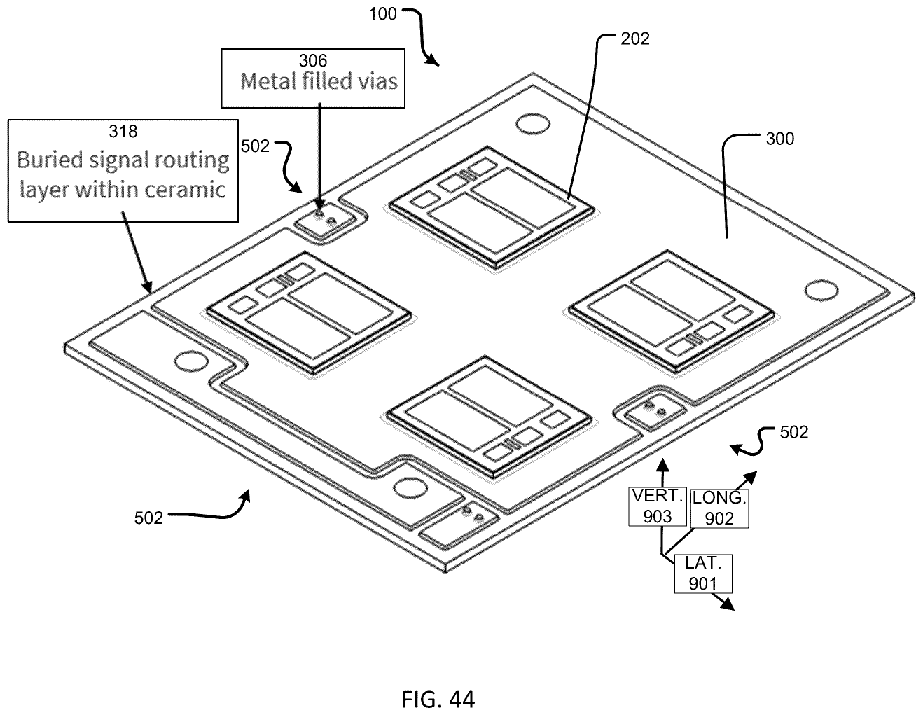

FIG. 44 illustrates a partial perspective view of a power package according to FIG. 41.

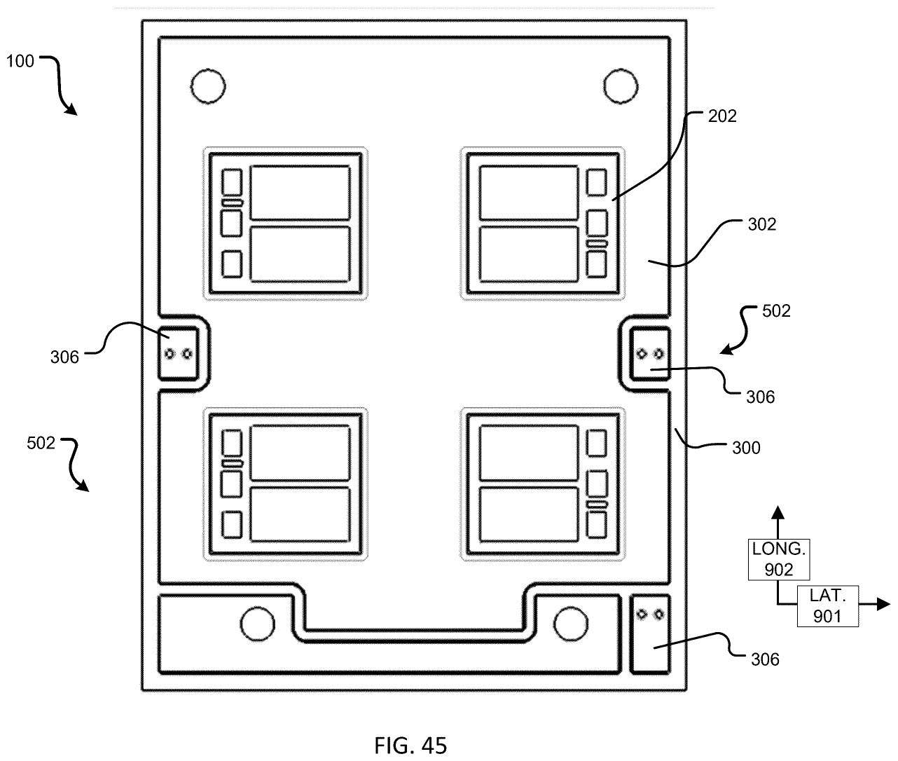

FIG. 45 illustrates a partial top view of a power package according to FIG. 41.

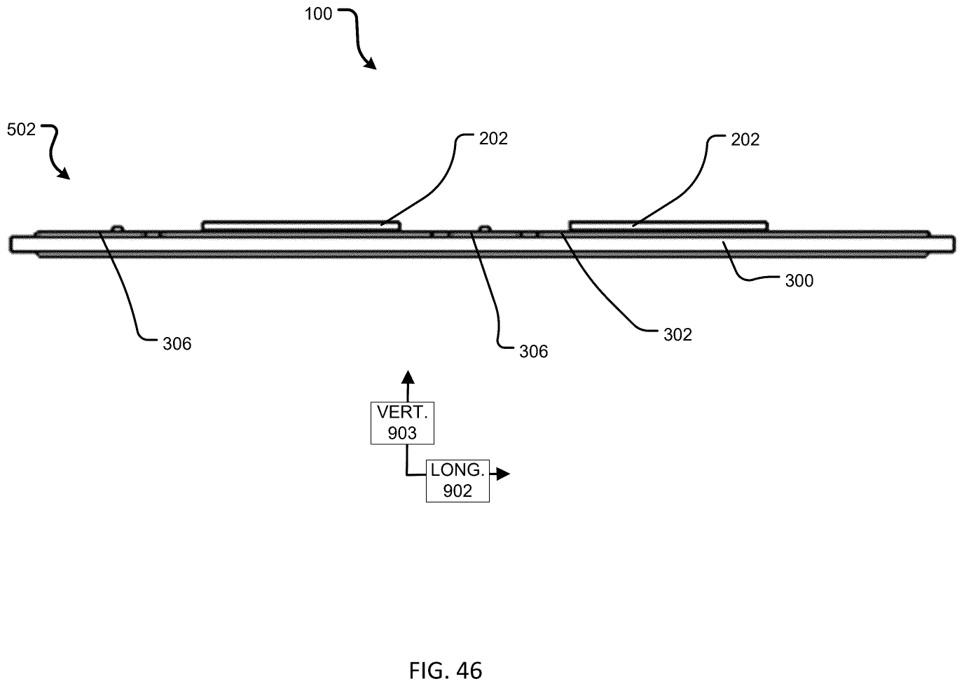

FIG. 46 illustrates a partial side view of a power package according to FIG. 41.

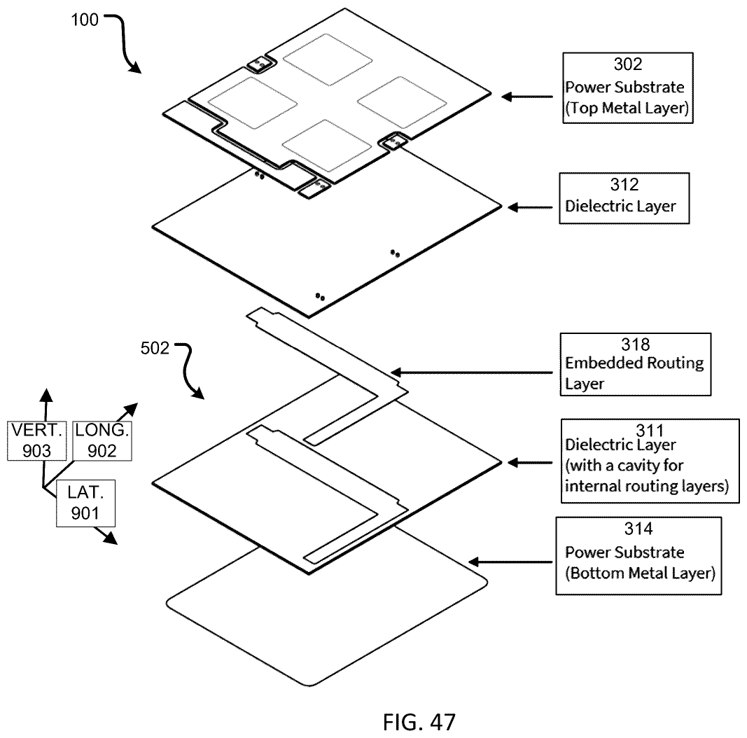

FIG. 47 illustrates a partial exploded perspective view of a power package according to FIG. 41.

With an increasing demand for higher power density in power modules, multi-layer power substrate technologies offer a highly effective solution. This type of substrate breaks free from the limitations of a two-dimensional footprint area, by introducing conductive layers in the third dimension. Similar to a multi-layered printed circuit board, multi-layer power substrates may contain three or more metallic/conductive layers interspersed by electrically insulating layers.

In aspects, the at least one power substrate 300 implemented with a multi-layer composite power and signal substrate may be configured and designed to have thicker metallic layers for high-current, high-power applications with higher voltage insulating capability while having thin metallic layers for conducting switching and sensing signals. Besides higher breakdown voltage, the insulating material may be configured to have high thermal conductivity for better thermal management of the power module. In this regard, FIGS. 41-47 show a configuration of the power package 100 using a multi-layered power substrate.

In particular, FIGS. 41-47 illustrate an implementation of the power package 100 implementing the at least one power substrate 300 as an internal multi-layer power substrate. More specifically, the power package 100 may include implementation of one or more of the components of the power package 100 as previously described including the power trace 302 and the at least one signal pad trace 306.

Although FIGS. 41-47 show an implementation of the power package 100 with the multi-layered technology alone, this technology can be combined with other technologies (listed in this disclosure) including integrated cooling structures, to obtain an improved and/or optimized product. Various embodiments may also use a range of materials such as copper, aluminum, molybdenum, tungsten, graphite, alloys of these metals, and a combination of multiple metals layered or printed together. The metallic layers may also include surface enhancements such as plating, mechanical abrasion, chemical abrasion, perimeter etching, step etching, spot etching, and/or the like.

The aspects of the power package 100 illustrated in FIGS. 41-47 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 41-47.

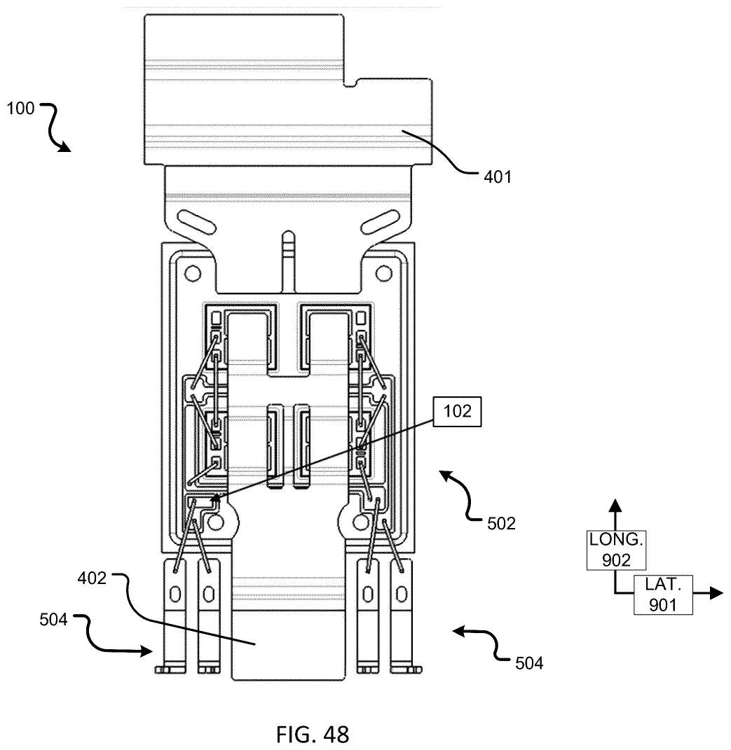

FIG. 48 illustrates a partial top view of a power package according to aspects of the disclosure.

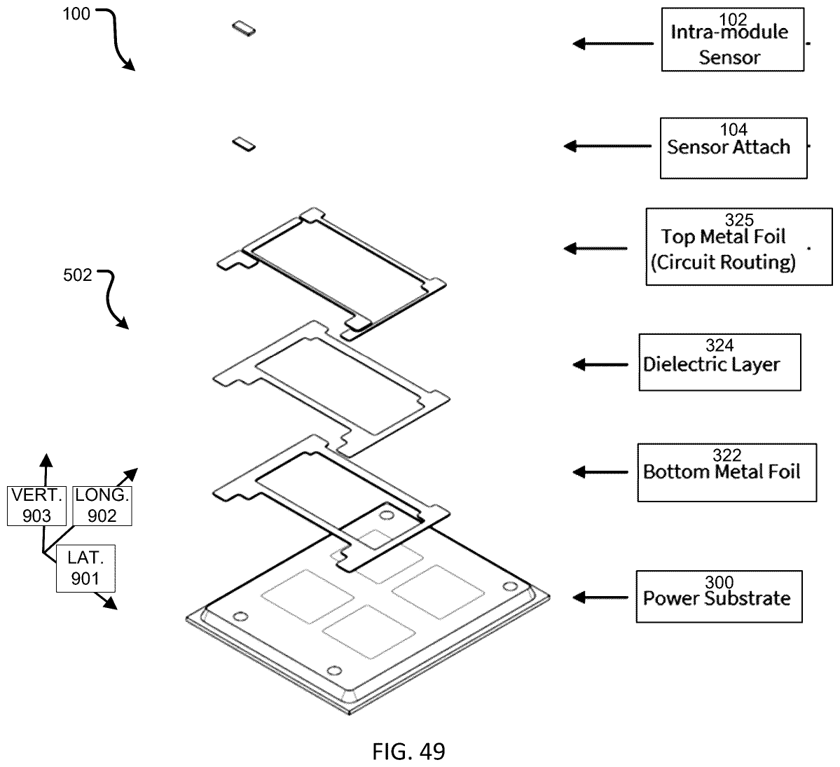

FIG. 49 illustrates a partial exploded perspective view of a power package according to FIG. 48.

In particular, FIGS. 48 and 49 illustrate an exemplary implementation of the power package 100 implementing the at least one power substrate 300 as an external multi-layer power substrate. In aspects, the power package 100 may further include the at least one signal connection assembly 502 as previously described.

Further, the power package 100 may implement the top metal foil 325, the dielectric layer 324, the bottom metal foil 322, arranged on the at least one power substrate 300 as previously described. Further, the power package 100 may implement a sensor attach 104 for attaching the at least one sensor 102 to the at least one power substrate 300.

In this regard, external multi-layer power substrates may be substrates with more than one routing layer added externally to the at least one power substrate 300 in order to conduct signals and increase the power density. An effective way of adding external layers on the at least one power substrate 300 may be through metal clad laminates (MCLs) that are soldered, sintered, and tacked onto the surface of the substrate. MCL layouts could also be achieved through direct printing of insulating and conductive pastes.

Implementations of the at least one power substrate 300 with metal clad laminates may be rigid or flexible dielectric laminates made from organic or in-organic material, superimposed by a patterned layer of metal on at least one side of the laminate; used for high frequency electrical interconnection and high voltage isolation.

Various aspects may use different types of metal clad laminates such as organic resin, ceramic base, metal core, electronic fiberglass cloth base, paper base, composite base, and/or the like. The metal foil could be copper, aluminum, silver, nickel, and/or the like.

Implementations of the at least one power substrate 300 with metal clad laminates and copper clad laminates may be utilized to address the increasing demand for higher power density and standardization of module footprints, MCLs offer a way to enhance power module efficiency, integrate additional features (sensing, protection, true source kelvins, etc.), and enable product differentiation in the market.

There are a number of advantages of implementing the at least one power substrate 300 by integrating metal clad laminates (MCLs) into the power package 100:

Lower Power Loop Parasitics: By routing the high frequency switching signals and sensor signals through the MCL instead of the power substrate, there is additional space available on the substrate for the power traces. These wider traces offer larger cross-sectional area to the high current conduction path and minimize the resistance and inductance of the power loop.

Better Thermal Performance: By providing larger power traces on the power substrate, the primary heat dissipation path area is increased. This intern allows for more efficient cooling of the power module and maximizes the power and ampacity rating of the module.

Cost benefit: Since all the complex signal routing is contained in the MCL, the power substrate only contains wide and simple blocks of power traces. These simple power substrate designs require minimal etching/patterning and are cheaper to manufacture. MCLs increase the power density of a package and shrink the required footprint and power substrate size. A smaller power substrate size yields more parts per panel during manufacturing, thereby driving down cost even further.

Product derivative flexibility: A simplified power substrate that only carries power traces can be used as a universal base for a product family. MCL layout can be tuned based on the specific product derivate design while keeping the power substrate the same. This flexibility offered by MCLs helps keep processes and components similar for derivates belonging to the same product family, thereby simplifying logistics, minimizing equipment tooling cost, availing high volume discounts for shared components, and minimizing production line down time that's lost to manufacturing line change from one derivative to another.

Integrate sensing and protection capabilities: MCLs offer circuit trace printing at a resolution that is much higher than that offered by power substrates (even multi-thickness substrates). This additional space that is saved up due to tighter pitches enables the addition of optional intra-module sensors (shown in FIG. 16) to measure temperature, pressure, humidity, moisture, mechanical strain, and the like. The additional space can also be used for adding over-current protection, gate resistors for minimizing voltage overshoots during switching, integration of smart IC chips, etc. into the package.

The aspects of the power package 100 illustrated in FIGS. 48-49 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 48-49.

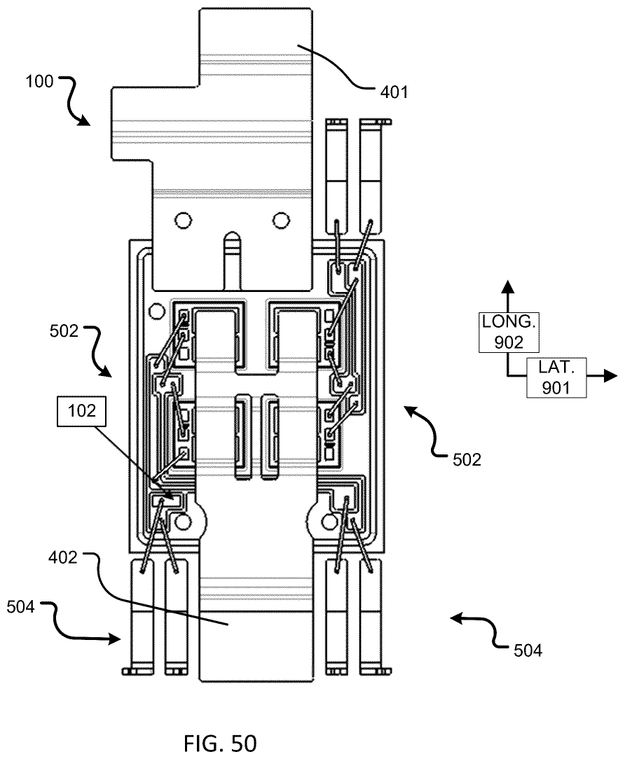

FIG. 50 illustrates a partial top view of a power package according to aspects of the disclosure.

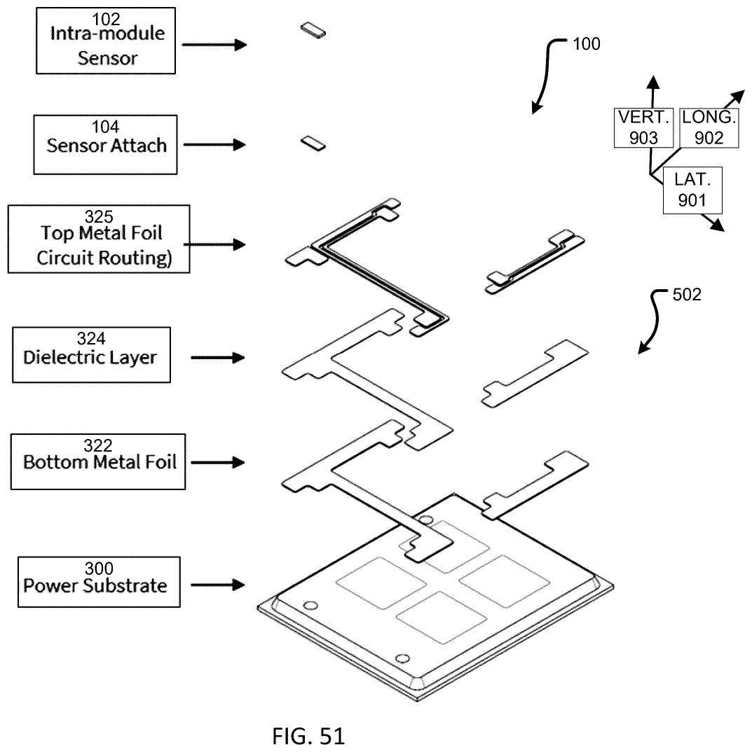

FIG. 51 illustrates a partial exploded perspective view of a power package according to FIG. 50.

In particular, FIGS. 50 and 51 illustrate another exemplary implementation of the power package 100 implementing the at least one power substrate 300 as an external multi-layer power substrate. In aspects, the power package 100 may further include the at least one signal connection assembly 502 as previously described. Further, the power package 100 may implement the top metal foil 325, the dielectric layer 324, the bottom metal foil 322, arranged on the at least one power substrate 300 as previously described. Further, the power package 100 may implement the sensor attach 104 for attaching the at least one sensor 102 to the at least one power substrate 300.

The aspects of the power package 100 illustrated in FIGS. 50-51 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 50-51.

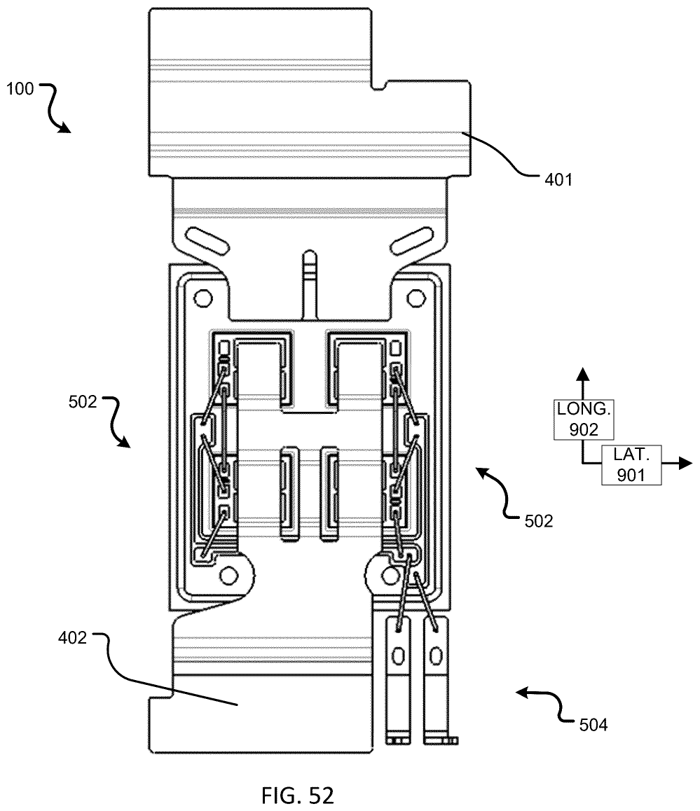

FIG. 52 illustrates a partial top view of a power package according to aspects of the disclosure.

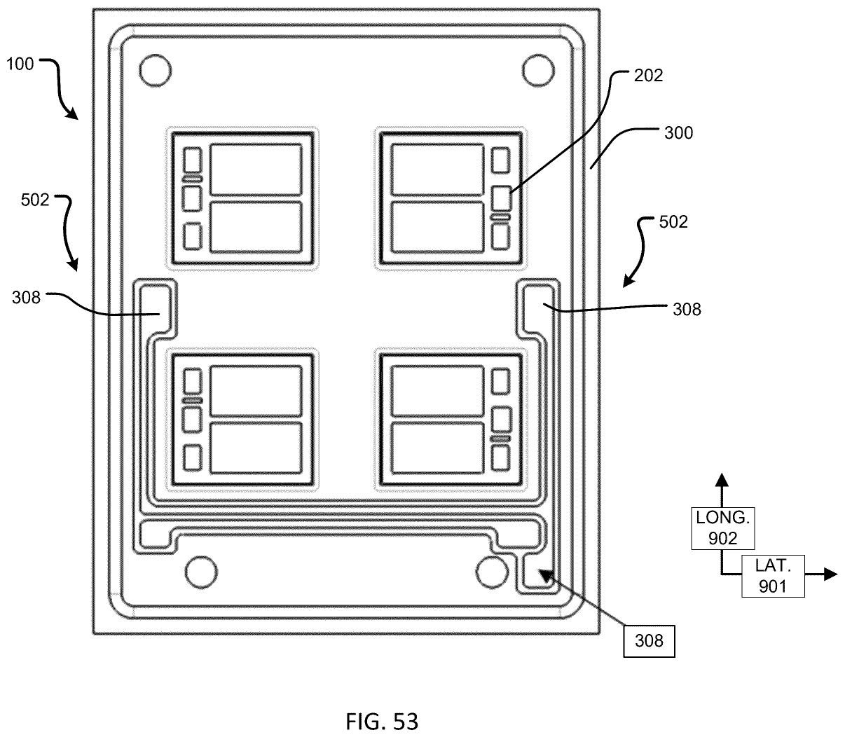

FIG. 53 illustrates a partial top view of a power package according to aspects of the disclosure.

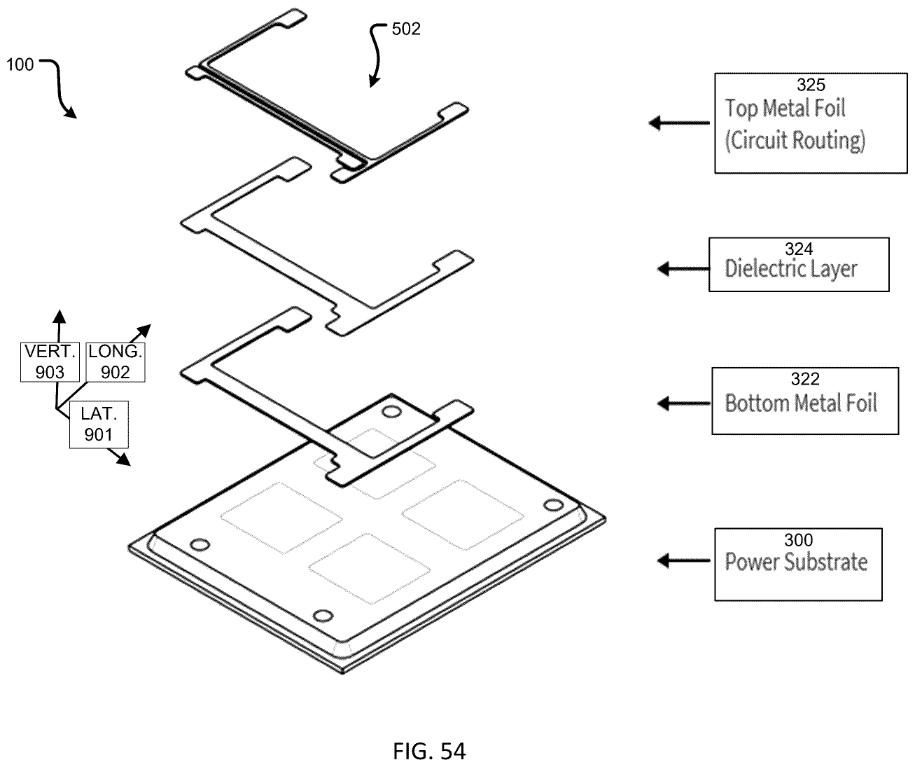

FIG. 54 illustrates a partial exploded perspective view of a power package according to aspects of the disclosure.

In particular, FIGS. 52-54 illustrate another exemplary implementation of the power package 100 implementing the at least one power substrate 300 as an external multi-layer power substrate. In aspects, the power package 100 may further include the at least one signal connection assembly 502 and the at least one routing layer 308 as previously described. Further, the power package 100 may implement the top metal foil 325, the dielectric layer 324, the bottom metal foil 322, arranged on the at least one power substrate 300 as previously described.

The aspects of the power package 100 illustrated in FIGS. 52-54 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 52-54.

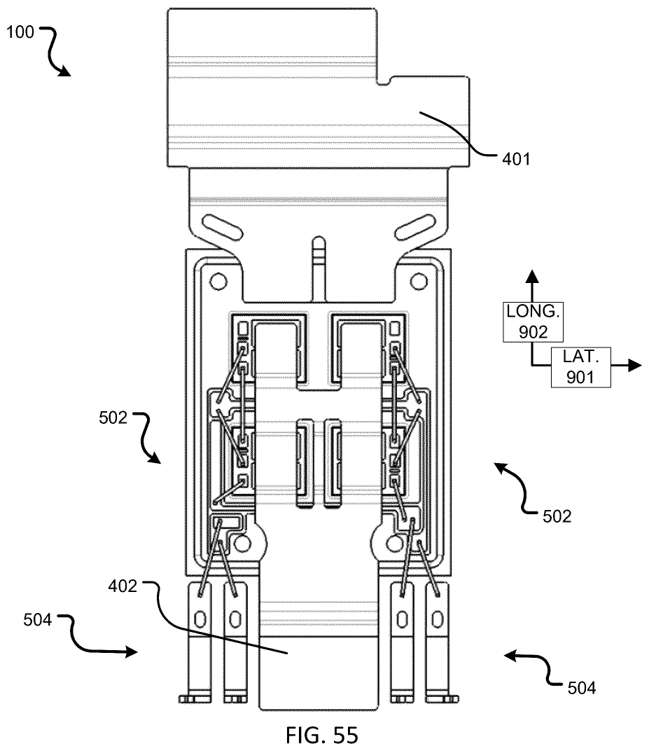

FIG. 55 illustrates a partial view of a power package according to aspects of the disclosure.

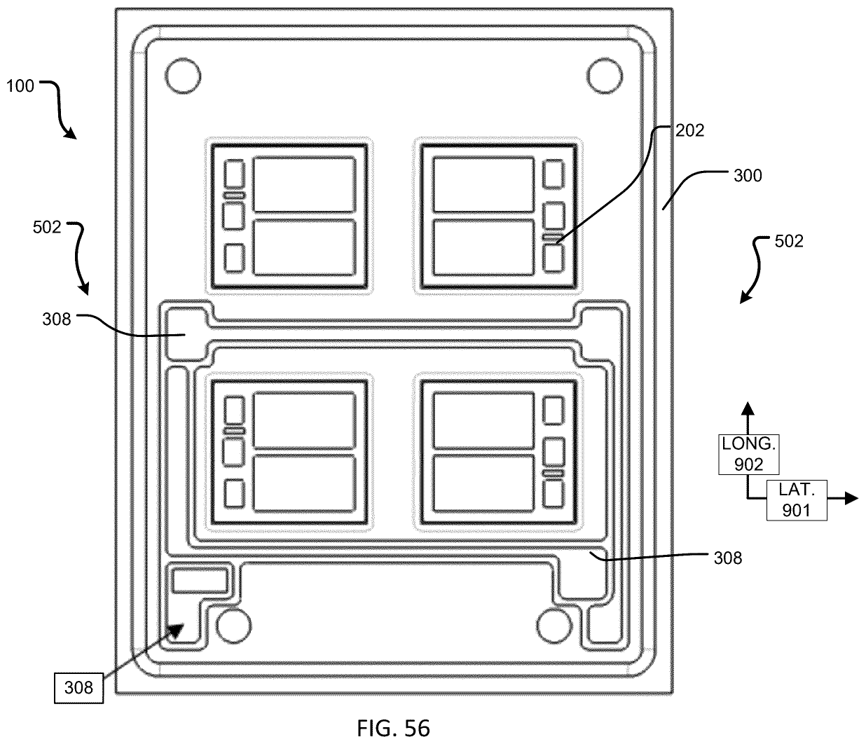

FIG. 56 illustrates a partial view of a power package according to aspects of the disclosure.

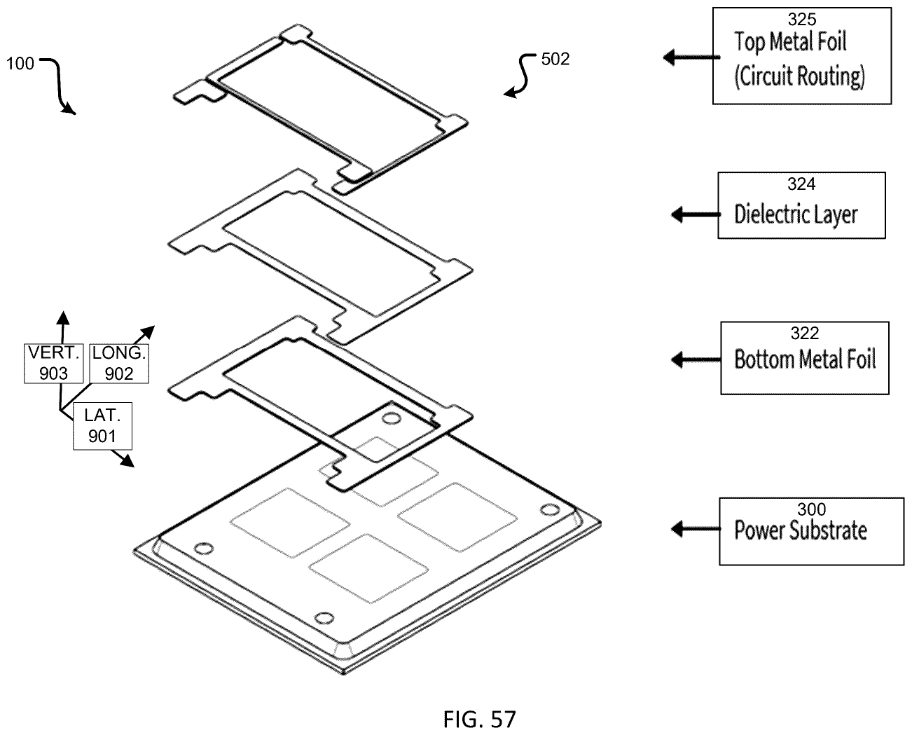

FIG. 57 illustrates a partial view of a power package according to aspects of the disclosure.

In particular, FIGS. 55-57 illustrate another exemplary implementation of the power package 100 implementing the at least one power substrate 300 as an external multi-layer power substrate. In aspects, the power package 100 may further include the at least one signal connection assembly 502 and the at least one routing layer 308 as previously described. Further, the power package 100 may implement the top metal foil 325, the dielectric layer 324, the bottom metal foil 322, arranged on the at least one power substrate 300 as previously described.

The aspects of the power package 100 illustrated in FIGS. 55-57 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 55-57.

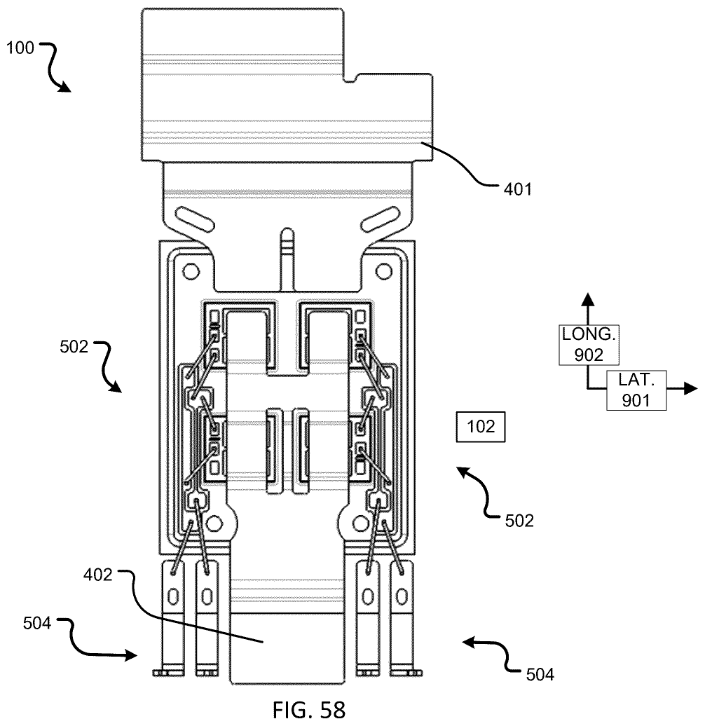

FIG. 58 illustrates a partial top view of a power package according to aspects of the disclosure.

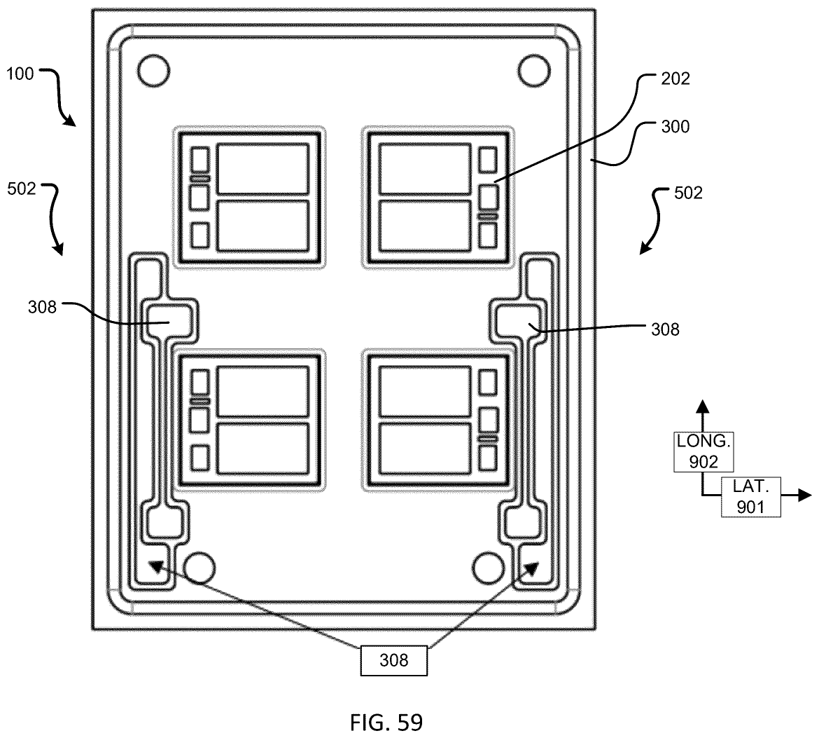

FIG. 59 illustrates a partial top view of a power package according to aspects of the disclosure.

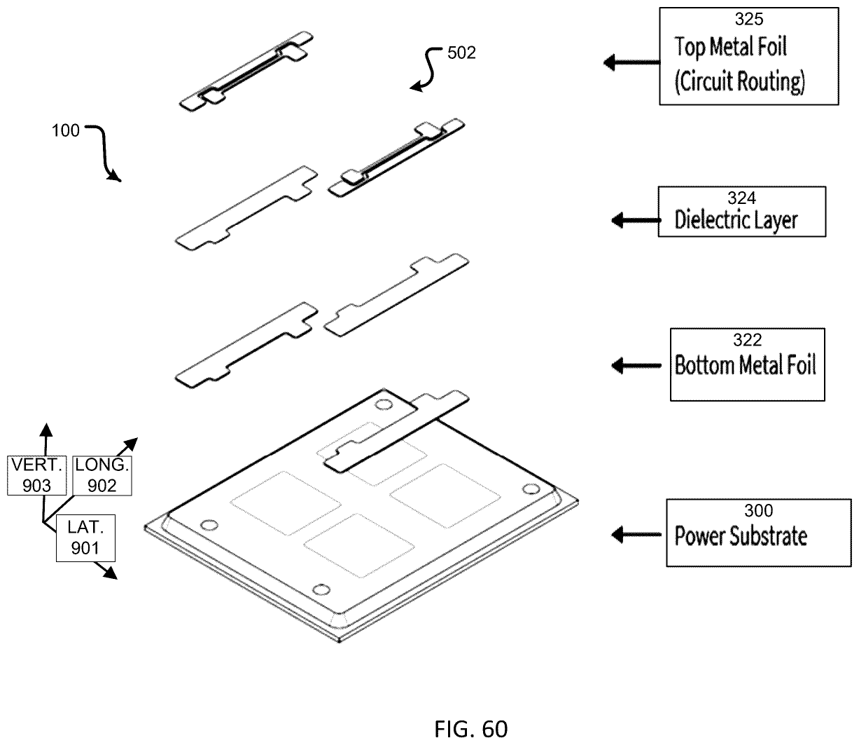

FIG. 60 illustrates a partial exploded perspective view of a power package according to aspects of the disclosure.

In particular, FIGS. 58-60 illustrate another exemplary implementation of the power package 100 implementing the at least one power substrate 300 as an external multi-layer power substrate. In aspects, the power package 100 may further include the at least one signal connection assembly 502 and the at least one routing layer 308 as previously described. Further, the power package 100 may implement the top metal foil 325, the dielectric layer 324, the bottom metal foil 322, arranged on the at least one power substrate 300 as previously described.

The aspects of the power package 100 illustrated in FIGS. 58-60 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 58-60.

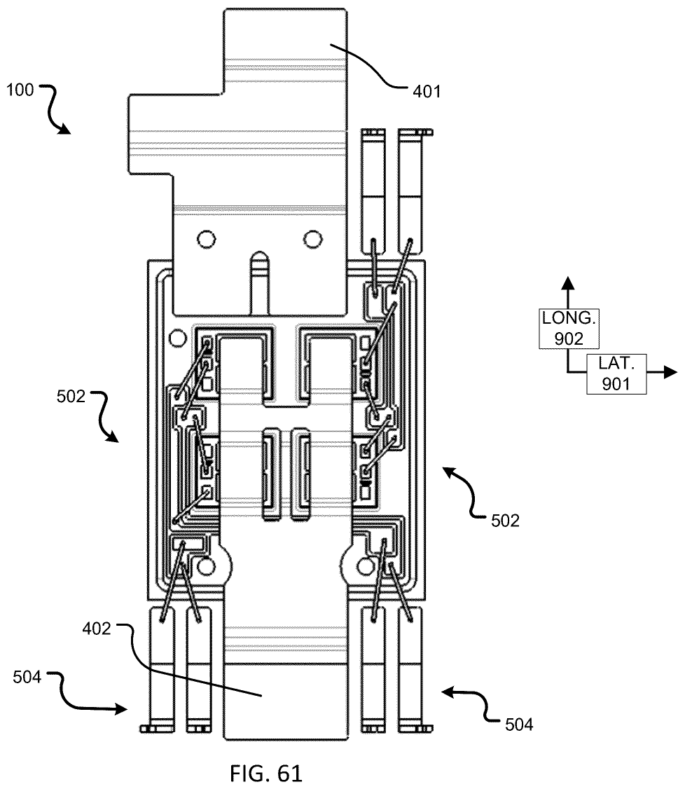

FIG. 61 illustrates a partial top view of a power package according to aspects of the disclosure.

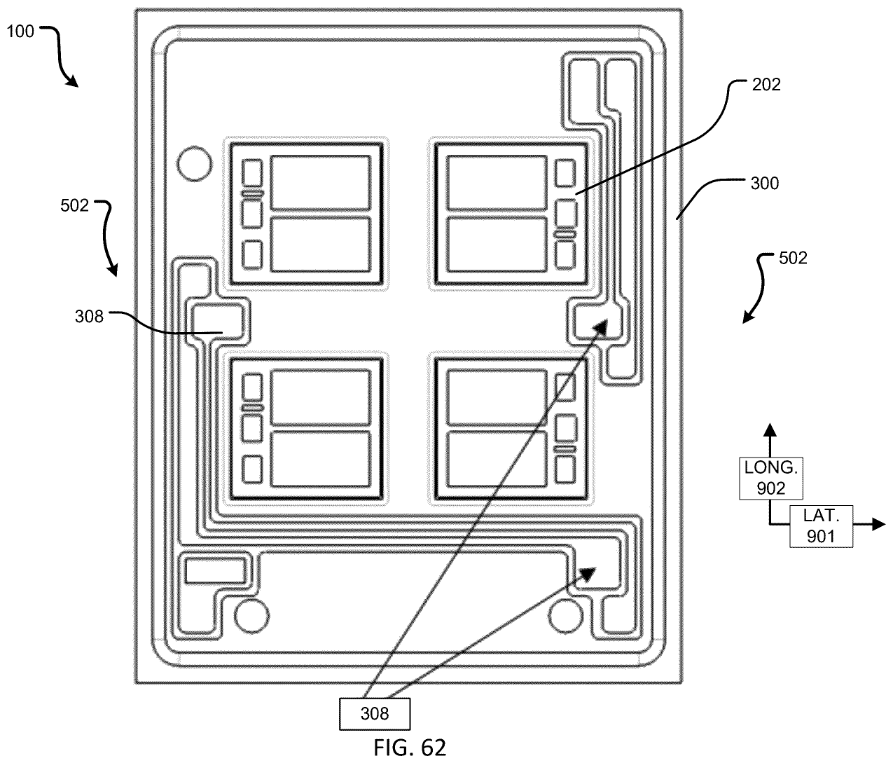

FIG. 62 illustrates a partial top view of a power package according to aspects of the disclosure.

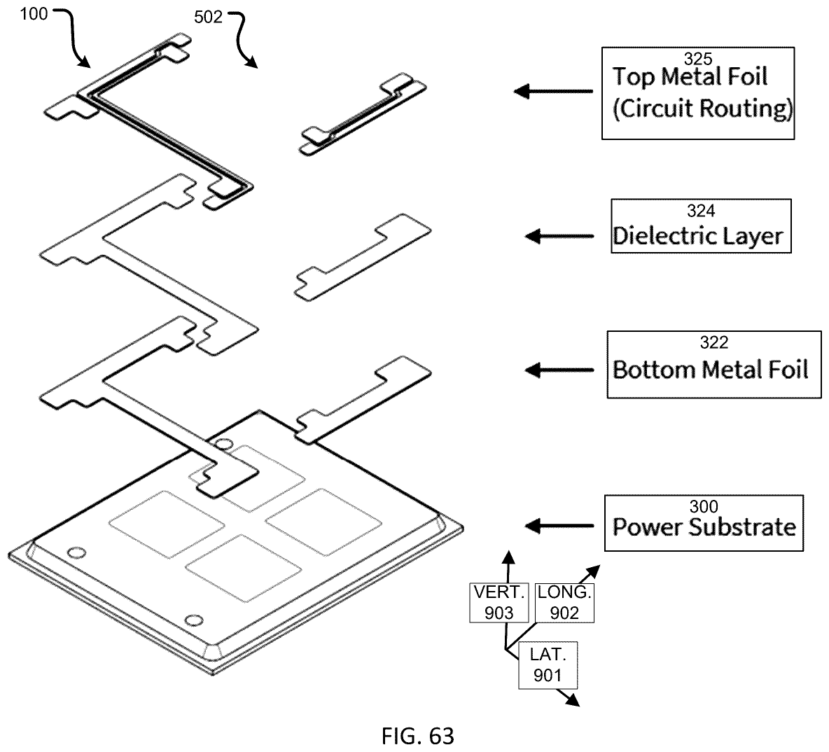

FIG. 63 illustrates a partial exploded perspective view of a power package according to aspects of the disclosure.

In particular, FIGS. 61-63 illustrate another exemplary implementation of the power package 100 implementing the at least one power substrate 300 as an external multi-layer power substrate. In aspects, the power package 100 may further include the at least one signal connection assembly 502 and the at least one routing layer 308 as previously described. Further, the power package 100 may implement the top metal foil 325, the dielectric layer 324, the bottom metal foil 322, arranged on the at least one power substrate 300 as previously described.

The aspects of the power package 100 illustrated in FIGS. 61-63 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 61-63.

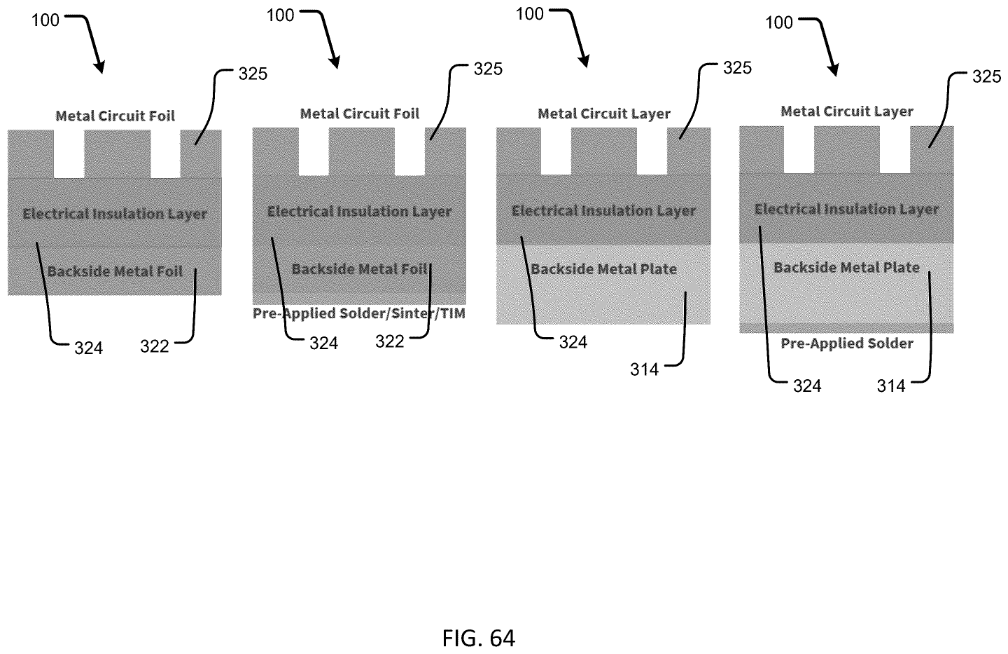

FIG. 64 illustrates partial cross-sectional views of power packages according to aspects of the disclosure.

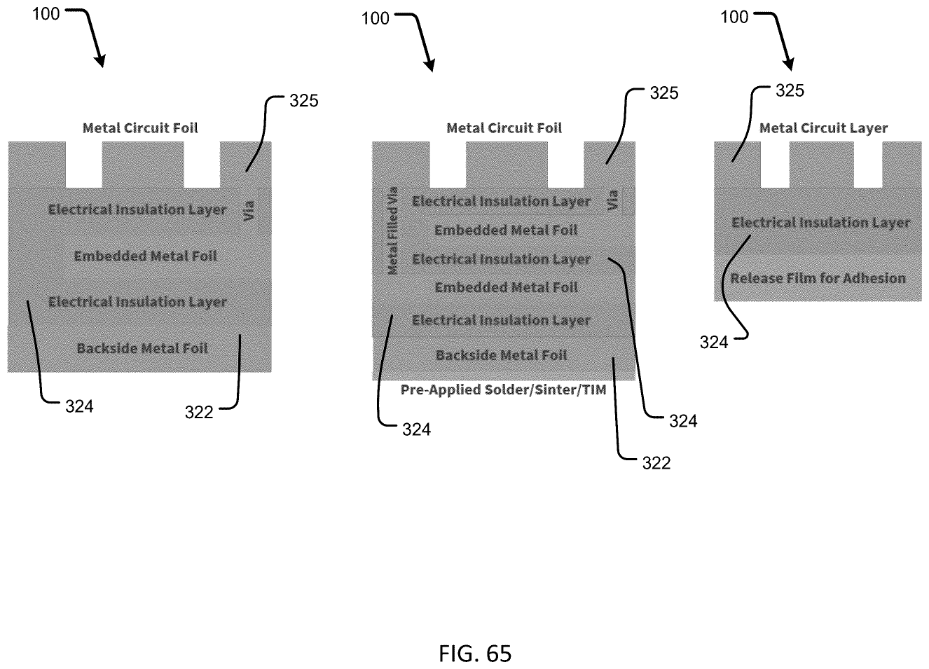

FIG. 65 illustrates a partial cross-sectional views of a power packages according to aspects of the disclosure.

In particular, FIGS. 64 and 65 illustrate partial cross-sectional views of the power package 100 having metal clad laminate implementations of the at least one power substrate 300. In aspects, the metal clad laminate implementations of the at least one power substrate 300 may use any of the several types of metal clad laminates, single as well as multi layered. The MCL may also come with a pre-applied solder, sinter, thermal grease, thermal pad, thermally conductive epoxy, and/or the like as illustrated. A bottom layer of a metal clad laminate implementation of the at least one power substrate 300 may be a metal foil, a thick metal plate, and/or a release film. Multilayer MCLs may also be used for higher routing density and addition of additional features.

The aspects of the power package 100 illustrated in FIGS. 64-65 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIGS. 64-65.

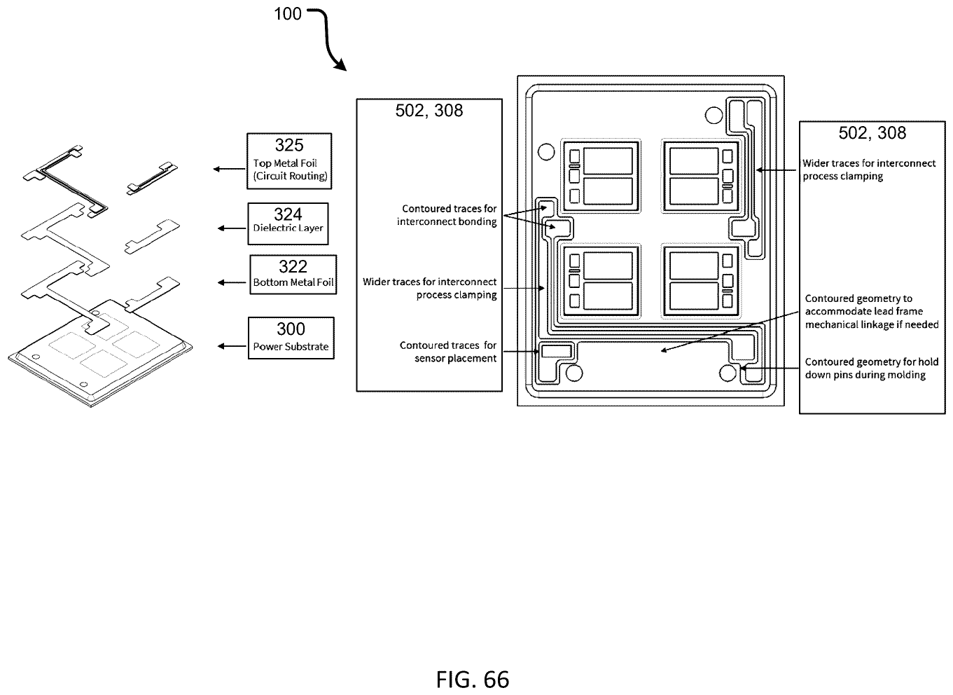

FIG. 66 illustrates a partial perspective view alongside a partial top view of a power package according to aspects of the disclosure.

In particular, FIG. 66 illustrates the power package 100 having an exemplary metal clad laminate implementation of the at least one power substrate 300. In aspects, MCLs can be attached to the at least one power substrate 300 or the metallic lead frame by means of soldering, sintering, thermal adhesive, hot tacking, bolting, laser welding, ultra-sonic welding, and the like.

A shape of the MCL implementation of the at least one power substrate 300 may need to be improved and/or optimized for ease of processing, equipment and tooling access, cost, thermal performance, conduction loop parasitics, magnetic flux cancellation, device positioning, interconnect positioning and bonding, pin/terminal layout, fiducials, and hold down pin access. Thus, a metal clad laminate implementation of the at least one power substrate 300 may utilize judicious contouring of the MCL layout.

The aspects of the power package 100 illustrated in FIG. 66 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIG. 66.

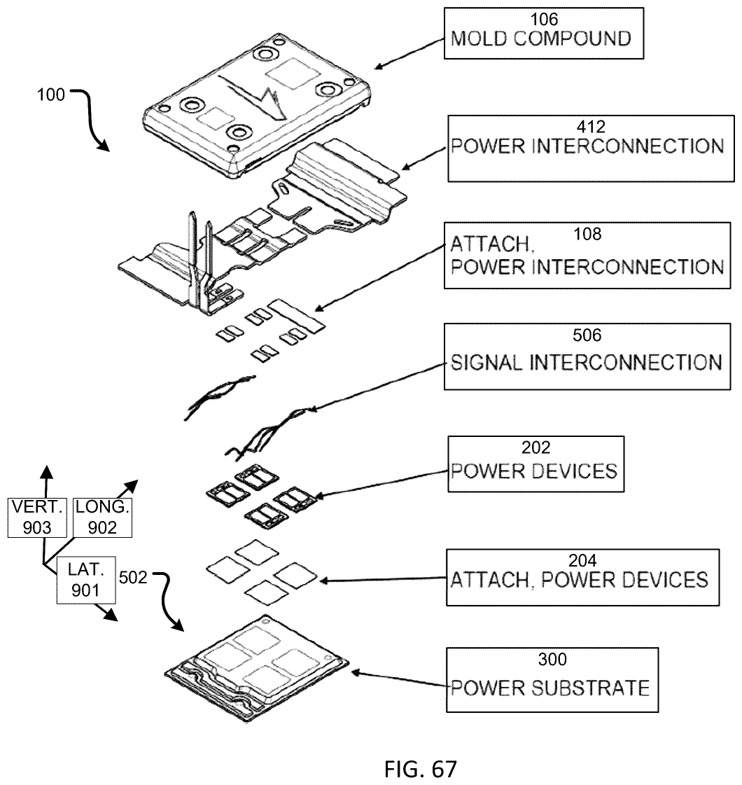

FIG. 67 illustrates a partial exploded view of an exemplary implementation of a power package according to aspects of the disclosure.

In particular, FIG. 67 illustrates a partial exploded view of an exemplary implementation of the power package 100. In aspects, the power package 100 may include a housing 106 and a power interconnection attach 108. In aspects, the power package 100 may be implemented as an over-molded power module, which may be assembled on a patterned lead frame array, encapsulated with a mold compound or similar composite dielectric material, singulated from the lead frame array, and finally the electrical contacts are formed into shape. In aspects, multiple parts may be fabricated on a single lead frame to maximize throughput. These processes are highly compatible with serial processing in an automated manufacturing line.

In aspects, the power package 100 may be implemented with one or more the following as described herein:

Power Devices—Power semiconductor switches that may be sized to minimize the device area for a given power requirement.

Device Attach—Material that may be selected to (1) maximize thermal performance or (2) minimize cost.

Power Substrate—Material that may be selected to (1) maximize thermal performance, (2) maximize reliability, or (3) minimize cost.

Lead Frame-Material that may be selected to be compatible with the attach method to the power substrate and power interconnection.

Lead Frame Attach-Methods that may include welding, solder paste, sinter, or preform.

Sensor-Material that may be selected to (1) maximize reliability, (2) maximize sensing accuracy, or (3) minimize cost.

Sensor Attach-Methods that may include welding, solder paste, sinter, or preform.

Power Interconnection-Topside high current electrical connection that may be formed either through (1) direct welded, soldered, or sintered connection to the lead frame, (2) power wire bonds from the topside bond pads to the lead frame, or (3) power ribbon bonds from the topside bond pads to the lead frame.

Signal Interconnection-Topside electrical connection of the signal pads of the devices to the signal terminals of the package, which may be formed through signal wire bonds.

Metal Clad Laminate-Material that may be selected to (1) maximize reliability, (2) minimize cost, (3) maximize dielectric performance, (4) minimize interconnection loop inductance & resistance, or (5) maximize density of high frequency interconnections.

Mold Compound-Material that may be selected to (1) maximize reliability, (2) minimize stresses, or (3) maximize dielectric performance.

The aspects of the power package 100 illustrated in FIG. 67 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIG. 67.

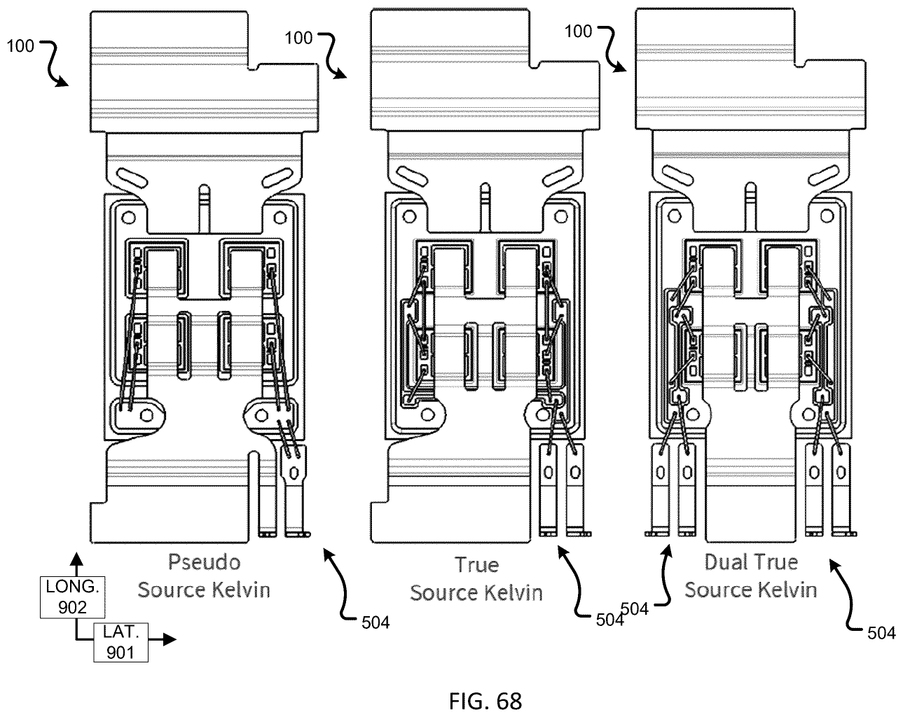

FIG. 68 illustrates partial views of exemplary power packages according to aspects of the disclosure.

In particular, FIG. 68 illustrates partial views of exemplary implementations of the power package 100. More specifically, the left illustrated implementation of the power package 100 implements a pseudo-source Kelvin implementation of the signal terminals 504; the center illustrated implementation of the power package 100 implements a true source Kelvin implementation of the signal terminals 504; and the right illustrated implementation of the power package 100 implements a dual true pseudo-source Kelvin implementation of the signal terminals 504.

In aspects, the power package 100 may be configured to improve switching quality and thus may be configured to ensure independent loops. The power source connection may have a separate path from the signal source (referred to as a source Kelvin) such that one does not overlap or interfere with the other. The closer the separate connections are made to the device, the better the switching performance.

The implementation of a true source kelvin in a power module may not be possible with the use of traditional power substrate technologies for most layout, but with the help of the technologies and solutions discussed in this disclosure, a power module with ultra-high power and signal density can be achieved. The proposed technologies enable the implementation of a true source kelvin, smart circuitry, intra module sensors, etc.

Implementing a true source kelvin is a tradeoff, as it requires extra signal interconnections and area on the power substrate for the layout. An alternative method uses a pseudo source kelvin, in which some of the paths overlap but not all of them.

This can be implemented by ‘branching off’ the source kelvin connection at some mid-point in the source path.

The need for a true vs. pseudo source kelvin depends on how the product is used, in particular the switching frequency, switching rates, and loss distribution (conduction vs. switching). 8 depicts the three different approaches. The pseudo source kelvin (left) extends up close to the devices decouple the path overlap as much as possible. The single true source kelvin (center) has a dedicated trace on the power substrate and dedicated kelvin bonds to the source pad on the devices. The dual true source kelvins (right) have two separate dedicated traces on the power substrate and dedicated kelvin bonds to the source pads on the devices.

A power module with a dual source kelvin implementation has several advantages over the same power module with just one true source kelvin implementation. These advantages include:

In aspects, the power package 100 may be configured with lower signal loop inductance: Loop resistance and inductance is directly proportional to the length of the conductor. Since dual source kelvin implementations can be positioned/designed in ways that minimize the signal loop length to the signal terminals, they decrease the overall signal loop inductance.

In aspects, the power package 100 may be configured with symmetrical design layout: Power modules with multiple devices that have a single source kelvin connection, tend to be asymmetrical in terms of switching due to the mismatch in trace length of the signal conductor to the power devices. In such module layouts, the power devices that are located on the same side as the signal terminals switch faster than the power devices that are located farther away (longer signal loop). Having a dual source kelvin approach with two signal loops enables symmetrical loop length to the power devices on either side of the package and minimize switching mismatch.

In aspects, the power package 100 may be configured with custom device switching: A dual source kelvin approach with two independent signal loops allow for fine tuning of the switching signals based on the power module layout in order to minimize the switching time mismatch and thereby minimizing transconductance currents between devices. The ability to customize the power device switching allows for ultra-low switching mismatch between devices, minimizes the switching losses, and allows for faster switching.

In aspects, the power package 100 may be configured with minimal power and signal loop magnetic coupling: Dual source kelvins with 2 separate signal loops allow for shorter conductor lengths and the ability to strategically place the signal terminals to avoid close contact or overlap with the high current power loop. Minimizing this signal-power loop overlap intern minimizes the magnetic mutual coupling between these conductor loops and allows for lower signal loop inductance and cleaner switching.

The aspects of the power package 100 illustrated in FIG. 68 and described therewith, may optionally be implemented in any other aspects of the power package 100 illustrated in the other figures and described therewith. Further, the aspects of the power package 100 illustrated in the other figures and described therewith may optionally be implemented in the aspects of the power package 100 illustrated in FIG. 68.

In aspects of the power package 100, the at least one signal connection assembly 502 may be configured with the at least one signal trace 304 that is thinner than the power trace 302, the at least one signal connection assembly 502 may be configured with the embedded routing layer 318 within the at least one power substrate 300, and/or the at least one signal connection assembly 502 may be configured with the at least one routing layer 308 on the at least one power substrate 300.

In aspects of the power package 100, the at least one signal connection assembly 502 may be configured with the at least one signal trace 304 that is thinner than the power trace 302. In aspects, the at least one signal connection assembly 502 may be configured with such that the at least one signal trace 304 is thinner than the power trace 302 along a vertical axis, which allows the power trace 302 to be larger.

In aspects, the at least one signal connection assembly 502 may be configured with the embedded routing layer 318 within the at least one power substrate 300. In aspects, the at least one signal connection assembly 502 may be configured with the embedded routing layer 318 below the power trace 302.

In aspects of the power package 100, the at least one signal connection assembly 502 may be configured with the at least one signal pad trace 306 connected to the embedded routing layer 318.

In aspects of the power package 100, the at least one signal connection assembly 502 may be configured with the at least one routing layer 308 on the at least one power substrate 300. In aspects, the at least one signal connection assembly 502 may be configured with the at least one routing layer 308 is on the power trace 302.

In aspects of the power package 100 as described herein, the power package 100 may contain power semiconductor devices, including MOSFETs, IGBTs, diodes, and/or the like, arranged into a variety of circuit topologies. A power module is typically a package that contains multiple devices in parallel and arranged into multiple switch positions. It serves many functions, including electrical interconnection; electrical isolation; heat transfer; mechanical structure; protection of the devices from environmental contamination and moisture; external electrical and thermal connection interfaces; compliance with safety standards such as voltage creepage and clearance distances; and/or the like.

In aspects of the power package 100 as described herein, the power package 100 may include and/or be implemented as:

A case module. In aspects, the case module implementation of the power package 100 may include: Power substrate, devices, and terminals may be surrounded by a separate insulative housing or case and filled with an insulating element (gel, epoxy, and/or the like). In aspects, the Power substrate may or may not be attached to a base plate, cold plate, etc.

An overmolded module. In aspects, the overmolded module implementation of the power package 100 may include: a Power substrate and devices attached to a lead frame and molded over with an epoxy molding compound or similar dielectric material.

A hermetic module. In aspects, the hermetic module implementation of the power package 100 may include: a Power substrate and devices may be attached to a hermetic outer package, often a structure of metal, ceramic, and glass, then filled with a gel or epoxy, and sealed.

A hybrid module. In aspects, the hybrid module implementation of the power package 100 may include: a combination of approaches that uses elements of multiple categories or is difficult to group in a single classification.

In one aspect, the power package 100 may be implemented in a wide variety of power topologies, including half-bridge, full-bridge, three phase, booster, chopper, DC-DC converters, and like arrangements and/or topologies. In one aspect, one or more implementations of the power package 100 may be implemented in an application.

The power package 100 may be implemented in an application that may be a power system, a motor system, a motor drive, an automotive motor system, a charging system, an automotive charging system, a vehicle system, an industrial motor drive, an embedded motor drive, an uninterruptible power supply, an AC-DC power supply, a welder power supply, a military system, an inverter, an inverter for wind turbines, solar power panels, tidal power plants, electric vehicles (EVs), a converter, a solar inverter, a circuit breaker, a protection circuit, a DC-DC converter, an Off-Board DC Fast Charger for an electric vehicle (EV), an on-board DC/DC Converter for an electric vehicle (EV), an on-board battery charger for an electric vehicle (EV), an electric vehicle (EV) Powertrain/Main Inverter, an electric vehicle (EV) charging infrastructure, an electric traction motor, a motor drive for an electric motor, a commercial inductive heating system, an uninterruptible power system, a power system, a motor system, a motor drive, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, electric vehicles (EVs), a converter, solar inverters, circuit breakers, protection circuits, DC-DC converters, Off-Board DC Fast Chargers for electric vehicles (EVs) and the like, on-board DC/DC Converters for electric vehicles (EVs) and the like, on-board battery chargers for electric vehicles (EVs) and the like, electric vehicle (EV) Powertrains/Main Inverters, electric vehicle (EV) charging infrastructures, electric traction motors, motor drives for electric motors, commercial inductive heating systems, uninterruptible power systems, and/or the like.

Accordingly, the disclosure has set forth a package and/or a system configured to implement higher voltages, currents, switching speeds, and/or the like.

One EXAMPLE: a power package includes at least one power substrate having at least one power trace. The power package in addition includes at least one power device on the at least one power trace. The power package moreover includes signal terminals. The power package also includes at least one signal connection assembly. The power package further includes where the at least one signal connection assembly comprises at least one of the following: at least one signal trace that is thinner than the at least one power trace; at least one embedded routing layer within the at least one power substrate; and/or at least one routing layer on the at least one power substrate.

The above-noted EXAMPLE may further include any one or a combination of more than one of the following EXAMPLES: The power package of the above-noted EXAMPLE where the at least one signal connection assembly is integrated on and/or within the at least one power substrate and the at least one signal connection assembly is configured to reduce a signal loop trace area and increase a power loop area. The power package of the above-noted EXAMPLE where the at least one signal connection assembly is configured to utilize less surface area of the at least one power substrate and the at least one signal connection assembly is configured to provide additional surface area for the at least one power trace. The power package of the above-noted EXAMPLE where the at least one signal connection assembly is configured to utilize less surface area of the at least one power substrate to provide additional surface area for the at least one power trace to be larger, which increases package footprint utilization, thermal management, switching performance, manufacturability, and/or power density. The power package of the above-noted EXAMPLE where: the at least one signal connection assembly is connected to at least one signal interconnect; and the at least one signal interconnect is further connected to at least one of the signal terminals. The power package of the above-noted EXAMPLE where: the at least one signal connection assembly is connected to at least one signal interconnect; and the at least one signal connection assembly being further configured to transfer signals between at least one of the signal terminals and/or the at least one power device. The power package of the above-noted EXAMPLE where the at least one signal connection assembly comprises the at least one signal trace that is thinner than the at least one power trace. The power package of the above-noted EXAMPLE where the at least one power substrate is configured such that the at least one signal trace is thinner than the at least one power trace along a vertical axis, which allows the at least one power trace to be larger. The power package of the above-noted EXAMPLE where a larger implementation of the at least one power trace comprises greater current carrying capability, greater thermal conduction, greater power density using a same package footprint, and/or reduced mechanical stress. The power package of the above-noted EXAMPLE where the at least one signal trace comprises a thickness along a vertical axis; the at least one power trace comprises a thickness along a vertical axis; and the thickness of the at least one power trace along the vertical axis is greater than the thickness of the at least one signal trace along the vertical axis. The power package of the above-noted EXAMPLE where a thinner implementation of the at least one signal trace minimizes electromagnetic coupling between different current carrying loops, reduces power and signal loop inductances, and/or increases manufacturability. The power package of the above-noted EXAMPLE where a thickness of the at least one power trace along a vertical axis is greater than two times a thickness of the at least one signal trace along the vertical axis. The power package of the above-noted EXAMPLE where the at least one signal connection assembly comprises the at least one embedded routing layer within the at least one power substrate. The power package of the above-noted EXAMPLE where the at least one embedded routing layer is below the at least one power trace. The power package of the above-noted EXAMPLE where the at least one signal connection assembly further comprises at least one signal pad trace connected to the at least one embedded routing layer. The power package of the above-noted EXAMPLE where the at least one power trace is on at least two sides of the at least one signal pad trace. The power package of the above-noted EXAMPLE where: the at least one signal pad trace comprises a thickness along a vertical axis; the at least one power trace comprises a thickness along the vertical axis; and the thickness of the at least one power trace along the vertical axis is greater than the thickness of the at least one signal pad trace along the vertical axis. The power package of the above-noted EXAMPLE where a thickness of the at least one power trace along a vertical axis is greater than two times a thickness of the at least one signal pad trace along the vertical axis. The power package of the above-noted EXAMPLE where the at least one power substrate is configured such that the at least one signal pad trace is thinner than the at least one power trace along a vertical axis, which allows the at least one power trace to be larger. The power package of the above-noted EXAMPLE where the at least one signal connection assembly comprises a first dielectric layer, the at least one embedded routing layer on the first dielectric layer, and a second dielectric layer on the at least one embedded routing layer. The power package of the above-noted EXAMPLE where: the at least one power substrate comprises a bottom metal layer; and the at least one signal connection assembly comprises a first dielectric layer on the bottom metal layer, the at least one embedded routing layer on the first dielectric layer, and a second dielectric layer on the at least one embedded routing layer. The power package of the above-noted EXAMPLE where the at least one signal connection assembly comprises the at least one routing layer on the at least one power substrate. The power package of the above-noted EXAMPLE where the at least one routing layer is on the at least one power trace. The power package of the above-noted EXAMPLE where the at least one routing layer comprises a top metal foil on a dielectric layer. The power package of the above-noted EXAMPLE where the at least one routing layer comprises a metal clad laminate. The power package of the above-noted EXAMPLE where the at least one routing layer is soldered, sintered, and/or tacked onto a surface of the at least one power trace. The power package of the above-noted EXAMPLE where the at least one routing layer is configured through direct printing of insulating and conductive pastes onto the at least one power trace. The power package of the above-noted EXAMPLE where the at least one routing layer comprises a bottom metal foil on the at least one power trace, a dielectric layer on the bottom metal foil, and a top metal foil on the dielectric layer. The power package of the above-noted EXAMPLE where one or more terminal ends of the at least one routing layer and/or the top metal foil comprise wider portions to form bond pads for at least one signal interconnect to connect and the at least one signal interconnect is further connected to the at least one power device. The power package of the above-noted EXAMPLE where: the at least one power substrate comprises a multilayer power substrate; and the at least one signal connection assembly is integrated on and/or within the multilayer power substrate. The power package of the above-noted EXAMPLE where: the at least one power substrate comprises an internal multilayer power substrate; and the at least one signal connection assembly is integrated within the internal multilayer power substrate. The power package of the above-noted EXAMPLE where: the at least one power substrate comprises an external multilayer power substrate; and the at least one signal connection assembly is integrated on the external multilayer power substrate. The power package of the above-noted EXAMPLE where: the at least one power substrate comprises a multi-thickness power substrate; and the at least one signal connection assembly is integrated on and/or within the multi-thickness power substrate. The power package of the above-noted EXAMPLE where one or more of the signal terminals are configured as one or more intra-module temperature sensing terminals, intra-module current sensing terminals, intra-module strain sensing terminals, intra-module humidity sensing terminals, true Kelvin source terminals, pseudo-kelvin source terminals, gate drive terminals, and/or drain Kelvin terminals. The power package of the above-noted EXAMPLE includes at least one sensor that comprises a temperature sensor, a current sensor, a humidity/moisture sensor, and/or a mechanical strain sensor. The power package of the above-noted EXAMPLE where a plurality of the at least one power device are on the at least one power substrate. The power package of the above-noted EXAMPLE where: a plurality of the at least one power device are on and along a longitudinal axis of the at least one power substrate; and a plurality of the at least one power device are on and along a lateral axis of the at least one power substrate. The power package of the above-noted EXAMPLE includes a power interconnect connected to a source of the at least one power device and a power terminal. The power package of the above-noted EXAMPLE where the power interconnect comprises at least one of a direct source attach, power wire bonding, and/or power ribbon bonding. The power package of the above-noted EXAMPLE where the at least one signal connection assembly comprise orthogonal routing. The power package of the above-noted EXAMPLE where the at least one signal connection assembly comprise contoured routing. The power package of the above-noted EXAMPLE where the at least one signal connection assembly comprise winged routing. A half bridge implementation of the above-noted EXAMPLE. A full bridge implementation of the above-noted EXAMPLE. A three-phase and/or six pack implementation of the above-noted EXAMPLE.

One EXAMPLE: a power package includes at least one power substrate having at least one power trace. The power package in addition includes at least one power device on the at least one power trace. The power package moreover includes signal terminals. The power package also includes at least one signal connection assembly configured to reduce a signal loop trace area and increase a power loop area. The power package further includes where the at least one signal connection assembly comprises at least one of the following: at least one signal trace that is thinner than the at least one power trace; at least one embedded routing layer within the at least one power substrate; and/or at least one routing layer on the at least one power substrate.

The above-noted EXAMPLE may further include any one or a combination of more than one of the following EXAMPLES: The power package of the above-noted EXAMPLE where the at least one signal connection assembly is integrated on and/or within the at least one power substrate and the at least one signal connection assembly is configured to reduce a signal loop trace area and increase a power loop area. The power package of the above-noted EXAMPLE where the at least one signal connection assembly is configured to utilize less surface area of the at least one power substrate and the at least one signal connection assembly is configured to provide additional surface area for the at least one power trace. The power package of the above-noted EXAMPLE where the at least one signal connection assembly is configured to utilize less surface area of the at least one power substrate to provide additional surface area for the at least one power trace to be larger, which increases package footprint utilization, thermal management, switching performance, manufacturability, and/or power density. The power package of the above-noted EXAMPLE where: the at least one signal connection assembly is connected to at least one signal interconnect; and the at least one signal interconnect is further connected to at least one of the signal terminals. The power package of the above-noted EXAMPLE where: the at least one signal connection assembly is connected to at least one signal interconnect; and the at least one signal connection assembly being further configured to transfer signals between at least one of the signal terminals and/or the at least one power device. The power package of the above-noted EXAMPLE where the at least one signal connection assembly comprises the at least one signal trace that is thinner than the at least one power trace. The power package of the above-noted EXAMPLE where the at least one power substrate is configured such that the at least one signal trace is thinner than the at least one power trace along a vertical axis, which allows the at least one power trace to be larger. The power package of the above-noted EXAMPLE where a larger implementation of the at least one power trace comprises greater current carrying capability, greater thermal conduction, greater power density using a same package footprint, and/or reduced mechanical stress. The power package of the above-noted EXAMPLE where the at least one signal trace comprises a thickness along a vertical axis; the at least one power trace comprises a thickness along a vertical axis; and the thickness of the at least one power trace along the vertical axis is greater than the thickness of the at least one signal trace along the vertical axis. The power package of the above-noted EXAMPLE where a thinner implementation of the at least one signal trace minimizes electromagnetic coupling between different current carrying loops, reduces power and signal loop inductances, and/or increases manufacturability. The power package of the above-noted EXAMPLE where a thickness of the at least one power trace along a vertical axis is greater than two times a thickness of the at least one signal trace along the vertical axis. The power package of the above-noted EXAMPLE where the at least one signal connection assembly comprises the at least one embedded routing layer within the at least one power substrate. The power package of the above-noted EXAMPLE where the at least one embedded routing layer is below the at least one power trace. The power package of the above-noted EXAMPLE where the at least one signal connection assembly further comprises at least one signal pad trace connected to the at least one embedded routing layer. The power package of the above-noted EXAMPLE where the at least one power trace is on at least two sides of the at least one signal pad trace. The power package of the above-noted EXAMPLE where: the at least one signal pad trace comprises a thickness along a vertical axis; the at least one power trace comprises a thickness along the vertical axis; and the thickness of the at least one power trace along the vertical axis is greater than the thickness of the at least one signal pad trace along the vertical axis. The power package of the above-noted EXAMPLE where a thickness of the at least one power trace along a vertical axis is greater than two times a thickness of the at least one signal pad trace along the vertical axis. The power package of the above-noted EXAMPLE where the at least one power substrate is configured such that the at least one signal pad trace is thinner than the at least one power trace along a vertical axis, which allows the at least one power trace to be larger. The power package of the above-noted EXAMPLE where the at least one signal connection assembly comprises a first dielectric layer, the at least one embedded routing layer on the first dielectric layer, and a second dielectric layer on the at least one embedded routing layer. The power package of the above-noted EXAMPLE where: the at least one power substrate comprises a bottom metal layer; and the at least one signal connection assembly comprises a first dielectric layer on the bottom metal layer, the at least one embedded routing layer on the first dielectric layer, and a second dielectric layer on the at least one embedded routing layer. The power package of the above-noted EXAMPLE where the at least one signal connection assembly comprises the at least one routing layer on the at least one power substrate. The power package of the above-noted EXAMPLE where the at least one routing layer is on the at least one power trace. The power package of the above-noted EXAMPLE where the at least one routing layer comprises a top metal foil on a dielectric layer. The power package of the above-noted EXAMPLE where the at least one routing layer comprises a metal clad laminate. The power package of the above-noted EXAMPLE where the at least one routing layer is soldered, sintered, and/or tacked onto a surface of the at least one power trace. The power package of the above-noted EXAMPLE where the at least one routing layer is configured through direct printing of insulating and conductive pastes onto the at least one power trace. The power package of the above-noted EXAMPLE where the at least one routing layer comprises a bottom metal foil on the at least one power trace, a dielectric layer on the bottom metal foil, and a top metal foil on the dielectric layer. The power package of the above-noted EXAMPLE where one or more terminal ends of the at least one routing layer and/or the top metal foil comprise wider portions to form bond pads for at least one signal interconnect to connect and the at least one signal interconnect is further connected to the at least one power device. The power package of the above-noted EXAMPLE where: the at least one power substrate comprises a multilayer power substrate; and the at least one signal connection assembly is integrated on and/or within the multilayer power substrate. The power package of the above-noted EXAMPLE where: the at least one power substrate comprises an internal multilayer power substrate; and the at least one signal connection assembly is integrated within the internal multilayer power substrate. The power package of the above-noted EXAMPLE where: the at least one power substrate comprises an external multilayer power substrate; and the at least one signal connection assembly is integrated on the external multilayer power substrate. The power package of the above-noted EXAMPLE where: the at least one power substrate comprises a multi-thickness power substrate; and the at least one signal connection assembly is integrated on and/or within the multi-thickness power substrate. The power package of the above-noted EXAMPLE where one or more of the signal terminals are configured as one or more intra-module temperature sensing terminals, intra-module current sensing terminals, intra-module strain sensing terminals, intra-module humidity sensing terminals, true Kelvin source terminals, pseudo-kelvin source terminals, gate drive terminals, and/or drain Kelvin terminals. The power package of the above-noted EXAMPLE includes at least one sensor that comprises a temperature sensor, a current sensor, a humidity/moisture sensor, and/or a mechanical strain sensor. The power package of the above-noted EXAMPLE where a plurality of the at least one power device are on the at least one power substrate. The power package of the above-noted EXAMPLE where: a plurality of the at least one power device are on and along a longitudinal axis of the at least one power substrate; and a plurality of the at least one power device are on and along a lateral axis of the at least one power substrate. The power package of the above-noted EXAMPLE includes a power interconnect connected to a source of the at least one power device and a power terminal. The power package of the above-noted EXAMPLE where the power interconnect comprises at least one of a direct source attach, power wire bonding, and/or power ribbon bonding. The power package of the above-noted EXAMPLE where the at least one signal connection assembly comprise orthogonal routing. The power package of the above-noted EXAMPLE where the at least one signal connection assembly comprise contoured routing. The power package of the above-noted EXAMPLE where the at least one signal connection assembly comprise winged routing. A half bridge implementation of the above-noted EXAMPLE. A full bridge implementation of the above-noted EXAMPLE. A three-phase and/or six pack implementation of the above-noted EXAMPLE.

One EXAMPLE: a power package includes at least one power substrate having at least one power trace. The power package in addition includes at least one power device on the at least one power trace. The power package moreover includes signal terminals. The power package also includes at least one signal connection assembly. The power package further includes where the at least one signal connection assembly is connected to at least one signal interconnect. The power package in addition includes where the at least one signal interconnect is further connected to at least one of the signal terminals. The power package moreover includes where the at least one signal connection assembly comprises at least one of the following: at least one signal trace that is thinner than the at least one power trace; at least one embedded routing layer within the at least one power substrate; and/or. The power package in addition includes at least one routing layer on the at least one power substrate.

The above-noted EXAMPLE may further include any one or a combination of more than one of the following EXAMPLES: The power package of the above-noted EXAMPLE where the at least one signal connection assembly is integrated on and/or within the at least one power substrate and the at least one signal connection assembly is configured to reduce a signal loop trace area and increase a power loop area. The power package of the above-noted EXAMPLE where the at least one signal connection assembly is configured to utilize less surface area of the at least one power substrate and the at least one signal connection assembly is configured to provide additional surface area for the at least one power trace. The power package of the above-noted EXAMPLE where the at least one signal connection assembly is configured to utilize less surface area of the at least one power substrate to provide additional surface area for the at least one power trace to be larger, which increases package footprint utilization, thermal management, switching performance, manufacturability, and/or power density. The power package of the above-noted EXAMPLE where: the at least one signal connection assembly is connected to at least one signal interconnect; and the at least one signal interconnect is further connected to at least one of the signal terminals. The power package of the above-noted EXAMPLE where: the at least one signal connection assembly is connected to at least one signal interconnect; and the at least one signal connection assembly being further configured to transfer signals between at least one of the signal terminals and/or the at least one power device. The power package of the above-noted EXAMPLE where the at least one signal connection assembly comprises the at least one signal trace that is thinner than the at least one power trace. The power package of the above-noted EXAMPLE where the at least one power substrate is configured such that the at least one signal trace is thinner than the at least one power trace along a vertical axis, which allows the at least one power trace to be larger. The power package of the above-noted EXAMPLE where a larger implementation of the at least one power trace comprises greater current carrying capability, greater thermal conduction, greater power density using a same package footprint, and/or reduced mechanical stress. The power package of the above-noted EXAMPLE where the at least one signal trace comprises a thickness along a vertical axis; the at least one power trace comprises a thickness along a vertical axis; and the thickness of the at least one power trace along the vertical axis is greater than the thickness of the at least one signal trace along the vertical axis. The power package of the above-noted EXAMPLE where a thinner implementation of the at least one signal trace minimizes electromagnetic coupling between different current carrying loops, reduces power and signal loop inductances, and/or increases manufacturability. The power package of the above-noted EXAMPLE where a thickness of the at least one power trace along a vertical axis is greater than two times a thickness of the at least one signal trace along the vertical axis. The power package of the above-noted EXAMPLE where the at least one signal connection assembly comprises the at least one embedded routing layer within the at least one power substrate. The power package of the above-noted EXAMPLE where the at least one embedded routing layer is below the at least one power trace. The power package of the above-noted EXAMPLE where the at least one signal connection assembly further comprises at least one signal pad trace connected to the at least one embedded routing layer. The power package of the above-noted EXAMPLE where the at least one power trace is on at least two sides of the at least one signal pad trace. The power package of the above-noted EXAMPLE where: the at least one signal pad trace comprises a thickness along a vertical axis; the at least one power trace comprises a thickness along the vertical axis; and the thickness of the at least one power trace along the vertical axis is greater than the thickness of the at least one signal pad trace along the vertical axis. The power package of the above-noted EXAMPLE where a thickness of the at least one power trace along a vertical axis is greater than two times a thickness of the at least one signal pad trace along the vertical axis. The power package of the above-noted EXAMPLE where the at least one power substrate is configured such that the at least one signal pad trace is thinner than the at least one power trace along a vertical axis, which allows the at least one power trace to be larger. The power package of the above-noted EXAMPLE where the at least one signal connection assembly comprises a first dielectric layer, the at least one embedded routing layer on the first dielectric layer, and a second dielectric layer on the at least one embedded routing layer. The power package of the above-noted EXAMPLE where: the at least one power substrate comprises a bottom metal layer; and the at least one signal connection assembly comprises a first dielectric layer on the bottom metal layer, the at least one embedded routing layer on the first dielectric layer, and a second dielectric layer on the at least one embedded routing layer. The power package of the above-noted EXAMPLE where the at least one signal connection assembly comprises the at least one routing layer on the at least one power substrate. The power package of the above-noted EXAMPLE where the at least one routing layer is on the at least one power trace. The power package of the above-noted EXAMPLE where the at least one routing layer comprises a top metal foil on a dielectric layer. The power package of the above-noted EXAMPLE where the at least one routing layer comprises a metal clad laminate. The power package of the above-noted EXAMPLE where the at least one routing layer is soldered, sintered, and/or tacked onto a surface of the at least one power trace. The power package of the above-noted EXAMPLE where the at least one routing layer is configured through direct printing of insulating and conductive pastes onto the at least one power trace. The power package of the above-noted EXAMPLE where the at least one routing layer comprises a bottom metal foil on the at least one power trace, a dielectric layer on the bottom metal foil, and a top metal foil on the dielectric layer. The power package of the above-noted EXAMPLE where one or more terminal ends of the at least one routing layer and/or the top metal foil comprise wider portions to form bond pads for at least one signal interconnect to connect and the at least one signal interconnect is further connected to the at least one power device. The power package of the above-noted EXAMPLE where: the at least one power substrate comprises a multilayer power substrate; and the at least one signal connection assembly is integrated on and/or within the multilayer power substrate. The power package of the above-noted EXAMPLE where: the at least one power substrate comprises an internal multilayer power substrate; and the at least one signal connection assembly is integrated within the internal multilayer power substrate. The power package of the above-noted EXAMPLE where: the at least one power substrate comprises an external multilayer power substrate; and the at least one signal connection assembly is integrated on the external multilayer power substrate. The power package of the above-noted EXAMPLE where: the at least one power substrate comprises a multi-thickness power substrate; and the at least one signal connection assembly is integrated on and/or within the multi-thickness power substrate. The power package of the above-noted EXAMPLE where one or more of the signal terminals are configured as one or more intra-module temperature sensing terminals, intra-module current sensing terminals, intra-module strain sensing terminals, intra-module humidity sensing terminals, true Kelvin source terminals, pseudo-kelvin source terminals, gate drive terminals, and/or drain Kelvin terminals. The power package of the above-noted EXAMPLE includes at least one sensor that comprises a temperature sensor, a current sensor, a humidity/moisture sensor, and/or a mechanical strain sensor. The power package of the above-noted EXAMPLE where a plurality of the at least one power device are on the at least one power substrate. The power package of the above-noted EXAMPLE where: a plurality of the at least one power device are on and along a longitudinal axis of the at least one power substrate; and a plurality of the at least one power device are on and along a lateral axis of the at least one power substrate. The power package of the above-noted EXAMPLE includes a power interconnect connected to a source of the at least one power device and a power terminal. The power package of the above-noted EXAMPLE where the power interconnect comprises at least one of a direct source attach, power wire bonding, and/or power ribbon bonding. The power package of the above-noted EXAMPLE where the at least one signal connection assembly comprise orthogonal routing. The power package of the above-noted EXAMPLE where the at least one signal connection assembly comprise contoured routing. The power package of the above-noted EXAMPLE where the at least one signal connection assembly comprise winged routing. A half bridge implementation of the above-noted EXAMPLE. A full bridge implementation of the above-noted EXAMPLE. A three-phase and/or six pack implementation of the above-noted EXAMPLE.

One EXAMPLE: a power package includes at least one power substrate having at least one power trace. The power package in addition includes at least one power device on the at least one power trace. The power package moreover includes signal terminals. The power package also includes at least one signal connection assembly. The power package further includes where the at least one signal connection assembly comprises at least one of the following: at least one signal trace that is thinner than the at least one power trace; at least one embedded routing layer within the at least one power substrate; and/or at least one routing layer on the at least one power trace.

The above-noted EXAMPLE may further include any one or a combination of more than one of the following EXAMPLES: The power package of the above-noted EXAMPLE where the at least one signal connection assembly is integrated on and/or within the at least one power substrate and the at least one signal connection assembly is configured to reduce a signal loop trace area and increase a power loop area. The power package of the above-noted EXAMPLE where the at least one signal connection assembly is configured to utilize less surface area of the at least one power substrate and the at least one signal connection assembly is configured to provide additional surface area for the at least one power trace. The power package of the above-noted EXAMPLE where the at least one signal connection assembly is configured to utilize less surface area of the at least one power substrate to provide additional surface area for the at least one power trace to be larger, which increases package footprint utilization, thermal management, switching performance, manufacturability, and/or power density. The power package of the above-noted EXAMPLE where: the at least one signal connection assembly is connected to at least one signal interconnect; and the at least one signal interconnect is further connected to at least one of the signal terminals. The power package of the above-noted EXAMPLE where: the at least one signal connection assembly is connected to at least one signal interconnect; and the at least one signal connection assembly being further configured to transfer signals between at least one of the signal terminals and/or the at least one power device. The power package of the above-noted EXAMPLE where the at least one signal connection assembly comprises the at least one signal trace that is thinner than the at least one power trace. The power package of the above-noted EXAMPLE where the at least one power substrate is configured such that the at least one signal trace is thinner than the at least one power trace along a vertical axis, which allows the at least one power trace to be larger. The power package of the above-noted EXAMPLE where a larger implementation of the at least one power trace comprises greater current carrying capability, greater thermal conduction, greater power density using a same package footprint, and/or reduced mechanical stress. The power package of the above-noted EXAMPLE where the at least one signal trace comprises a thickness along a vertical axis; the at least one power trace comprises a thickness along a vertical axis; and the thickness of the at least one power trace along the vertical axis is greater than the thickness of the at least one signal trace along the vertical axis. The power package of the above-noted EXAMPLE where a thinner implementation of the at least one signal trace minimizes electromagnetic coupling between different current carrying loops, reduces power and signal loop inductances, and/or increases manufacturability. The power package of the above-noted EXAMPLE where a thickness of the at least one power trace along a vertical axis is greater than two times a thickness of the at least one signal trace along the vertical axis. The power package of the above-noted EXAMPLE where the at least one signal connection assembly comprises the at least one embedded routing layer within the at least one power substrate. The power package of the above-noted EXAMPLE where the at least one embedded routing layer is below the at least one power trace. The power package of the above-noted EXAMPLE where the at least one signal connection assembly further comprises at least one signal pad trace connected to the at least one embedded routing layer. The power package of the above-noted EXAMPLE where the at least one power trace is on at least two sides of the at least one signal pad trace. The power package of the above-noted EXAMPLE where: the at least one signal pad trace comprises a thickness along a vertical axis; the at least one power trace comprises a thickness along the vertical axis; and the thickness of the at least one power trace along the vertical axis is greater than the thickness of the at least one signal pad trace along the vertical axis. The power package of the above-noted EXAMPLE where a thickness of the at least one power trace along a vertical axis is greater than two times a thickness of the at least one signal pad trace along the vertical axis. The power package of the above-noted EXAMPLE where the at least one power substrate is configured such that the at least one signal pad trace is thinner than the at least one power trace along a vertical axis, which allows the at least one power trace to be larger. The power package of the above-noted EXAMPLE where the at least one signal connection assembly comprises a first dielectric layer, the at least one embedded routing layer on the first dielectric layer, and a second dielectric layer on the at least one embedded routing layer. The power package of the above-noted EXAMPLE where: the at least one power substrate comprises a bottom metal layer; and the at least one signal connection assembly comprises a first dielectric layer on the bottom metal layer, the at least one embedded routing layer on the first dielectric layer, and a second dielectric layer on the at least one embedded routing layer. The power package of the above-noted EXAMPLE where the at least one signal connection assembly comprises the at least one routing layer on the at least one power trace. The power package of the above-noted EXAMPLE where the at least one routing layer comprises a top metal foil on a dielectric layer. The power package of the above-noted EXAMPLE where the at least one routing layer comprises a metal clad laminate. The power package of the above-noted EXAMPLE where the at least one routing layer is soldered, sintered, and/or tacked onto a surface of the at least one power trace. The power package of the above-noted EXAMPLE where the at least one routing layer is configured through direct printing of insulating and conductive pastes onto the at least one power trace. The power package of the above-noted EXAMPLE where the at least one routing layer comprises a bottom metal foil on the at least one power trace, a dielectric layer on the bottom metal foil, and a top metal foil on the dielectric layer. The power package of the above-noted EXAMPLE where one or more terminal ends of the at least one routing layer and/or the top metal foil comprise wider portions to form bond pads for at least one signal interconnect to connect and the at least one signal interconnect is further connected to the at least one power device. The power package of the above-noted EXAMPLE where: the at least one power substrate comprises a multilayer power substrate; and the at least one signal connection assembly is integrated on and/or within the multilayer power substrate. The power package of the above-noted EXAMPLE where: the at least one power substrate comprises an internal multilayer power substrate; and the at least one signal connection assembly is integrated within the internal multilayer power substrate. The power package of the above-noted EXAMPLE where: the at least one power substrate comprises an external multilayer power substrate; and the at least one signal connection assembly is integrated on the external multilayer power substrate. The power package of the above-noted EXAMPLE where: the at least one power substrate comprises a multi-thickness power substrate; and the at least one signal connection assembly is integrated on and/or within the multi-thickness power substrate. The power package of the above-noted EXAMPLE where one or more of the signal terminals are configured as one or more intra-module temperature sensing terminals, intra-module current sensing terminals, intra-module strain sensing terminals, intra-module humidity sensing terminals, true Kelvin source terminals, pseudo-kelvin source terminals, gate drive terminals, and/or drain Kelvin terminals. The power package of the above-noted EXAMPLE includes at least one sensor that comprises a temperature sensor, a current sensor, a humidity/moisture sensor, and/or a mechanical strain sensor. The power package of the above-noted EXAMPLE where a plurality of the at least one power device are on the at least one power substrate. The power package of the above-noted EXAMPLE where: a plurality of the at least one power device are on and along a longitudinal axis of the at least one power substrate; and a plurality of the at least one power device are on and along a lateral axis of the at least one power substrate. The power package of the above-noted EXAMPLE includes a power interconnect connected to a source of the at least one power device and a power terminal. The power package of the above-noted EXAMPLE where the power interconnect comprises at least one of a direct source attach, power wire bonding, and/or power ribbon bonding. The power package of the above-noted EXAMPLE where the at least one signal connection assembly comprise orthogonal routing. The power package of the above-noted EXAMPLE where the at least one signal connection assembly comprise contoured routing. The power package of the above-noted EXAMPLE where the at least one signal connection assembly comprise winged routing. A half bridge implementation of the above-noted EXAMPLE. A full bridge implementation of the above-noted EXAMPLE. A three-phase and/or six pack implementation of the above-noted EXAMPLE.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A power package comprising:
at least one power substrate having at least one power trace;
at least one power device on the at least one power trace;
signal terminals; and
at least one signal connection assembly,
wherein the at least one signal connection assembly comprises at least one of the following:
at least one signal trace that is thinner than the at least one power trace;
at least one embedded routing layer within the at least one power substrate; and/or
at least one routing layer on the at least one power substrate.

2. The power package according to claim 1 wherein the at least one signal connection assembly is integrated on and/or within the at least one power substrate and the at least one signal connection assembly is configured to reduce a signal loop trace area and increase a power loop area.

3. (canceled)

4. The power package according to claim 1 wherein the at least one signal connection assembly is configured to utilize less surface area of the at least one power substrate to provide additional surface area for the at least one power trace to be larger, which increases package footprint utilization, thermal management, switching performance, manufacturability, and/or power density.

5. The power package according to claim 1 wherein:
the at least one signal connection assembly is connected to at least one signal interconnect; and
the at least one signal interconnect is further connected to at least one of the signal terminals.

6. (canceled)

7. The power package according to claim 1 wherein the at least one signal connection assembly comprises the at least one signal trace that is thinner than the at least one power trace.

8. The power package according to claim 7 wherein the at least one power substrate is configured such that the at least one signal trace is thinner than the at least one power trace along a vertical axis, which allows the at least one power trace to be larger.

9. (canceled)

10. The power package according to claim 7 wherein
the at least one signal trace comprises a thickness along a vertical axis;
the at least one power trace comprises a thickness along a vertical axis; and
the thickness of the at least one power trace along the vertical axis is greater than the thickness of the at least one signal trace along the vertical axis.

11. The power package according to claim 7 wherein a thinner implementation of the at least one signal trace minimizes electromagnetic coupling between different current carrying loops, reduces power and signal loop inductances, and/or increases manufacturability.

12. (canceled)

13. The power package according to claim 1 wherein the at least one signal connection assembly comprises the at least one embedded routing layer within the at least one power substrate.

14. The power package according to claim 13 wherein the at least one embedded routing layer is below the at least one power trace.

15. The power package according to claim 13 wherein the at least one signal connection assembly further comprises at least one signal pad trace connected to the at least one embedded routing layer.

16.-21. (canceled)

22. The power package according to claim 1 wherein the at least one signal connection assembly comprises the at least one routing layer on the at least one power substrate.

23. The power package according to claim 22 wherein the at least one routing layer is on the at least one power trace.

24. The power package according to claim 22 wherein the at least one routing layer comprises a top metal foil on a dielectric layer.

25. The power package according to claim 22 wherein the at least one routing layer comprises a metal clad laminate.

26.-42. (canceled)

43. A half bridge implementation of the power package according to claim 1.

44. A full bridge implementation of the power package according to claim 1.

45. A three-phase and/or six pack implementation of the power package according to claim 1.

46. A power package comprising:
at least one power substrate having at least one power trace;
at least one power device on the at least one power trace;
signal terminals; and
at least one signal connection assembly configured to reduce a signal loop trace area and increase a power loop area,
wherein the at least one signal connection assembly comprises at least one of the following:
at least one signal trace that is thinner than the at least one power trace;
at least one embedded routing layer within the at least one power substrate; and/or
at least one routing layer on the at least one power substrate.

47.-51. (canceled)

52. The power package according to claim 46 wherein the at least one signal connection assembly comprises the at least one signal trace that is thinner than the at least one power trace.

53.-57. (canceled)

58. The power package according to claim 46 wherein the at least one signal connection assembly comprises the at least one embedded routing layer within the at least one power substrate.

59.-66. (canceled)

67. The power package according to claim 46 wherein the at least one signal connection assembly comprises the at least one routing layer on the at least one power substrate.

68.-90. (canceled)

91. A power package comprising:
at least one power substrate having at least one power trace;
at least one power device on the at least one power trace;
signal terminals; and
at least one signal connection assembly,
wherein the at least one signal connection assembly is connected to at least one signal interconnect;
wherein the at least one signal interconnect is further connected to at least one of the signal terminals; and
wherein the at least one signal connection assembly comprises at least one of the following:
at least one signal trace that is thinner than the at least one power trace;
at least one embedded routing layer within the at least one power substrate; and/or
at least one routing layer on the at least one power substrate.

92.-96. (canceled)

97. The power package according to claim 91 wherein the at least one signal connection assembly comprises the at least one signal trace that is thinner than the at least one power trace.

98.-102. (canceled)

103. The power package according to claim 91 wherein the at least one signal connection assembly comprises the at least one embedded routing layer within the at least one power substrate.

104.-111. (canceled)

112. The power package according to claim 91 wherein the at least one signal connection assembly comprises the at least one routing layer on the at least one power substrate.

113.-179. (canceled)
